(19) United States
(12) Patent Application Publication
(10) Pub. No.: US 2025/0287834 A1
(43) Pub. Date: Sep. 11, 2025

(54) BORON COMPOUND AND ORGANIC LIGHT-EMITTING DEVICE COMPRISING SAME

(71) Applicant: University-Industry Cooperation Group of Kyung Hee University, Yongin-si (KR)

(72) Inventors: Jang Hyuk Kwon, Seongnam-si (KR); Braveenth Ramanaskanda, Seoul (KR); Ju Young Lee, Suwon-si (KR); Jae Doh Park, Seoul (KR); Hyun A Lee, Seoul (KR); Hye In Yang, Seoul (KR)

(21) Appl. No.: 18/687,228

(22) PCT Filed: Aug. 2, 2022
(86) PCT No.: PCT/KR2022/011432

§ 371 Date: Feb. 27, 2024

(30) Foreign Application Priority Data
Sep. 1, 2021 (KR) 10-2021-0116437

(51) Int. Cl. H10K 85/60; C07F 5/02; C07F 7/08; C09K 11/02; C09K 11/06; H10K 50/12; H10K 101/00

(52) U.S. Cl. CPC H10K 85/636; C07F 5/027; C07F 7/0812; C09K 11/02; C09K 11/06; H10K 85/615; H10K 85/6574; C07B 2200/05; C09K 2211/1007; C09K 2211/1014; C09K 2211/1022; H10K 50/12; H10K 85/658; H10K 2101/27

(57) ABSTRACT

The present invention relates to: a boron compound having a structure comprising a specific substituent; and an organic light-emitting device comprising same, and more specifically, to a boron compound having improved quantum efficiency and lifespan characteristics by, while attaching a substituent capable of disrupting intermolecular packing at the para position of boron, which does not significantly affect color characteristics, transforming the boron core inner structure, which affects color characteristics, into a carbazole form having only one side substituted with a heteroatom aromatic ring, and an organic light-emitting device comprising the same.

### CROSS-REFERENCE TO RELATED APPLICATION

This Application is a Section 371 National Stage Application of International Application No. PCT/KR2022/011432, filed Aug. 2, 2022 and published as WO 2023/033381 A1, in Korean, which claims priority to KR patent application serial no. 10-2021-0116437, filed Sep. 1, 2021, the contents of which are hereby incorporated by reference in their entirety.

### TECHNICAL FIELD

The present invention relates to a boron delayed fluorescent compound (thermally activated delayed fluorescence) having narrow half-width characteristics and an organic light-emitting device having improved color characteristics by using the same.

### BACKGROUND ART

Organic light emission refers to a phenomenon of converting electrical energy to light energy using organic materials. Herein, an organic light-emitting device is a device having the organic materials formed in multiple layers between an anode and a cathode, and emitting light when electrical energy is applied. An organic light-emitting device is formed with multiple organic layers for efficiency and stability, and may basically be formed with a hole injection layer, a hole transport layer, a light-emitting layer, an electron transport layer, an electron injection layer and the like.

Materials used as the organic layers may be divided into light-emitting materials and charge transport materials depending on the function, and the light-emitting materials may be classified into fluorescent materials using only fluorescence derived from a singlet excited state of electrons and phosphorescent materials derived from a triplet excited state depending on the light-emitting mechanism. In addition, the light-emitting materials may be divided into blue, green and red light-emitting materials depending on the light-emitting color, and phosphorescent materials are used in industry for all colors other than blue.

As for the blue light-emitting material, only fluorescent materials with reduced efficiency by using only singlet are used due to limitations in lifespan and color characteristics. Accordingly, as the blue light-emitting material, phosphorescent materials using triplet by using heavy metals such as iridium or platinum and delayed fluorescent materials using triplet with only pure organic materials by reducing an energy difference between singlet and triplet are being developed.

However, although high efficiency may be achieved when using the phosphorescent material, the price of heavy metals used for obtaining phosphorescence is high, and various social problems may be caused during mining.

Unlike existing fluorescence using only singlet energy and thereby having a triplet energy loss corresponding to 75%, delayed fluorescence induces a reverse intersystem crossing (RISC) phenomenon from triplet to singlet using only room temperature heat energy by designing molecules so that an energy difference between singlet and triplet is reduced, and as a result, energy of both triplet and singlet may be utilized. Accordingly, triplet may be used without heavy metal materials as with a phosphorescent material, resulting in higher light emission efficiency of a material compared to a fluorescent material, and it is called delayed fluorescence since fluorescence emission is obtained via triplet.

Characteristics of an organic light-emitting device may depend on a dopant material of a light-emitting layer, and a delayed fluorescent dopant needs to have a small overlap between HOMO (Highest Occupied Molecular Orbital) and LUMO (Lowest Unoccupied Molecular Orbital) in order to minimize the energy difference between singlet and triplet. For this purpose, a donor-acceptor structure is mostly used, and the structure has a characteristic of allowing intra charge transfer. However, when an existing compound having a donor-acceptor structure is used as a delayed fluorescent material, the emission wavelength shifts to a long wavelength region, and there is a disadvantage that color purity is inferior due to the wide luminescence spectrum.

In order to overcome this disadvantage, ‘DABNA-1’, an existing delayed fluorescent material having a multi-resonance effect (MR-TADF), was reported. The ‘DABNA-1’ has a structure of the following Chemical Formula a.

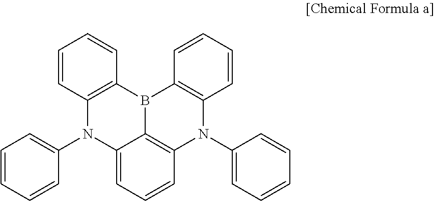 [SMILES: c1ccc(N2c3ccccc3B3c4ccccc4N(c4ccccc4)c4cccc2c43)cc1]

While an existing delayed fluorescent material having a donor-acceptor structure reduces an overlap between HOMO and LUMO by a donor monomer unit, MR-TADF separates the overlap between HOMO and LUMO by a solid intramolecular atomic unit, and in addition, there is almost no molecular distortion when the molecule is excited by light, electricity or the like, allowing to have narrow half-width characteristics. However, in the DABNA-1 structure, intermolecular packing readily occurs due to the flat molecular structure in which the ring structures are tightly bound, and there is a disadvantage of worsened color characteristics caused by a shift to a longer wavelength or widened half-width characteristics in a thin film state compared to in a solution state. For example, DABNA-1 shows narrow half-width characteristics of 21 nm in a solution state, however, when doped to an actual mCBP host by 1 wt %, there is a problem of the half-width increasing to 27 nm.

### DISCLOSURE

### Technical Problem

In view of the above, the present invention is directed to providing a boron compound having excellent quantum efficiency, and having improved color characteristics in a thin film state.

The present invention is also directed to providing an organic light-emitting device having improved color characteristics and lifespan characteristics.

### Technical Solution

In view of the above, a boron compound according to one embodiment of the present invention is represented by the following Chemical Formula 1.

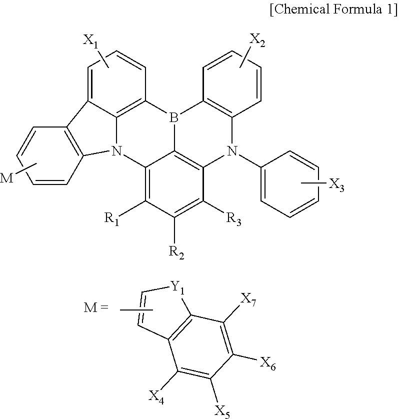

In Chemical Formula 1,

X₁ to X₇ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group, Y₁ is N-R₄, oxygen or sulfur, R₁ to R₃ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group, and R₄ is hydrogen, deuterium, a substituted or unsubstituted C₁˜C₆₀ alkyl group, a substituted or unsubstituted C₃˜C₁₀ cycloalkyl group, a substituted or unsubstituted C₆˜C₆₀ aryl group, or a substituted or unsubstituted C₆˜C₆₀ heteroaryl group.

The boron compound may specifically be represented by one of the following Chemical Formulae 2 to 126.

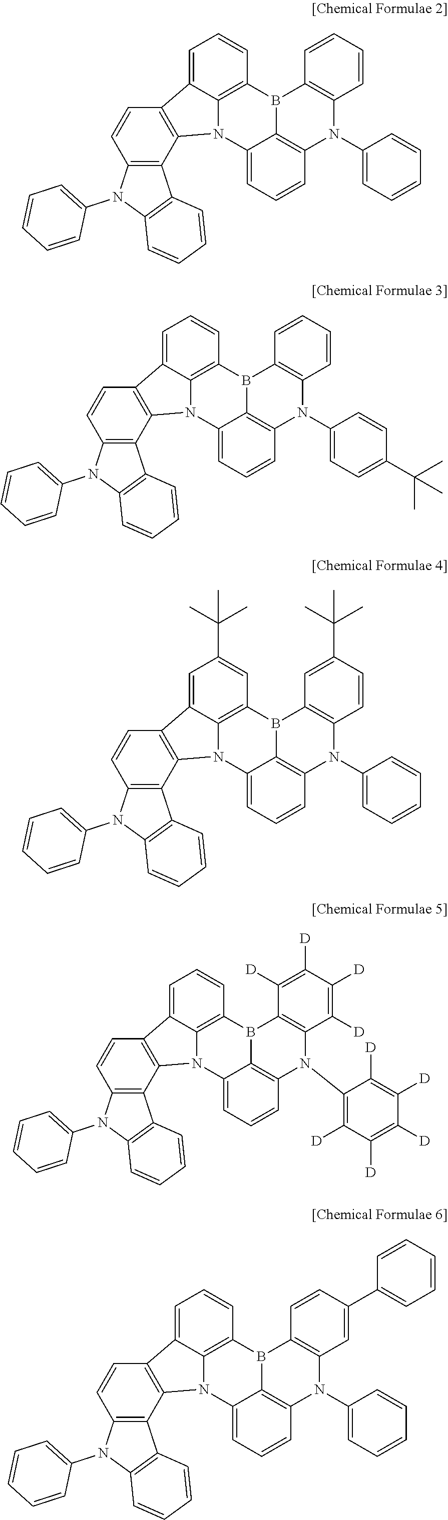 [SMILES: c1ccc(N2c3ccccc3B3c4c2cccc4-n2c4c3cccc4c3ccc4c(c5ccccc5n4-c4ccccc4)c32)cc1 ; CC(C)(C)c1ccc(N2c3ccccc3B3c4c2cccc4-n2c4c3cccc4c3ccc4c(c5ccccc5n4-c4ccccc4)c32)cc1 ; CC(C)(C)c1ccc2c(c1)B1c3c(cccc3-n3c4c1cc(C(C)(C)C)cc4c1ccc4c(c5ccccc5n4-c4ccccc4)c13)N2c1ccccc1 ; [2H]c1c([2H])c([2H])c(N2c3cccc4c3B(c3c([2H])c([2H])c([2H])c([2H])c32)c2cccc3c5ccc6c(c7ccccc7n6-c6ccccc6)c5n-4c23)c([2H])c1[2H] ; c1ccc(-c2ccc3c(c2)N(c2ccccc2)c2cccc4c2B3c2cccc3c5ccc6c(c7ccccc7n6-c6ccccc6)c5n-4c23)cc1]

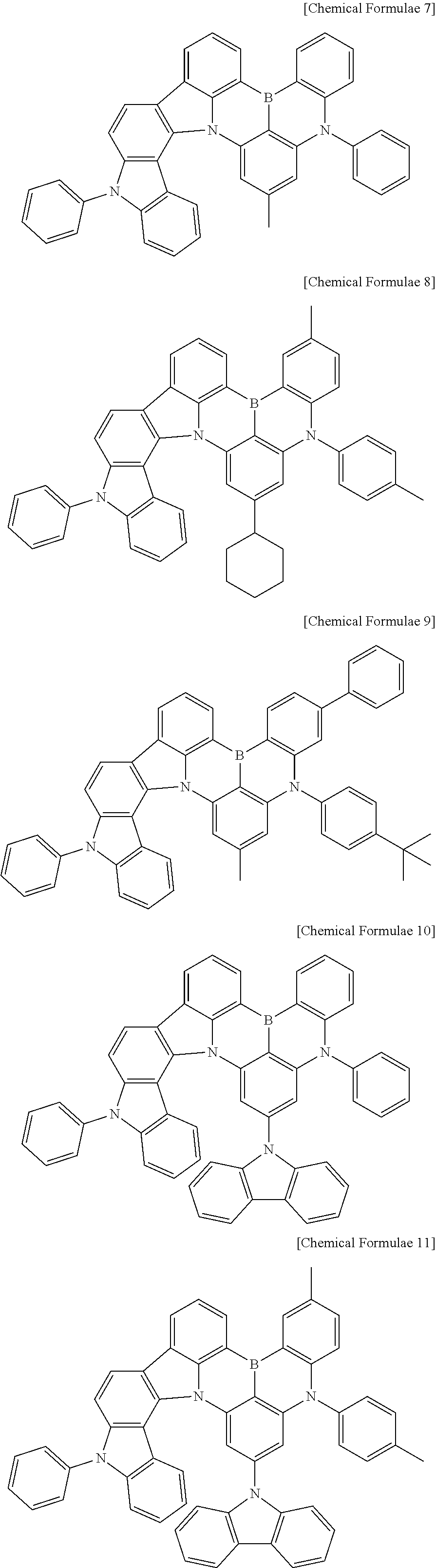

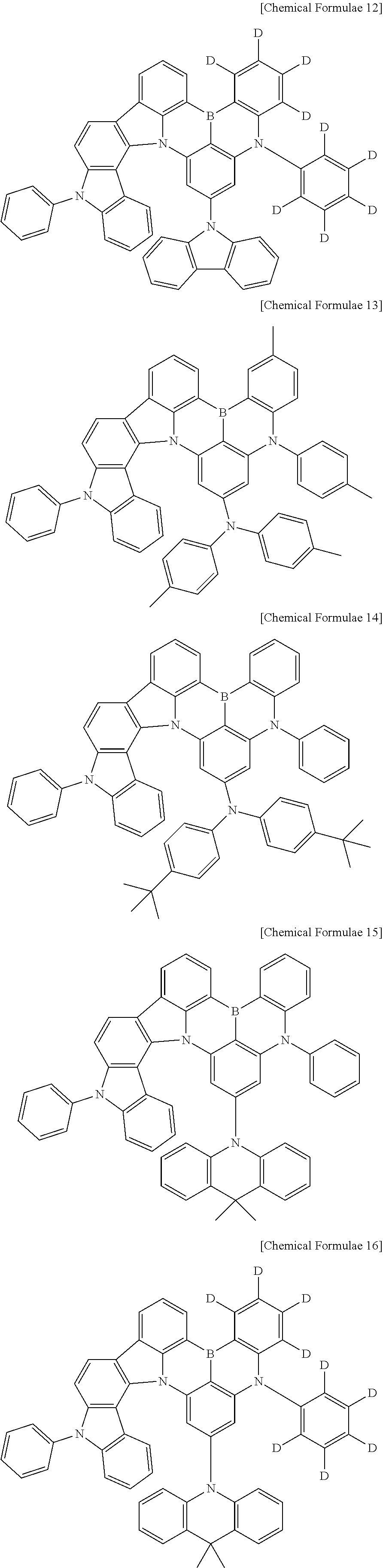

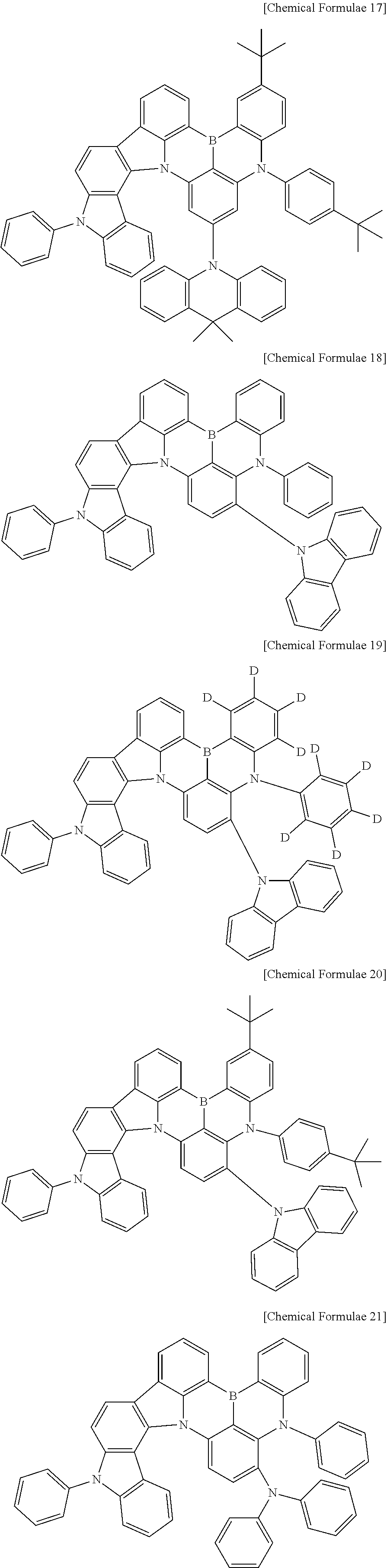

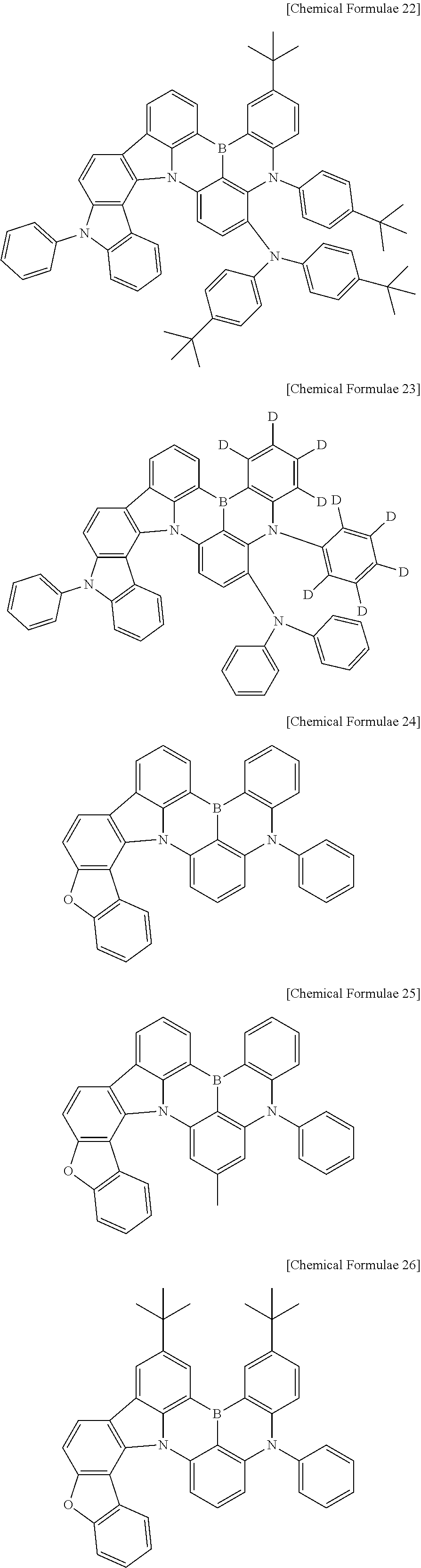

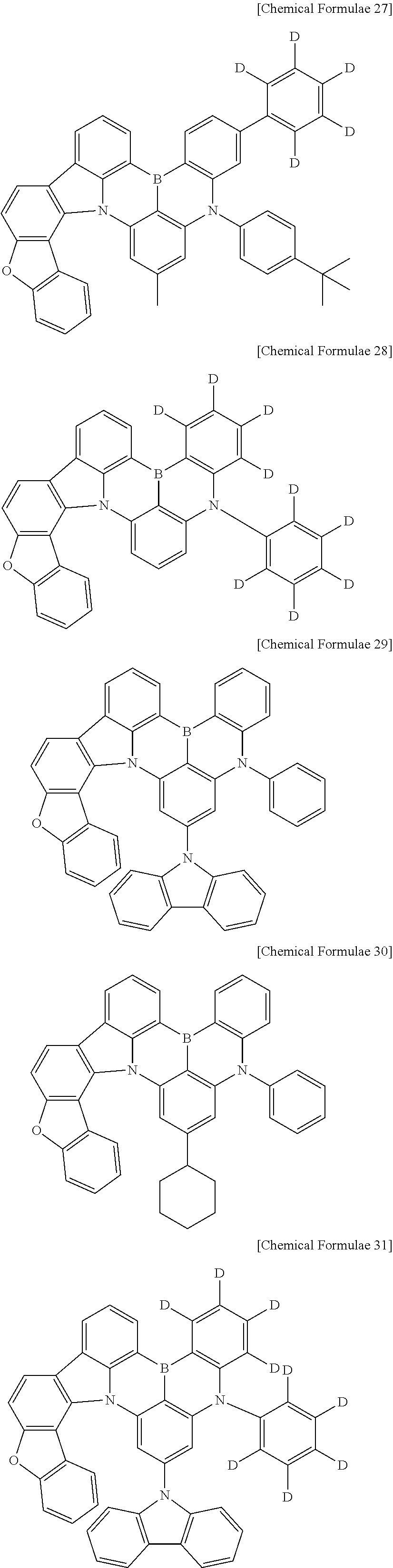

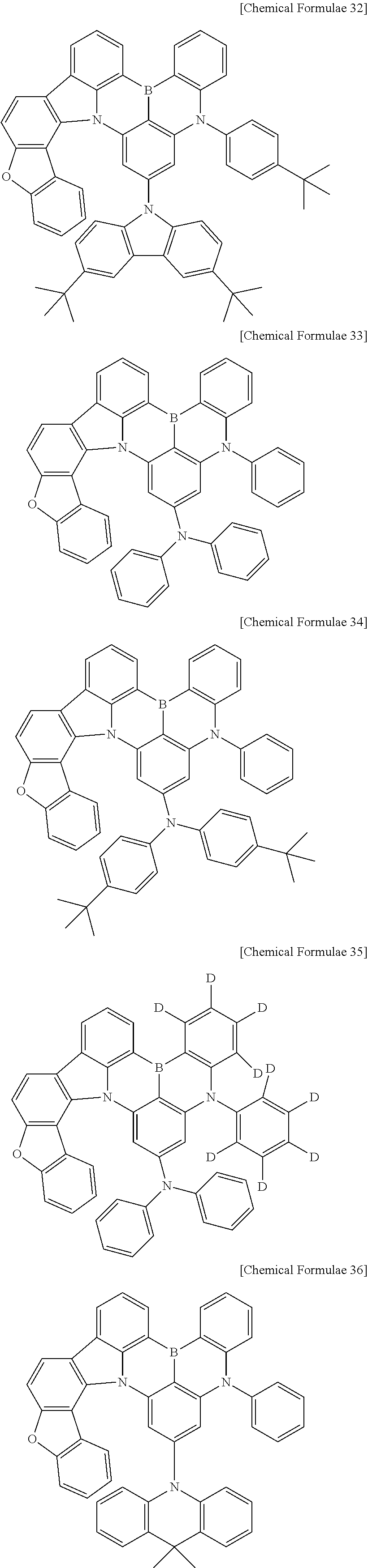

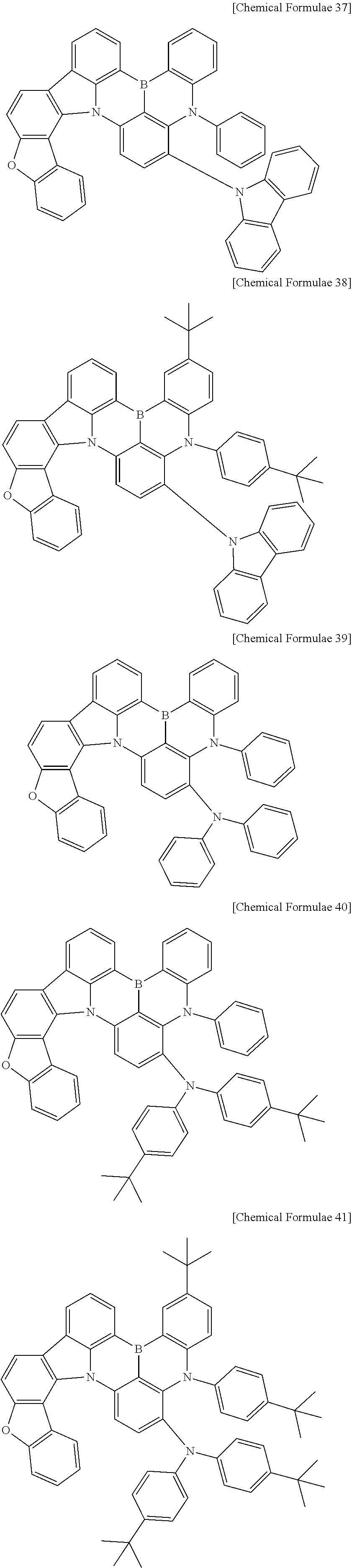

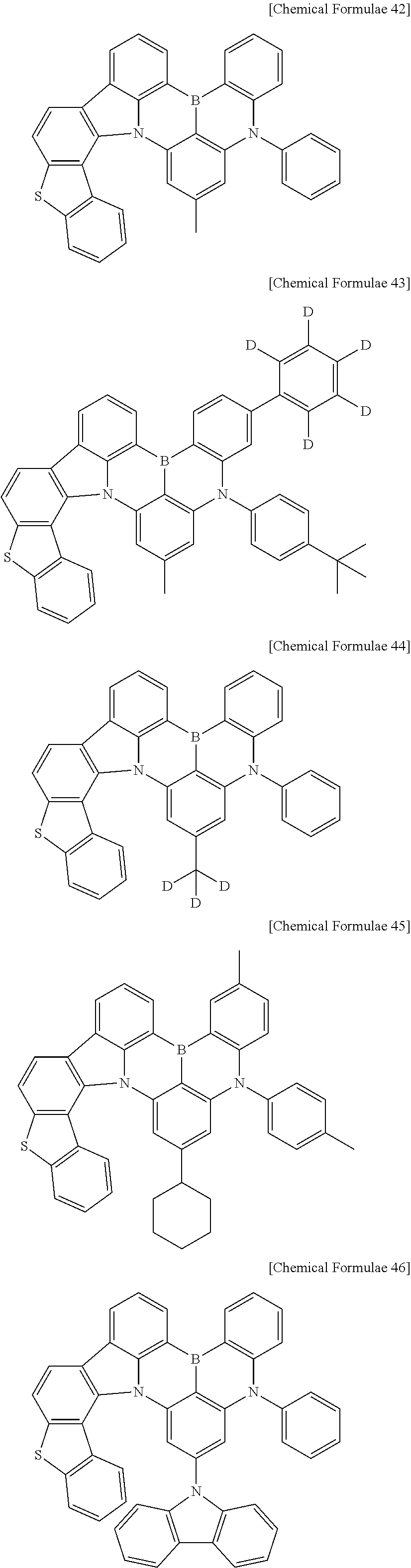 [SMILES: Cc1cc2c3c(c1)-n1c4c(cccc4c4ccc5sc6ccccc6c5c41)B3c1ccccc1N2c1ccccc1 ; [2H]c1c([2H])c([2H])c(-c2ccc3c(c2)N(c2ccc(C(C)(C)C)cc2)c2cc(C)cc4c2B3c2cccc3c5ccc6sc7ccccc7c6c5n-4c23)c([2H])c1[2H] ; [2H]C([2H])([2H])c1cc2c3c(c1)-n1c4c(cccc4c4ccc5sc6ccccc6c5c41)B3c1ccccc1N2c1ccccc1 ; Cc1ccc(N2c3ccc(C)cc3B3c4c2cc(C2CCCCC2)cc4-n2c4c3cccc4c3ccc4sc5ccccc5c4c32)cc1 ; c1ccc(N2c3ccccc3B3c4c2cc(-n2c5ccccc5c5ccccc52)cc4-n2c4c3cccc4c3ccc4sc5ccccc5c4c32)cc1]

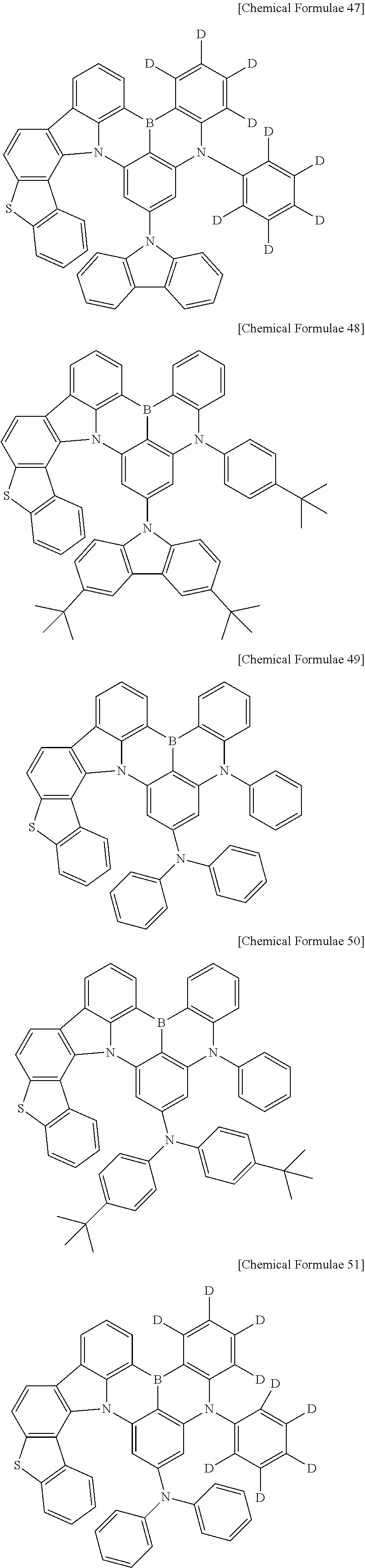

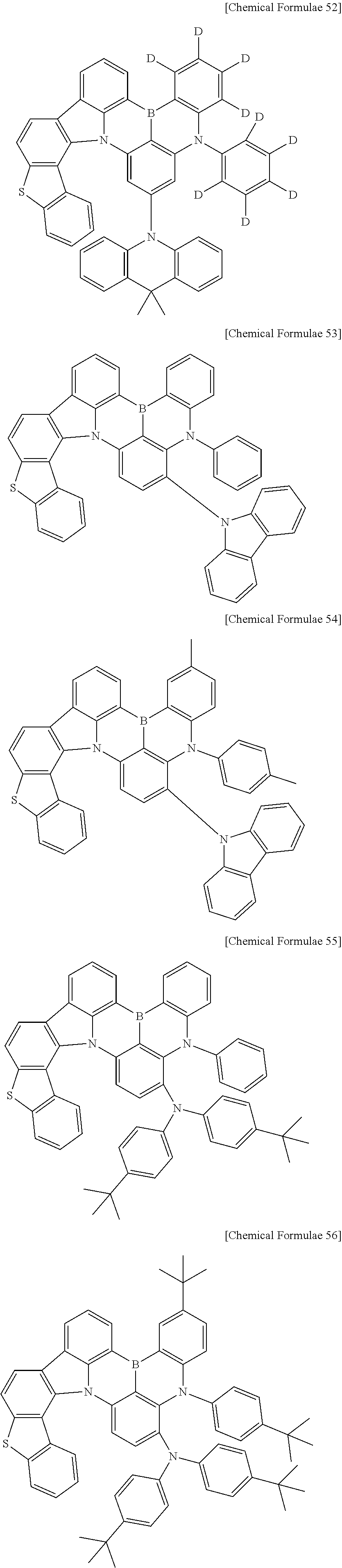

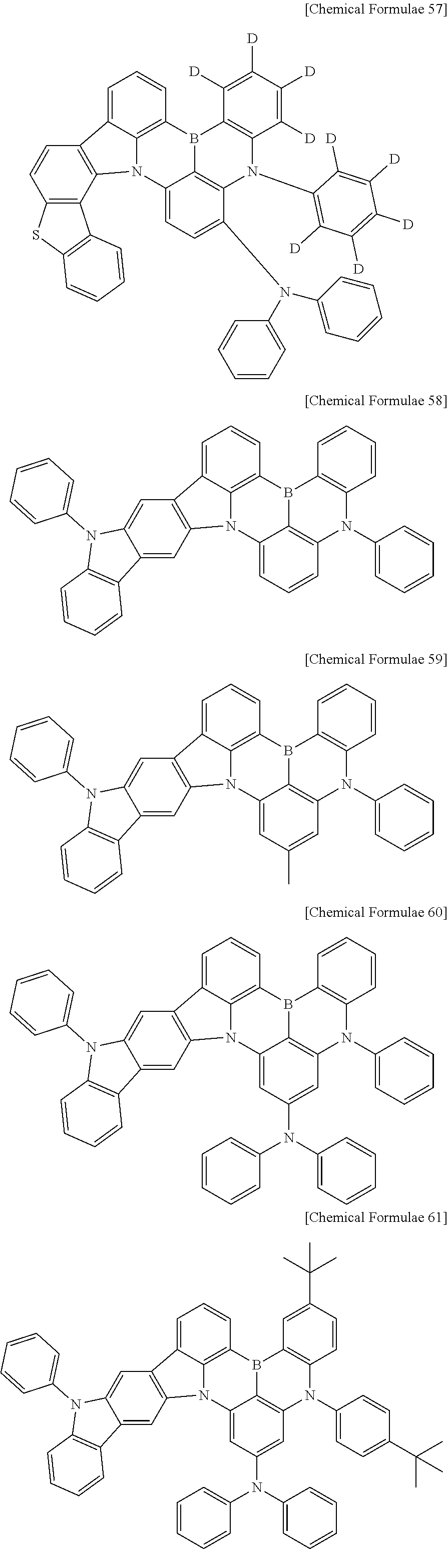

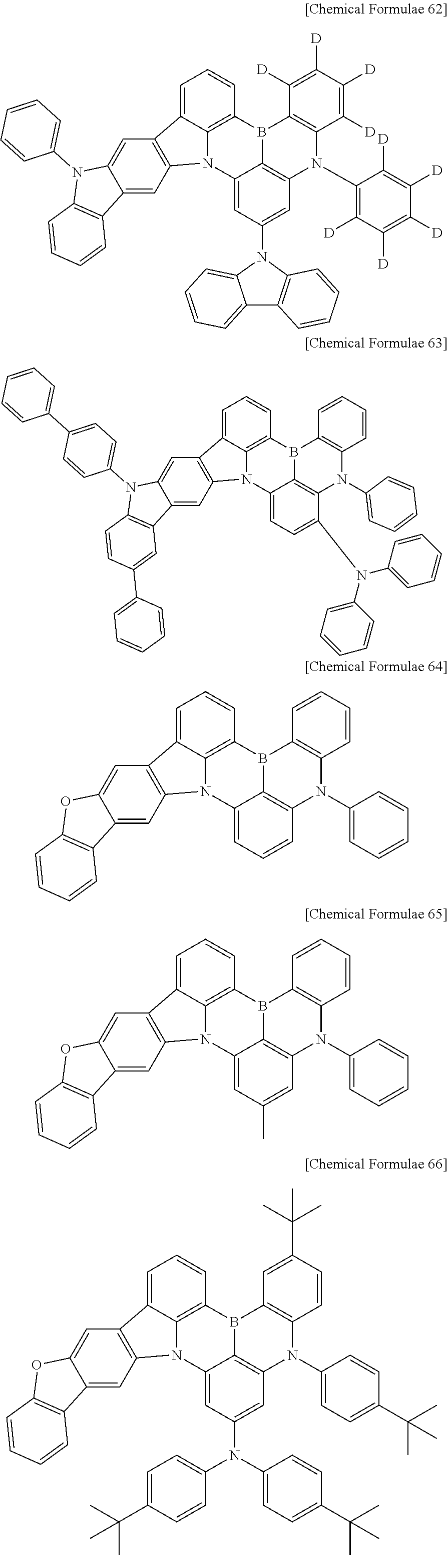

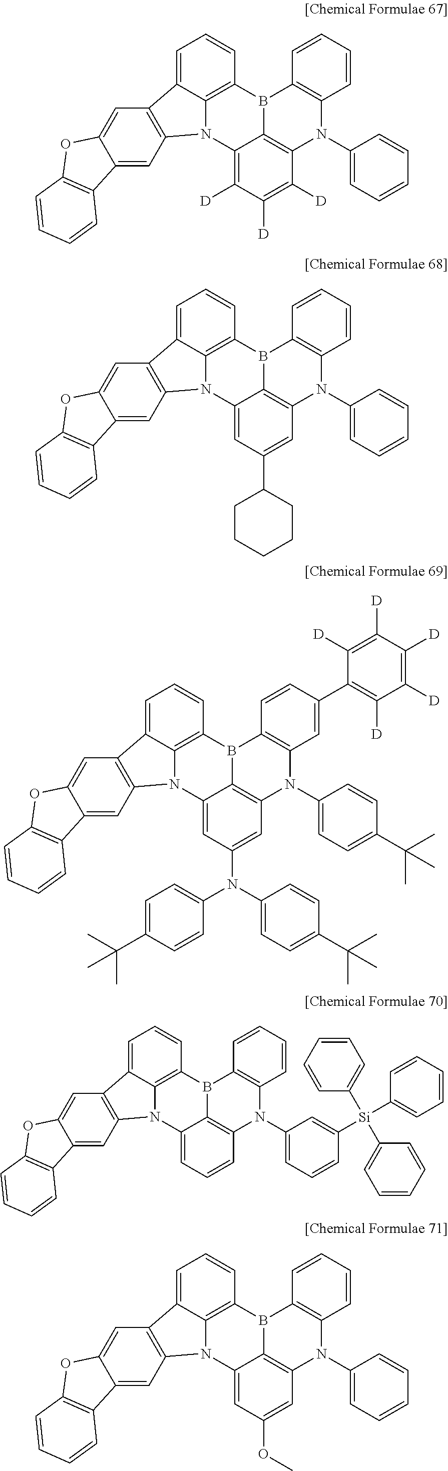 [SMILES: [2H]c1c([2H])c2c3c(c1[2H])-n1c4cc5c(cc4c4cccc(c41)B3c1ccccc1N2c1ccccc1)oc1ccccc15 ; c1ccc(N2c3ccccc3B3c4c2cc(C2CCCCC2)cc4-n2c4cc5c(cc4c4cccc3c42)oc2ccccc25)cc1 ; [2H]c1c([2H])c([2H])c(-c2ccc3c(c2)N(c2ccc(C(C)(C)C)cc2)c2cc(N(c4ccc(C(C)(C)C)cc4)c4ccc(C(C)(C)C)cc4)cc4c2B3c2cccc3c5cc6oc7ccccc7c6cc5n-4c23)c([2H])c1[2H] ; c1ccc([Si](c2ccccc2)(c2ccccc2)c2cccc(N3c4ccccc4B4c5c3cccc5-n3c5cc6c(cc5c5cccc4c53)oc3ccccc36)c2)cc1 ; COc1cc2c3c(c1)-n1c4cc5c(cc4c4cccc(c41)B3c1ccccc1N2c1ccccc1)oc1ccccc15]

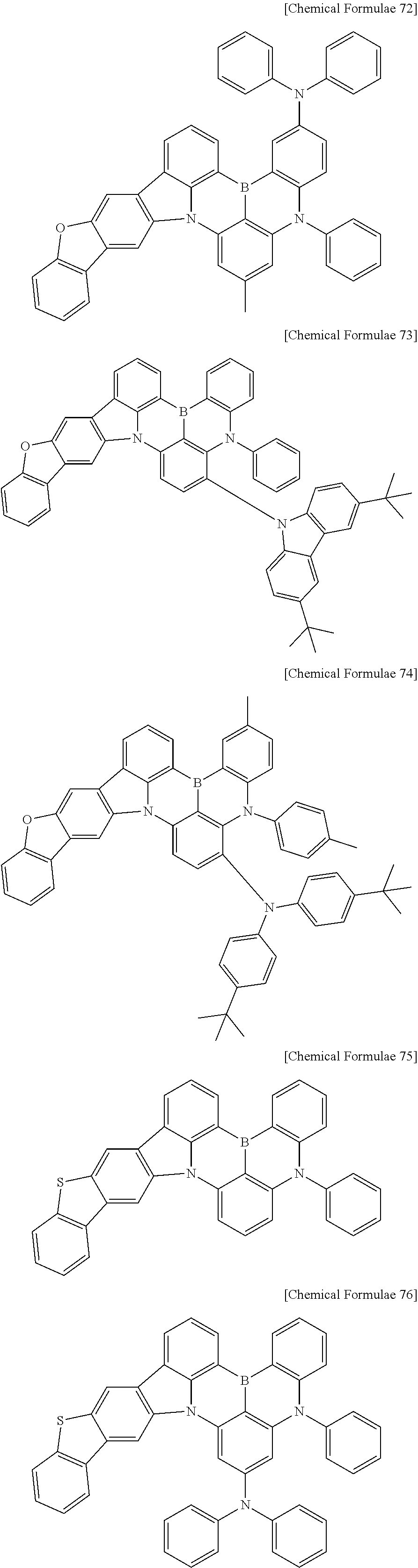 [SMILES: Cc1cc2c3c(c1)-n1c4cc5c(cc4c4cccc(c41)B3c1cc(N(c3ccccc3)c3ccccc3)ccc1N2c1ccccc1)oc1ccccc15 ; CC(C)(C)c1ccc2c(c1)c1cc(C(C)(C)C)ccc1n2-c1ccc2c3c1N(c1ccccc1)c1ccccc1B3c1cccc3c4cc5oc6ccccc6c5cc4n-2c13 ; Cc1ccc(N2c3ccc(C)cc3B3c4c(ccc(N(c5ccc(C(C)(C)C)cc5)c5ccc(C(C)(C)C)cc5)c42)-n2c4cc5c(cc4c4cccc3c42)oc2ccccc25)cc1 ; c1ccc(N2c3ccccc3B3c4c2cccc4-n2c4cc5c(cc4c4cccc3c42)sc2ccccc25)cc1 ; c1ccc(N(c2ccccc2)c2cc3c4c(c2)-n2c5cc6c(cc5c5cccc(c52)B4c2ccccc2N3c2ccccc2)sc2ccccc26)cc1]

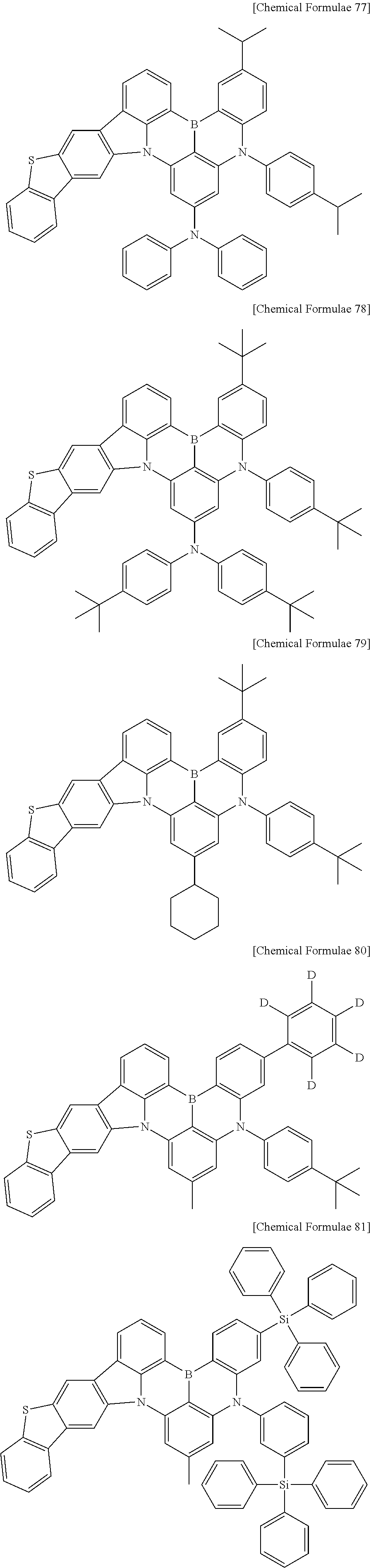

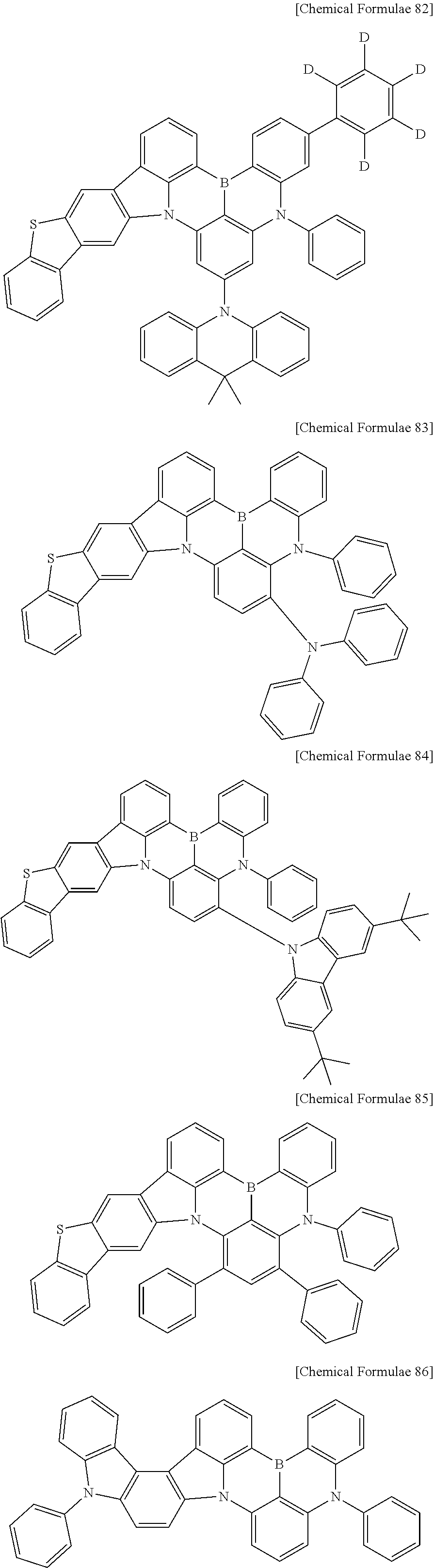

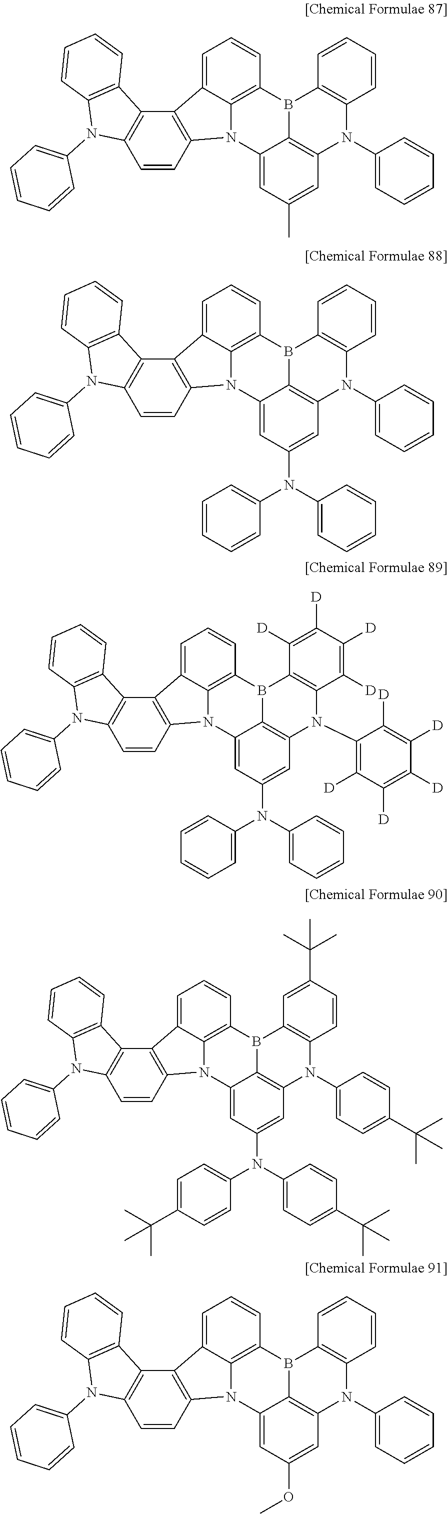

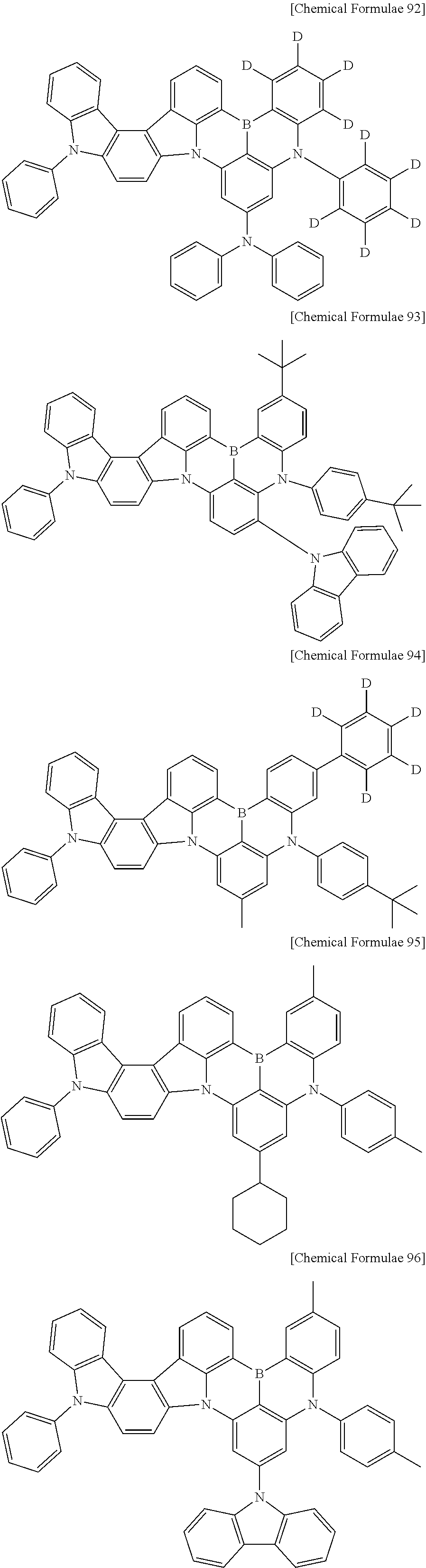

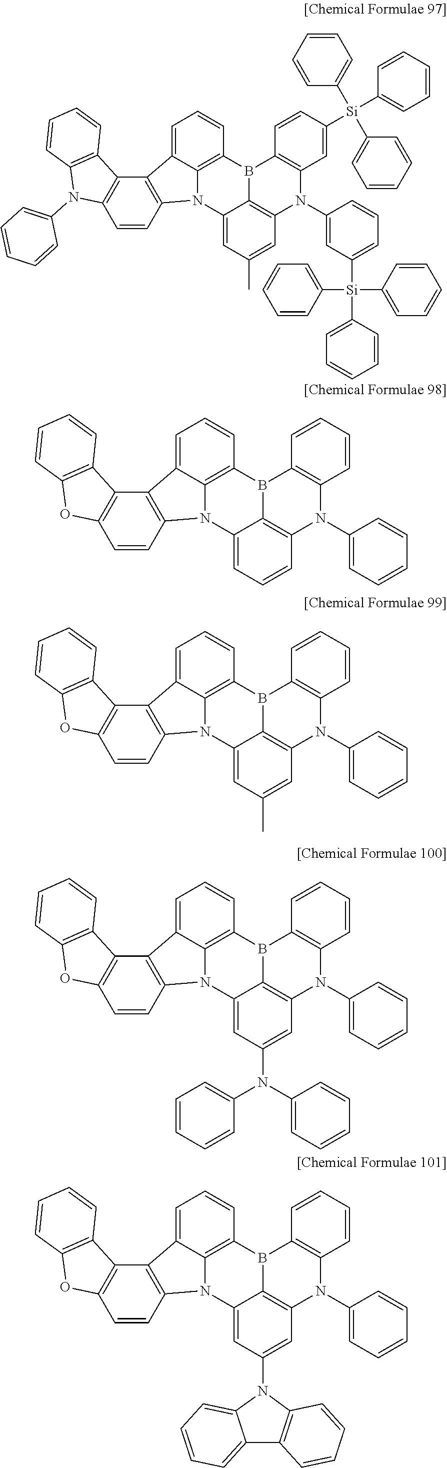

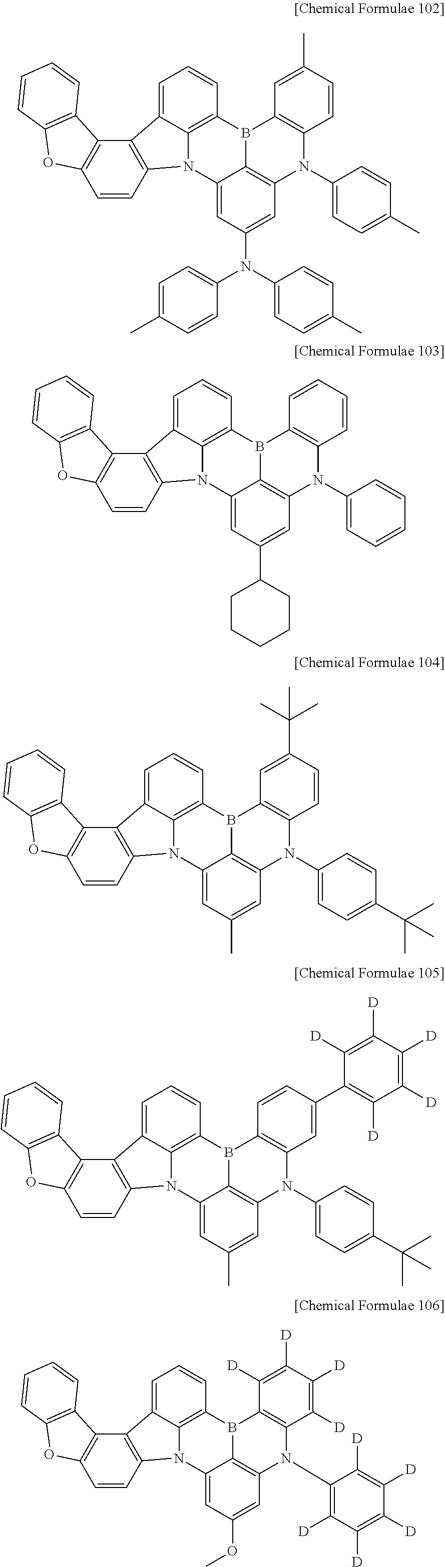

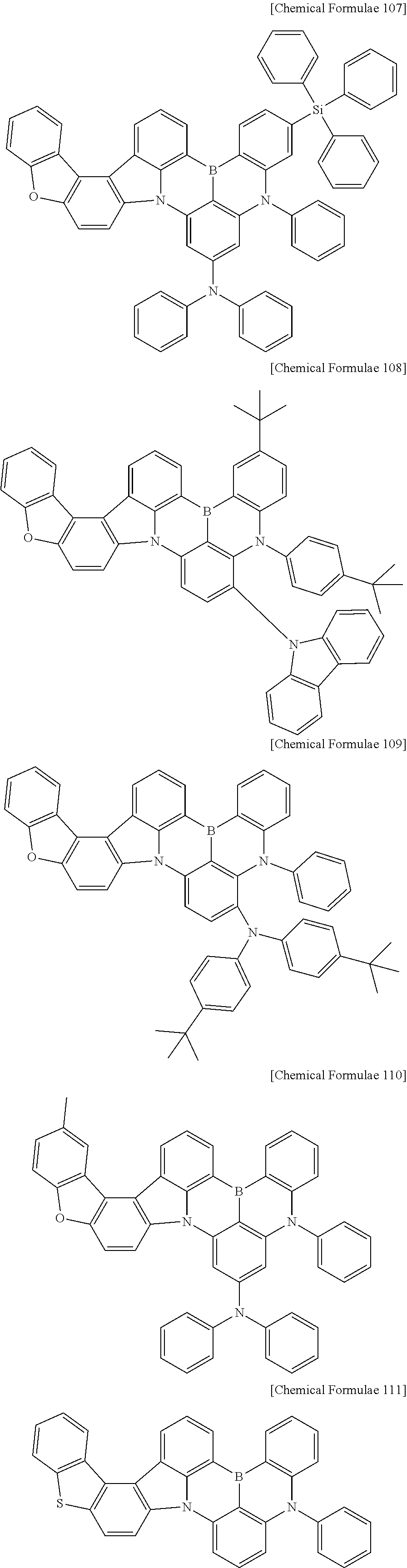

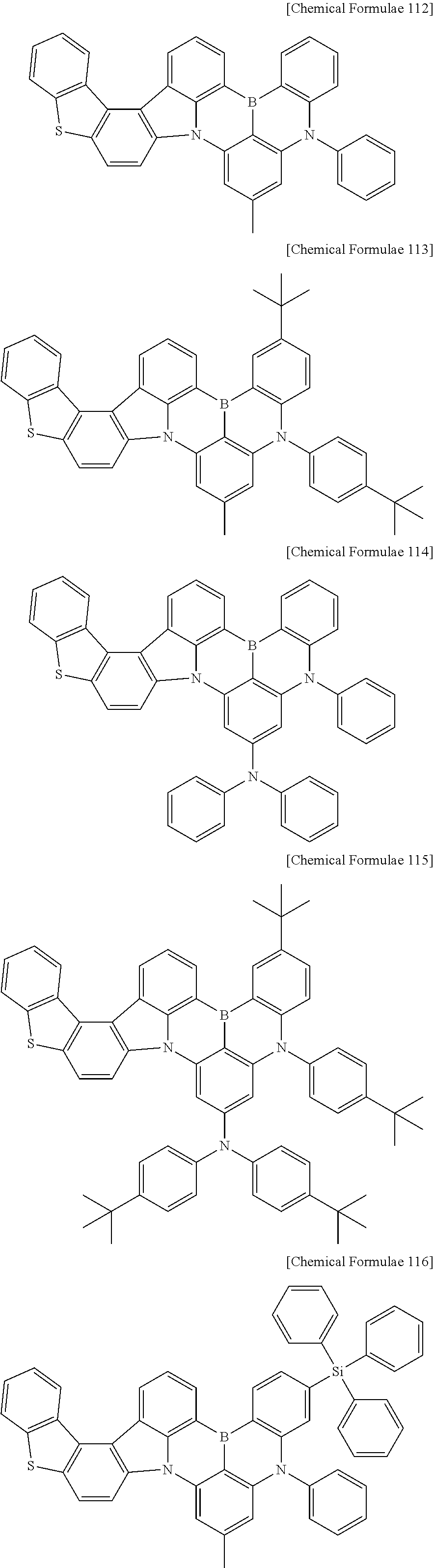

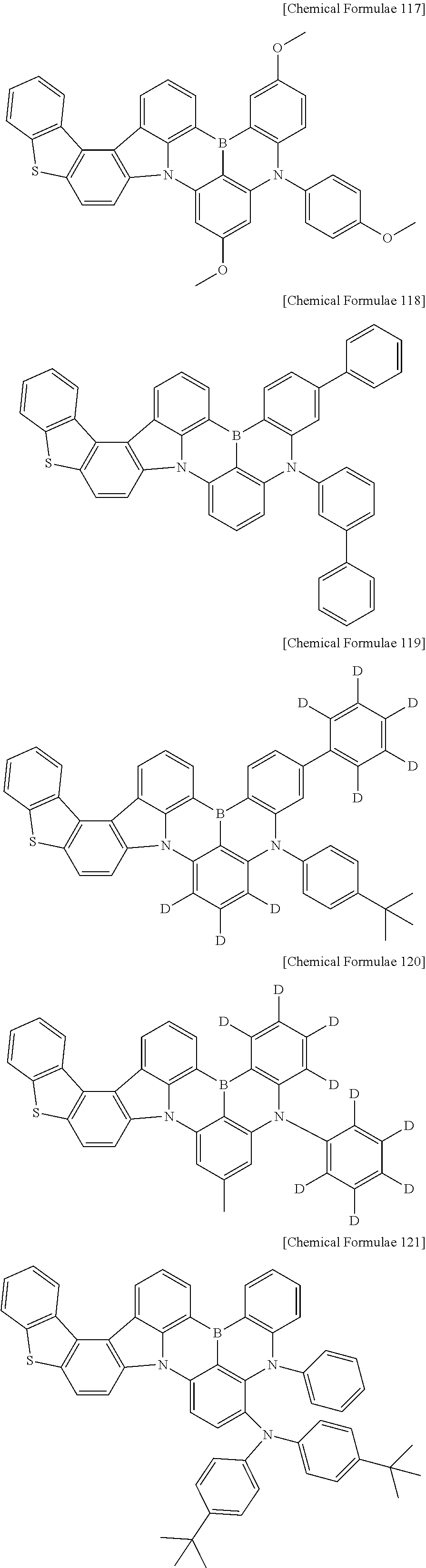

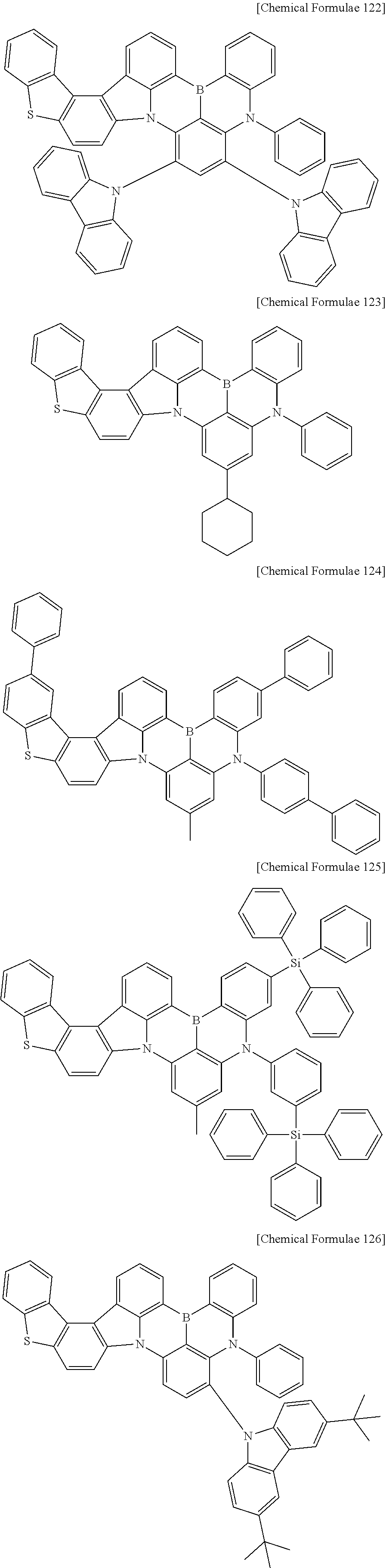

An organic light-emitting device according to another embodiment of the present invention includes a first electrode, a second electrode provided opposite to the first electrode, and an organic material layer located between the first electrode and the second electrode, wherein the organic material layer includes the boron compound.

The organic material layer may include an electron injection layer (EIL), an electron transport layer (ETL), a light-emitting layer (EML), a hole transport layer (HTL) and a hole injection layer (HIL).

The light-emitting layer may include an anthracene derivative represented by the following Chemical Formula 127 as a host compound.

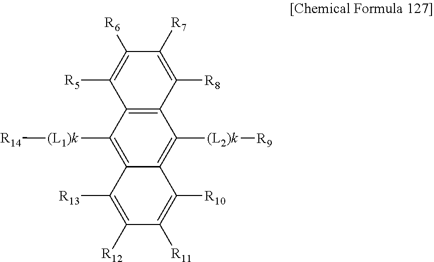

In Chemical Formula 127, R₅ to R₁₄ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group, L₁ and L₂ are each independently a single bond, a substituted or unsubstituted arylene group, or a substituted or unsubstituted heteroarylene group, and ks are each independently an integer of 1 to 3.

In addition, the light-emitting layer includes a host compound, a first dopant compound and a second dopant compound, and the second dopant compound is a delayed fluorescent material or a phosphorescent material, and the first dopant compound may include the boron compound.

The delayed fluorescent material of the second dopant compound is a material having an electron donating-electron accepting structure, and the material having an electron donating-electron accepting structure may use one or more of a boron compound, a triazine, a cyano group and a sulfone group as the electron acceptor and one or more of a carbazole derivative and an acridane derivative as the electron donor, and the phosphorescent material of the second dopant compound may include one or more types of heavy metals among Ir, Pt and Pd.

The host compound may include one or more of mCP, mCBP, mCBP-CN, 2CzPy, DBFPO, DPEPO, DDBFT and pSiTrz, and may include two or more types of different host compounds.

A display apparatus according to still another embodiment of the present invention includes the organic light-emitting device.

A lighting apparatus according to yet another embodiment of the present invention includes the organic light-emitting device.

### Advantageous Effects

A boron compound of the present invention reduces intermolecular packing characteristics using a specific substituent, and is effective in improving color characteristics in a device in a thin-film state while increasing quantum efficiency. In addition, an organic light-emitting device of the present invention is effective in improving color characteristics and lifespan characteristics by using the boron compound having improved stability through the substituent bond.

### BRIEF DESCRIPTION OF DRAWINGS

FIG. 1a shows color characteristics of Example 1 of a boron compound of the present invention, and FIG. 1b shows exciton lifespan characteristics of Example 1 of the boron compound of the present invention.

FIG. 2a shows color characteristics of Example 2 of a boron compound of the present invention, and FIG. 2b shows exciton lifespan characteristics of Example 2 of the boron compound of the present invention.

FIG. 3a shows color characteristics of Example 3 of a boron compound of the present invention, and FIG. 3b shows exciton lifespan characteristics of Example 3 of the boron compound of the present invention.

FIG. 4a shows color characteristics of Example 4 of a boron compound of the present invention, and FIG. 4b shows exciton lifespan characteristics of Example 4 of the boron compound of the present invention.

### BEST MODE

Hereinafter, the present invention will be described in detail with reference to drawings.

Prior thereto, terms or words used in the present specification and claims are not to be interpreted limitedly to common or dictionary meanings, and shall be interpreted as meanings and concepts corresponding to technical ideas of the present invention based on a principle in which inventors may suitably define the concept of terms in order to describe their invention in the best possible way.

Accordingly, embodiments described in the present specification and constitutions illustrated in the drawings are just most preferred one embodiment of the present invention, and do not represent all technical ideas of the present invention, and therefore, it needs to be understood that, at the time of filing of this application, there may be various equivalents and modified examples capable of replacing these.

A boron compound according to one aspect of the present invention is represented by the following Chemical Formula 1.

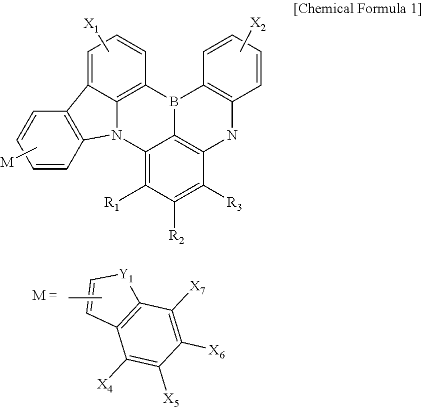

In Chemical Formula 1, X₁ to X₇ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group, Y₁ is N—R₄, oxygen or sulfur, R₁ to R₃ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁-C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group, and R₄ is hydrogen, deuterium, a substituted or unsubstituted C₁˜C₆₀ alkyl group, a substituted or unsubstituted C₃˜C₁₀ cycloalkyl group, a substituted or unsubstituted C₆˜C₆₀ aryl group, or a substituted or unsubstituted C₆˜C₆₀ heteroaryl group.

The boron compound represented by Chemical Formula 1 is capable of preventing intermolecular interactions by increasing the intermolecular distance through attaching a rotating body or a bulky aromatic ring substituent to the end of the molecule in order to reduce an intermolecular packing phenomenon.

When a light-emitting compound of an organic light-emitting device exhibits intermolecular packing characteristics, a self-quenching phenomenon occurs, lowering quantum efficiency, and therefore, the boron compound represented by Chemical Formula 1 may have a substituent attached thereto in order to obtain the effect of increasing quantum efficiency. Specifically, when the boron core inner structure, which affects color characteristics, is transformed into a carbazole form having only one side substituted with a heteroatom aromatic ring such as indole, furan or thiophene, while attaching a substituent capable of disrupting intermolecular packing at the para position of boron, which does not significantly affect color characteristics, the molecular structure exists in a distorted form while maintaining dark blue color characteristics, which may significantly reduce intermolecular packing. In addition, due to the increased conjugation length compared to before, effects of improving molecular stability and increasing quantum efficiency as well may be obtained.

The boron compound represented by Chemical Formula 1 may be, as a specific example, represented by one of the following Chemical Formulae 2 to 126.

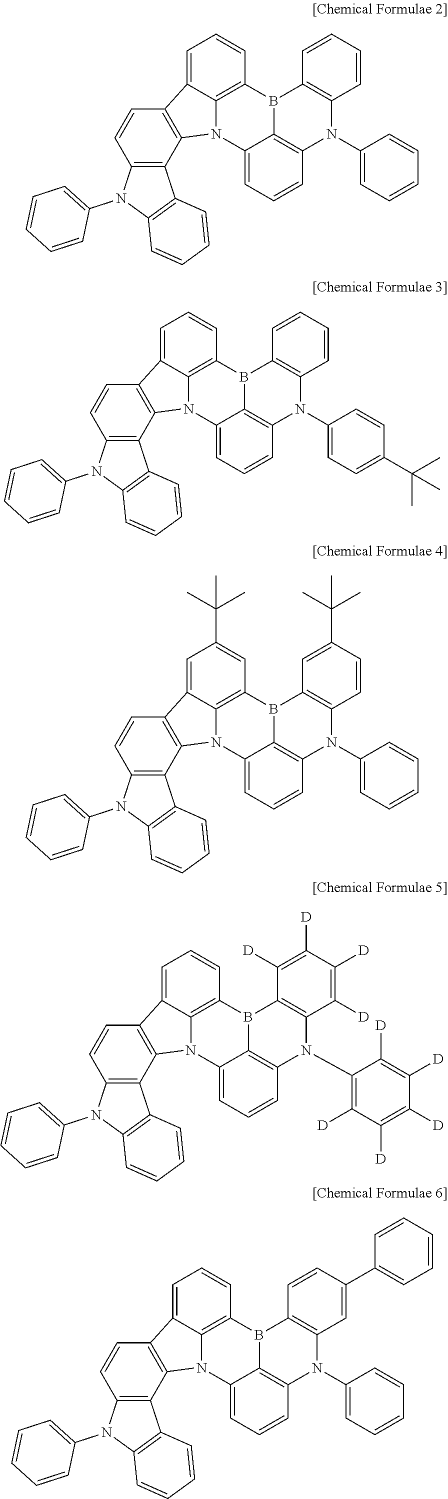 [SMILES: c1ccc(N2c3ccccc3B3c4c2cccc4-n2c4c3cccc4c3ccc4c(c5ccccc5n4-c4ccccc4)c32)cc1 ; CC(C)(C)c1ccc(N2c3ccccc3B3c4c2cccc4-n2c4c3cccc4c3ccc4c(c5ccccc5n4-c4ccccc4)c32)cc1 ; CC(C)(C)c1ccc2c(c1)B1c3c(cccc3-n3c4c1cc(C(C)(C)C)cc4c1ccc4c(c5ccccc5n4-c4ccccc4)c13)N2c1ccccc1 ; [2H]c1c([2H])c([2H])c(N2c3cccc4c3B(c3c([2H])c([2H])c([2H])c([2H])c32)c2cccc3c5ccc6c(c7ccccc7n6-c6ccccc6)c5n-4c23)c([2H])c1[2H] ; c1ccc(-c2ccc3c(c2)N(c2ccccc2)c2cccc4c2B3c2cccc3c5ccc6c(c7ccccc7n6-c6ccccc6)c5n-4c23)cc1]

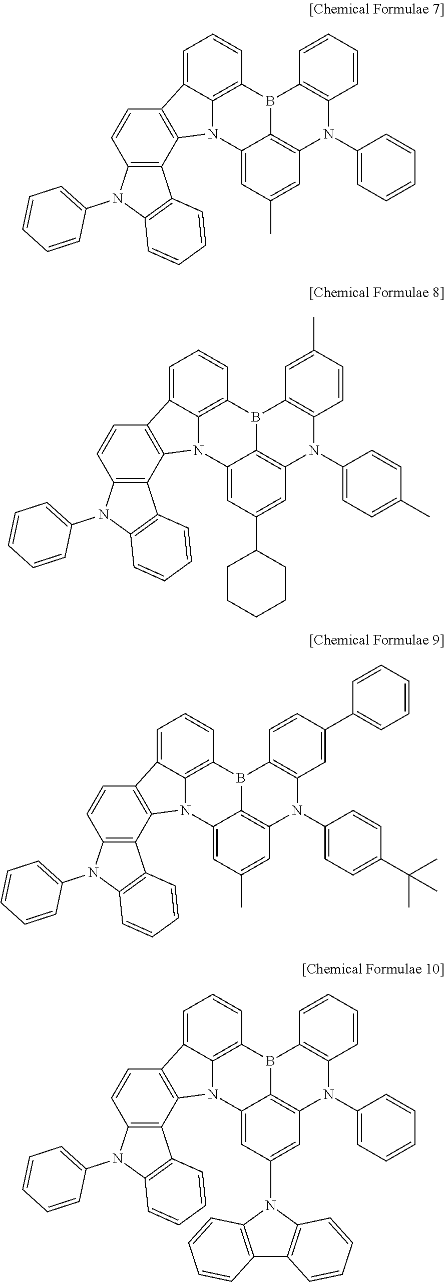 [SMILES: Cc1cc2c3c(c1)-n1c4c(cccc4c4ccc5c(c6ccccc6n5-c5ccccc5)c41)B3c1ccccc1N2c1ccccc1 ; Cc1ccc(N2c3ccc(C)cc3B3c4c2cc(C2CCCCC2)cc4-n2c4c3cccc4c3ccc4c(c5ccccc5n4-c4ccccc4)c32)cc1 ; Cc1cc2c3c(c1)-n1c4c(cccc4c4ccc5c(c6ccccc6n5-c5ccccc5)c41)B3c1ccc(-c3ccccc3)cc1N2c1ccc(C(C)(C)C)cc1 ; c1ccc(N2c3ccccc3B3c4c2cc(-n2c5ccccc5c5ccccc52)cc4-n2c4c3cccc4c3ccc4c(c5ccccc5n4-c4ccccc4)c32)cc1]

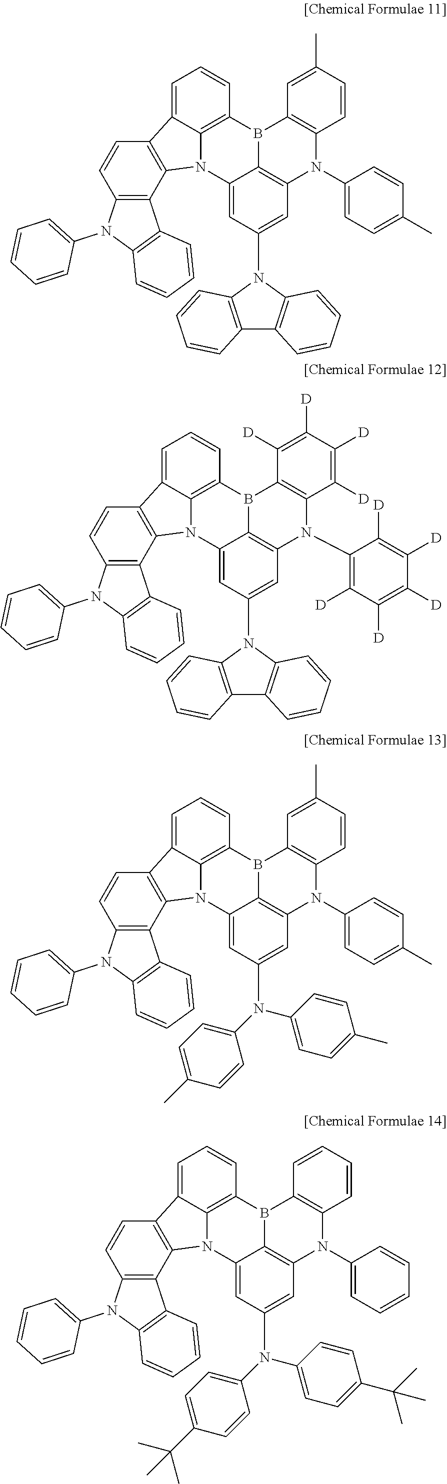

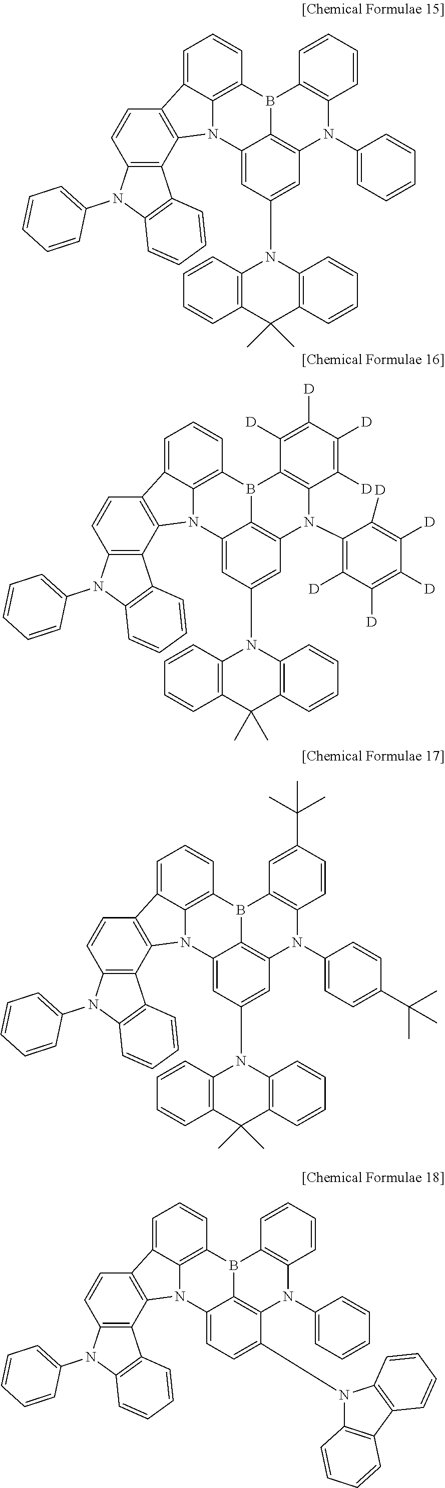

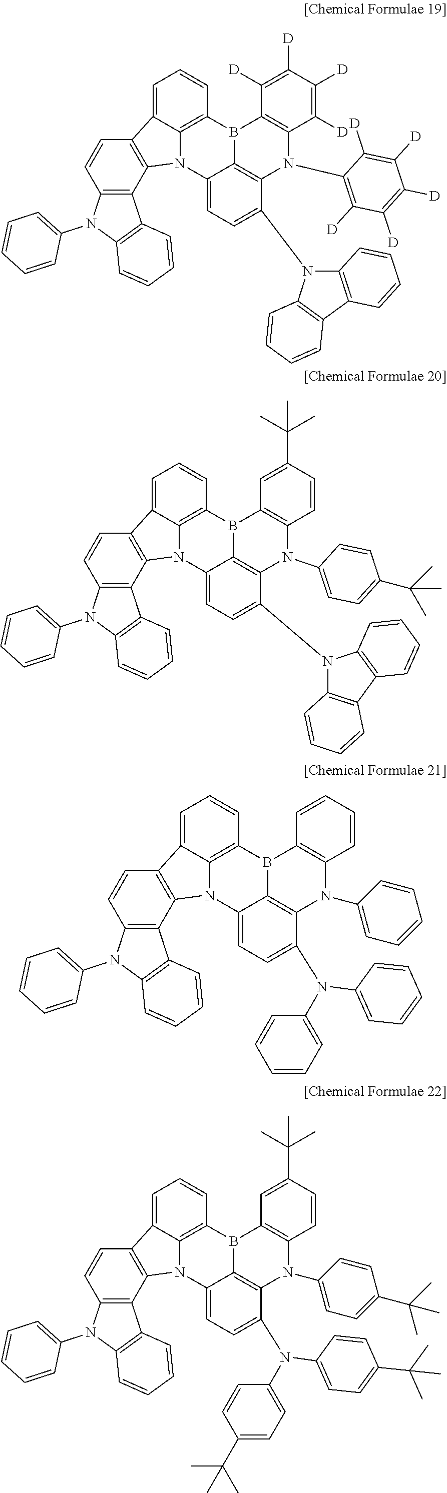

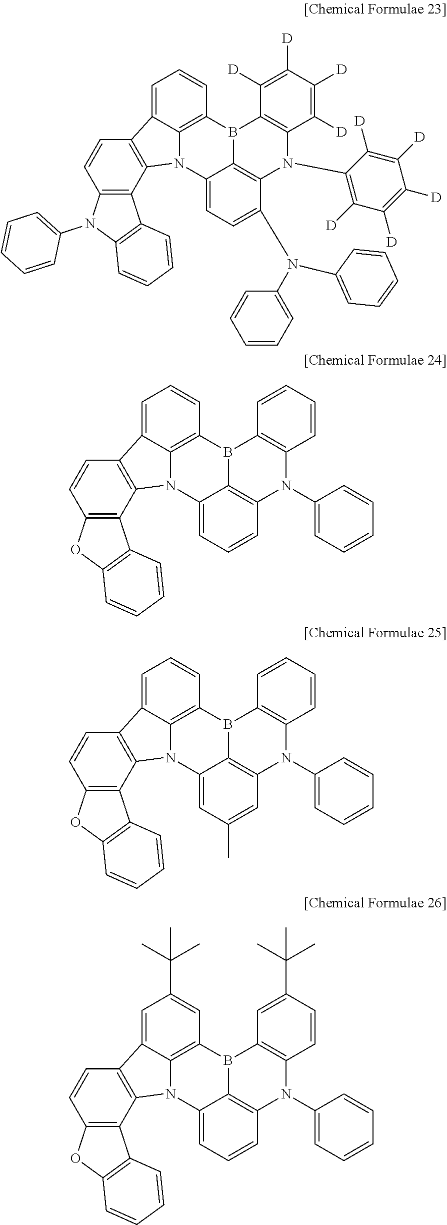

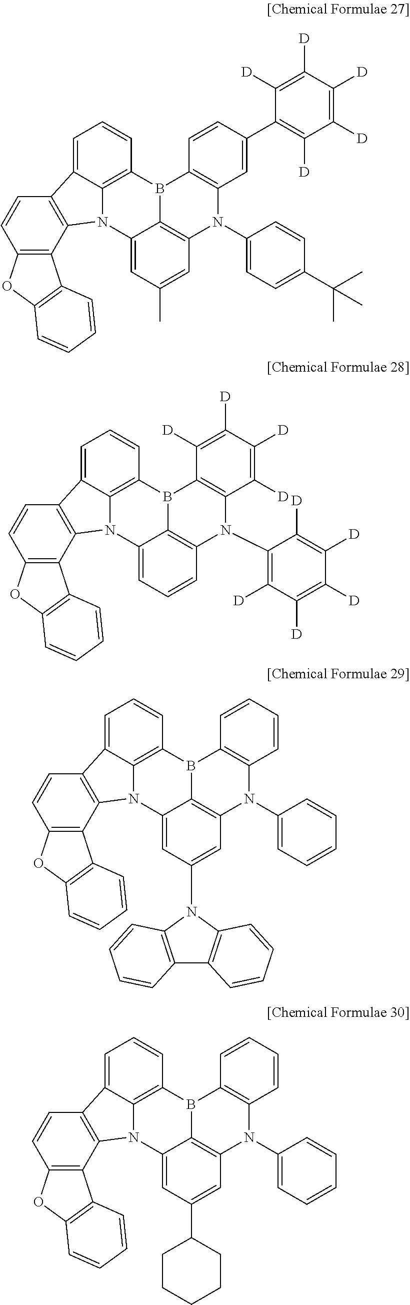 [SMILES: [2H]c1c([2H])c([2H])c(-c2ccc3c(c2)N(c2ccc(C(C)(C)C)cc2)c2cc(C)cc4c2B3c2cccc3c5ccc6oc7ccccc7c6c5n-4c23)c([2H])c1[2H] ; [2H]c1c([2H])c([2H])c(N2c3cccc4c3B(c3c([2H])c([2H])c([2H])c([2H])c32)c2cccc3c5ccc6oc7ccccc7c6c5n-4c23)c([2H])c1[2H] ; c1ccc(N2c3ccccc3B3c4c2cc(-n2c5ccccc5c5ccccc52)cc4-n2c4c3cccc4c3ccc4oc5ccccc5c4c32)cc1 ; c1ccc(N2c3ccccc3B3c4c2cc(C2CCCCC2)cc4-n2c4c3cccc4c3ccc4oc5ccccc5c4c32)cc1]

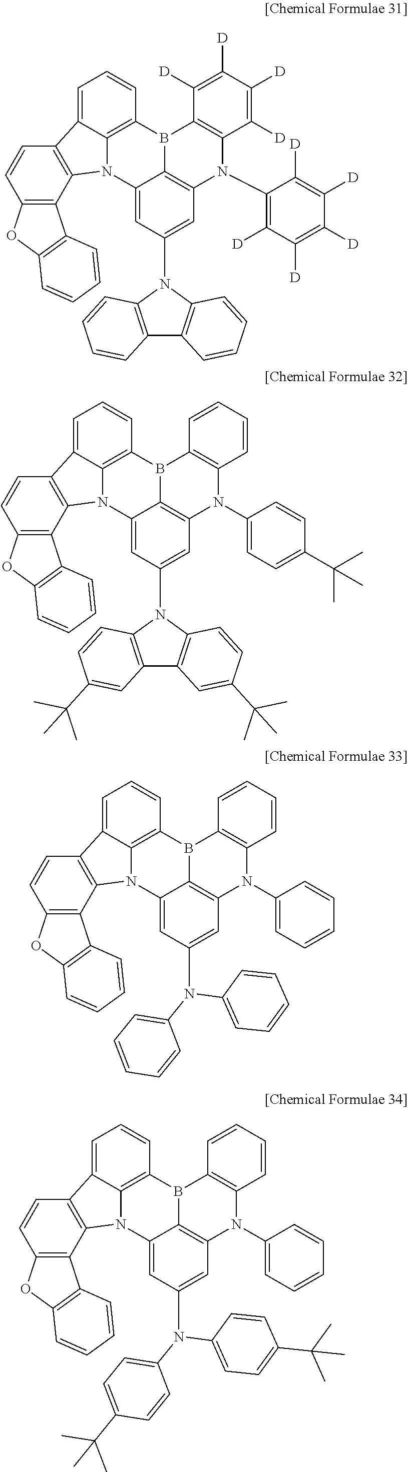

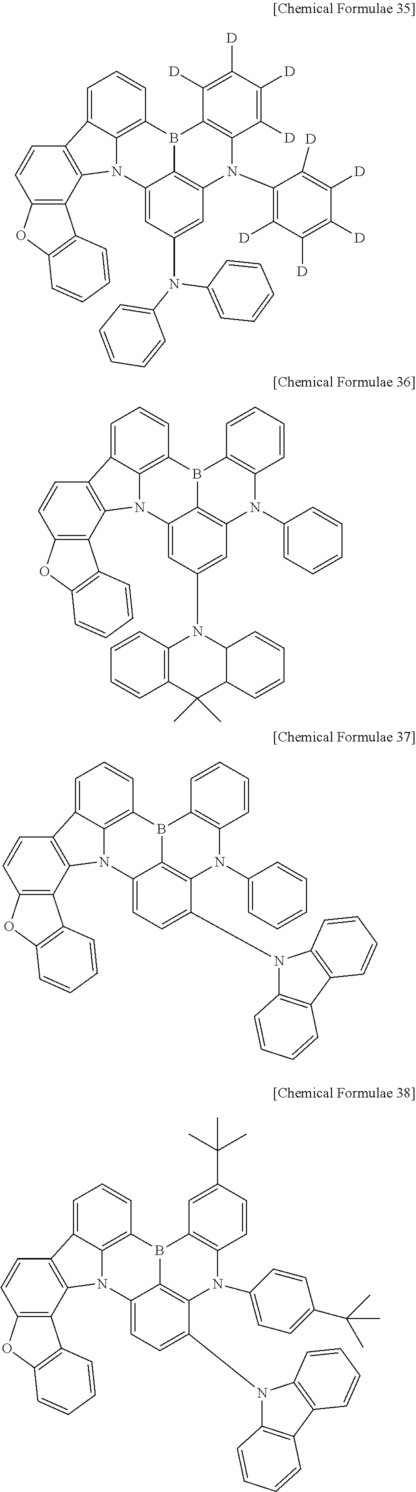

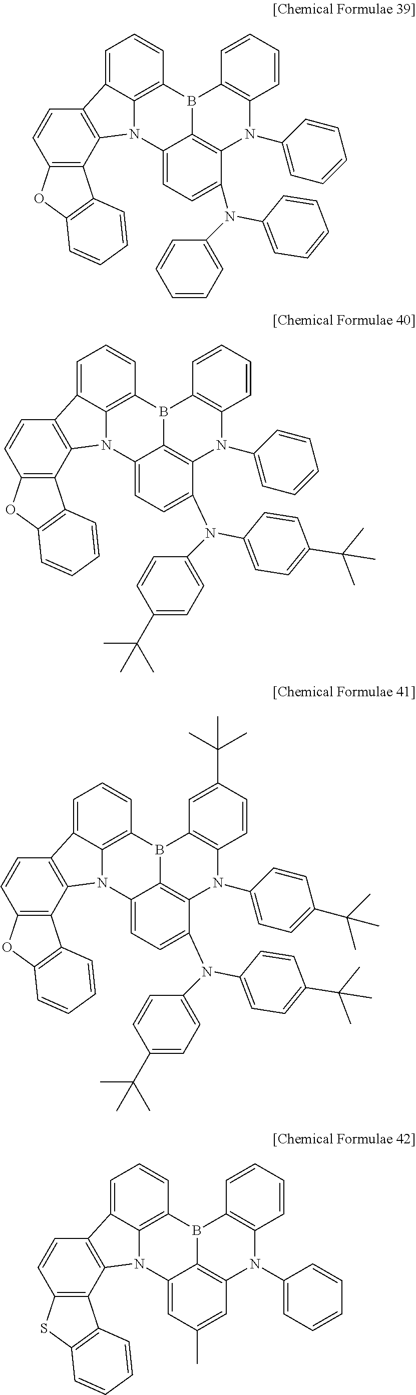 [SMILES: c1ccc(N(c2ccccc2)c2ccc3c4c2N(c2ccccc2)c2ccccc2B4c2cccc4c5ccc6oc7ccccc7c6c5n-3c24)cc1 ; CC(C)(C)c1ccc(N(c2ccc(C(C)(C)C)cc2)c2ccc3c4c2N(c2ccccc2)c2ccccc2B4c2cccc4c5ccc6oc7ccccc7c6c5n-3c24)cc1 ; CC(C)(C)c1ccc(N(c2ccc(C(C)(C)C)cc2)c2ccc3c4c2N(c2ccc(C(C)(C)C)cc2)c2ccc(C(C)(C)C)cc2B4c2cccc4c5ccc6oc7ccccc7c6c5n-3c24)cc1 ; Cc1cc2c3c(c1)-n1c4c(cccc4c4ccc5sc6ccccc6c5c41)B3c1ccccc1N2c1ccccc1]

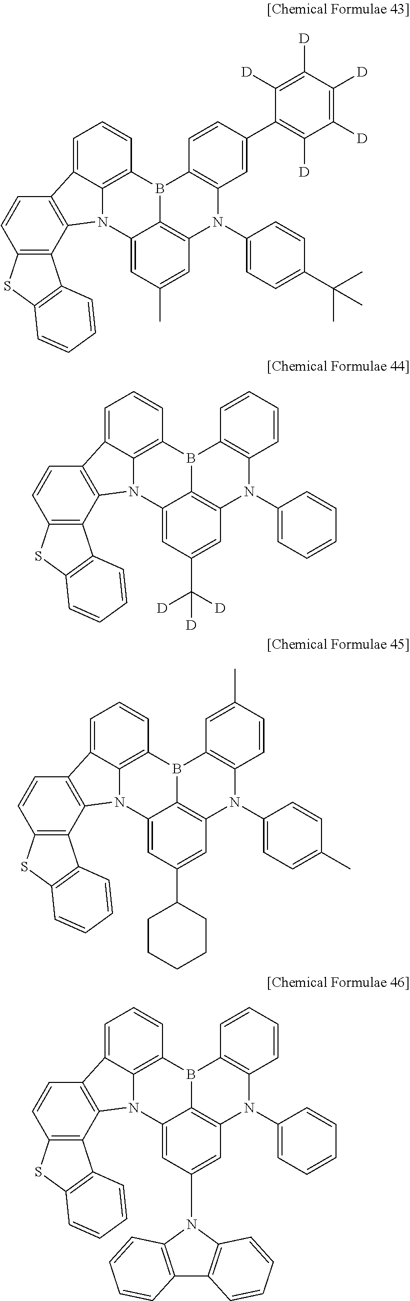 [SMILES: [2H]c1c([2H])c([2H])c(-c2ccc3c(c2)N(c2ccc(C(C)(C)C)cc2)c2cc(C)cc4c2B3c2cccc3c5ccc6sc7ccccc7c6c5n-4c23)c([2H])c1[2H] ; [2H]C([2H])([2H])c1cc2c3c(c1)-n1c4c(cccc4c4ccc5sc6ccccc6c5c41)B3c1ccccc1N2c1ccccc1 ; Cc1ccc(N2c3ccc(C)cc3B3c4c2cc(C2CCCCC2)cc4-n2c4c3cccc4c3ccc4sc5ccccc5c4c32)cc1 ; c1ccc(N2c3ccccc3B3c4c2cc(-n2c5ccccc5c5ccccc52)cc4-n2c4c3cccc4c3ccc4sc5ccccc5c4c32)cc1]

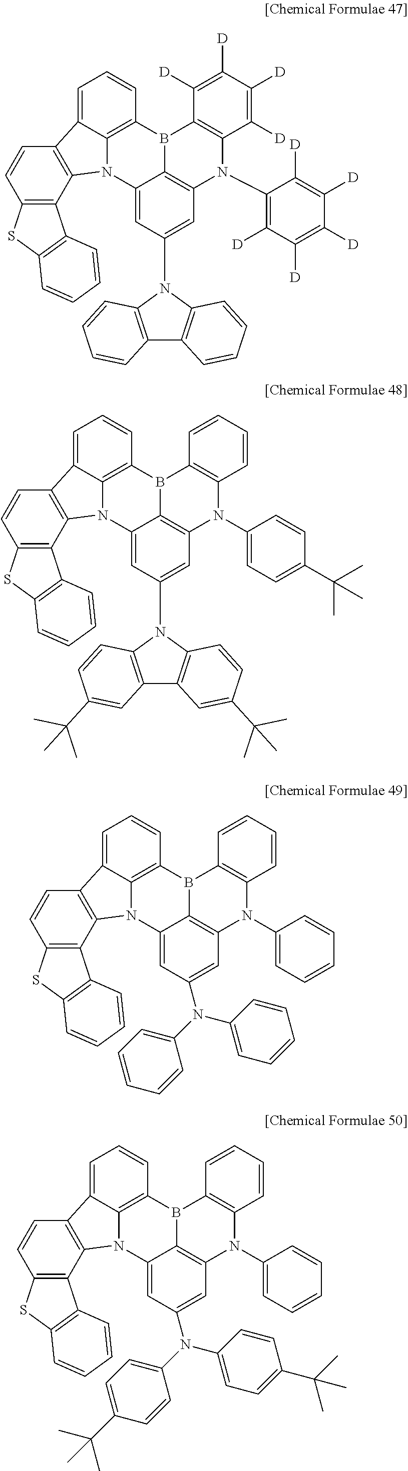 [SMILES: [2H]c1c([2H])c([2H])c(N2c3cc(-n4c5ccccc5c5ccccc54)cc4c3B(c3c([2H])c([2H])c([2H])c([2H])c32)c2cccc3c5ccc6sc7ccccc7c6c5n-4c23)c([2H])c1[2H] ; CC(C)(C)c1ccc(N2c3ccccc3B3c4c2cc(-n2c5ccc(C(C)(C)C)cc5c5cc(C(C)(C)C)ccc52)cc4-n2c4c3cccc4c3ccc4sc5ccccc5c4c32)cc1 ; c1ccc(N(c2ccccc2)c2cc3c4c(c2)-n2c5c(cccc5c5ccc6sc7ccccc7c6c52)B4c2ccccc2N3c2ccccc2)cc1 ; CC(C)(C)c1ccc(N(c2ccc(C(C)(C)C)cc2)c2cc3c4c(c2)-n2c5c(cccc5c5ccc6sc7ccccc7c6c52)B4c2ccccc2N3c2ccccc2)cc1]

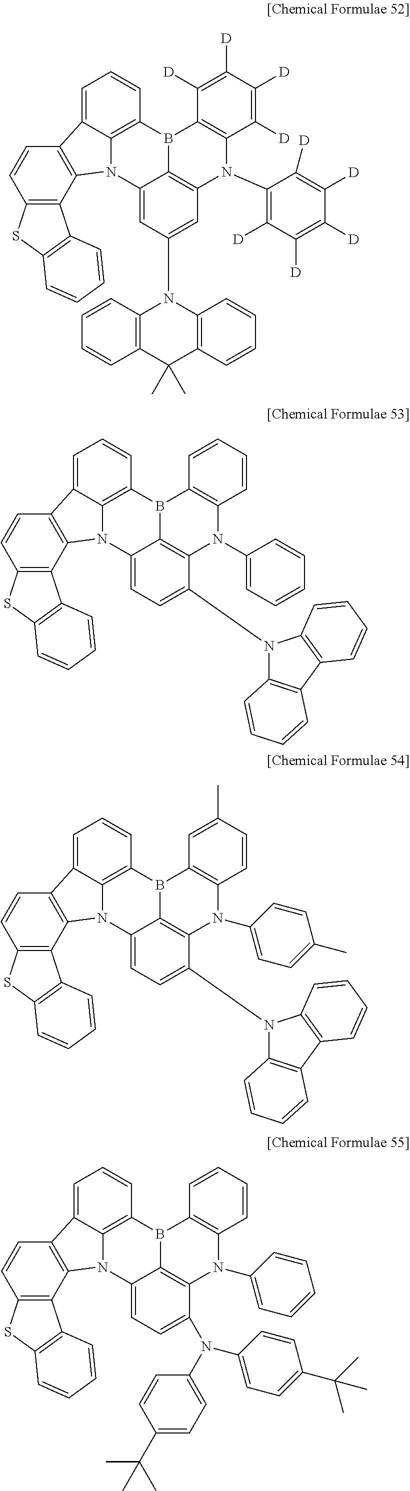 [SMILES: [2H]c1c([2H])c([2H])c(N2c3cc(N4c5ccccc5C(C)(C)c5ccccc54)cc4c3B(c3c([2H])c([2H])c([2H])c([2H])c32)c2cccc3c5ccc6sc7ccccc7c6c5n-4c23)c([2H])c1[2H] ; c1ccc(N2c3ccccc3B3c4c(ccc(-n5c6ccccc6c6ccccc65)c42)-n2c4c3cccc4c3ccc4sc5ccccc5c4c32)cc1 ; Cc1ccc(N2c3ccc(C)cc3B3c4c(ccc(-n5c6ccccc6c6ccccc65)c42)-n2c4c3cccc4c3ccc4sc5ccccc5c4c32)cc1 ; CC(C)(C)c1ccc(N(c2ccc(C(C)(C)C)cc2)c2ccc3c4c2N(c2ccccc2)c2ccccc2B4c2cccc4c5ccc6sc7ccccc7c6c5n-3c24)cc1]

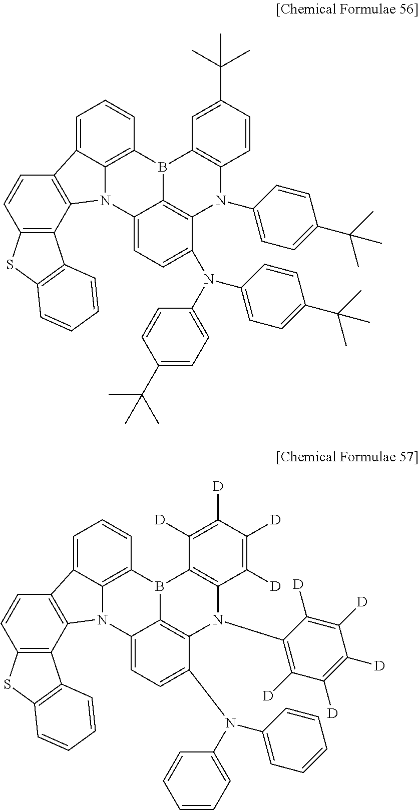 [SMILES: CC(C)(C)c1ccc(N(c2ccc(C(C)(C)C)cc2)c2ccc3c4c2N(c2ccc(C(C)(C)C)cc2)c2ccc(C(C)(C)C)cc2B4c2cccc4c5ccc6sc7ccccc7c6c5n-3c24)cc1 ; [2H]c1c([2H])c([2H])c(N2c3c(N(c4ccccc4)c4ccccc4)ccc4c3B(c3c([2H])c([2H])c([2H])c([2H])c32)c2cccc3c5ccc6sc7ccccc7c6c5n-4c23)c([2H])c1[2H]]

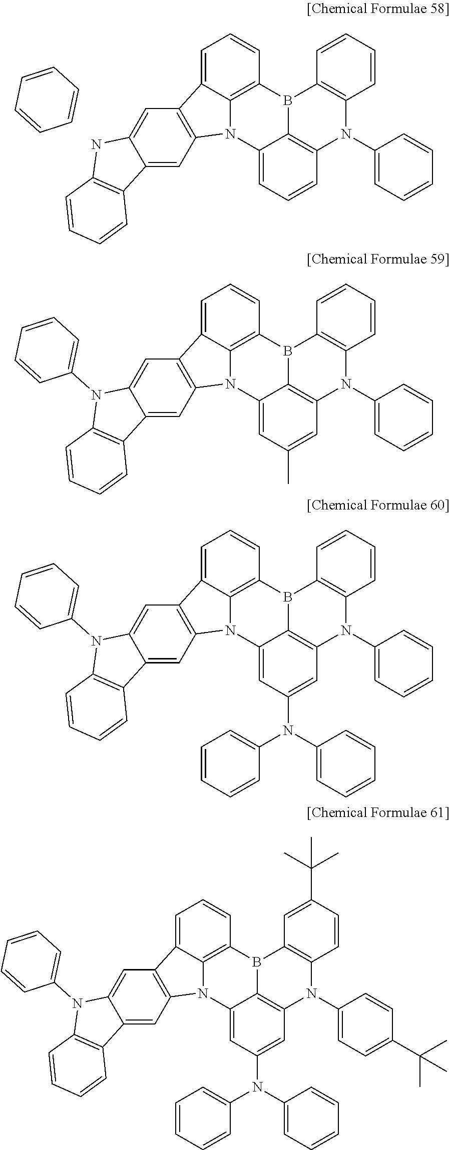

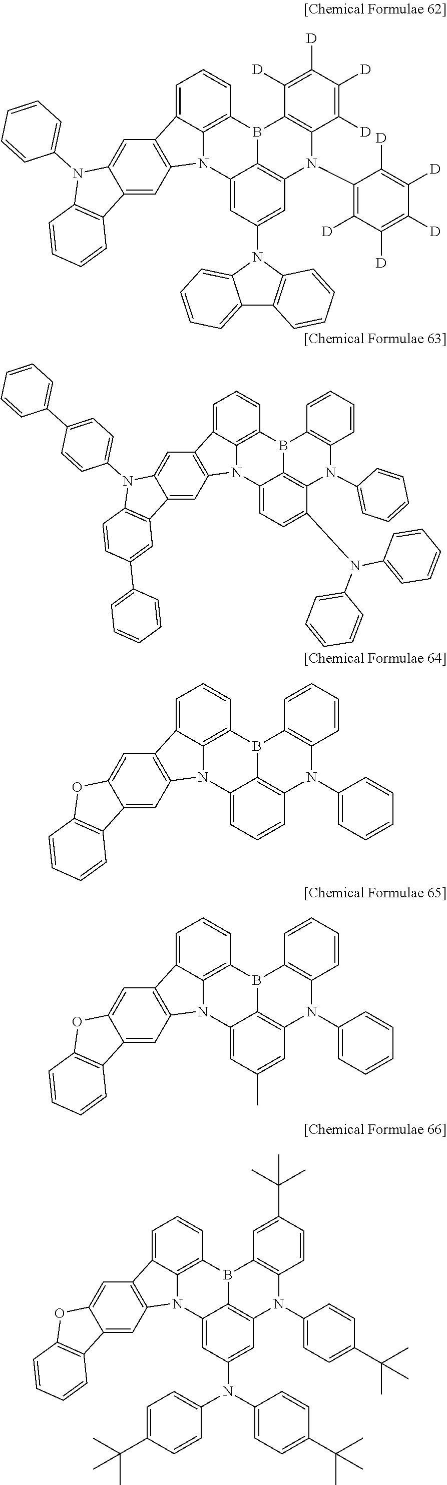

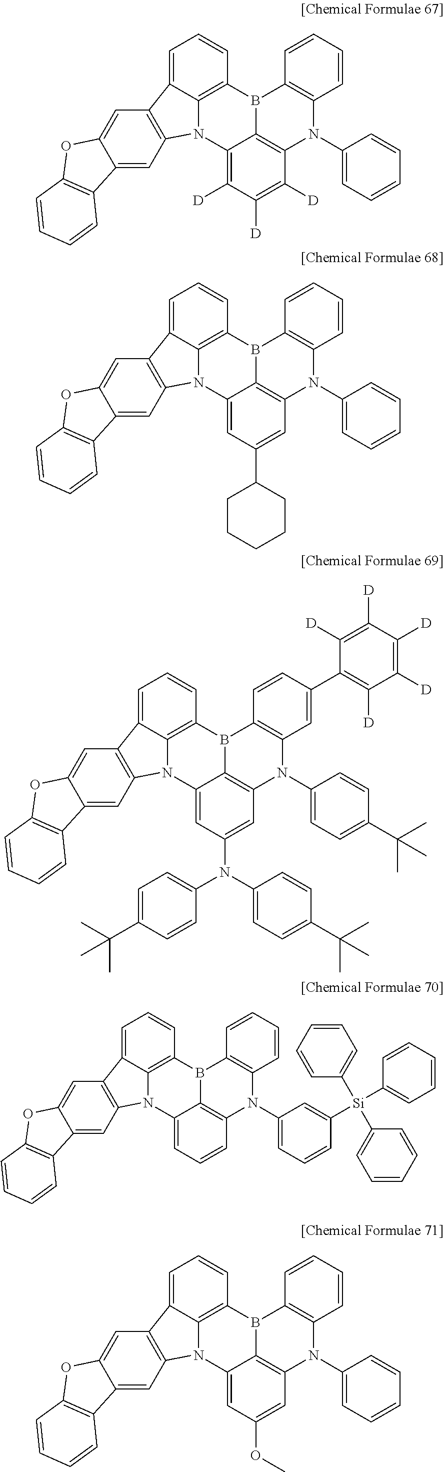 [SMILES: [2H]c1c([2H])c2c3c(c1[2H])-n1c4cc5c(cc4c4cccc(c41)B3c1ccccc1N2c1ccccc1)oc1ccccc15 ; c1ccc(N2c3ccccc3B3c4c2cc(C2CCCCC2)cc4-n2c4cc5c(cc4c4cccc3c42)oc2ccccc25)cc1 ; [2H]c1c([2H])c([2H])c(-c2ccc3c(c2)N(c2ccc(C(C)(C)C)cc2)c2cc(N(c4ccc(C(C)(C)C)cc4)c4ccc(C(C)(C)C)cc4)cc4c2B3c2cccc3c5cc6oc7ccccc7c6cc5n-4c23)c([2H])c1[2H] ; c1ccc([Si](c2ccccc2)(c2ccccc2)c2cccc(N3c4ccccc4B4c5c3cccc5-n3c5cc6c(cc5c5cccc4c53)oc3ccccc36)c2)cc1 ; COc1cc2c3c(c1)-n1c4cc5c(cc4c4cccc(c41)B3c1ccccc1N2c1ccccc1)oc1ccccc15]

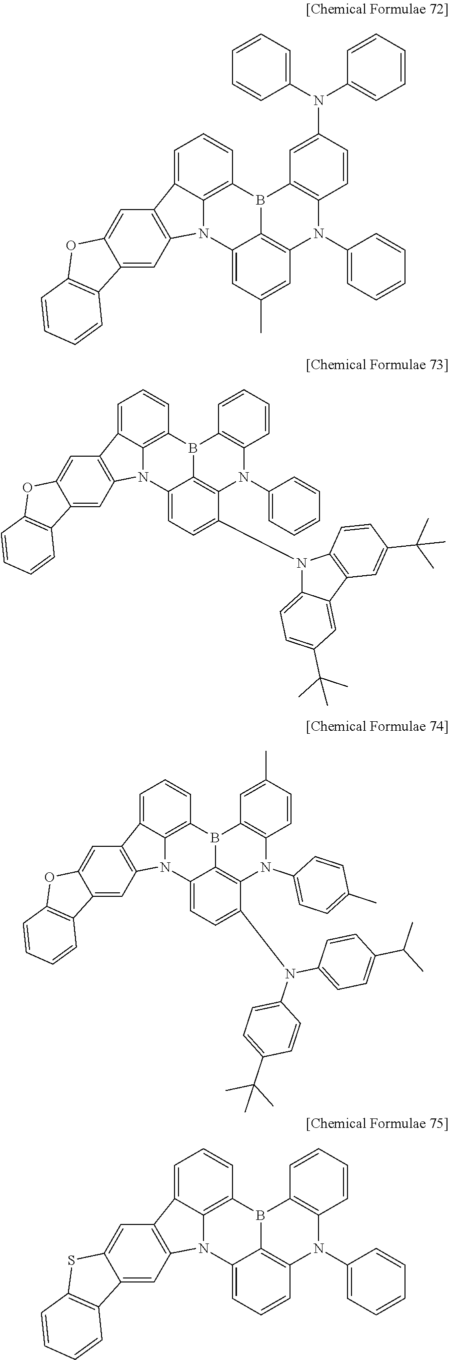 [SMILES: Cc1cc2c3c(c1)-n1c4cc5c(cc4c4cccc(c41)B3c1cc(N(c3ccccc3)c3ccccc3)ccc1N2c1ccccc1)oc1ccccc15 ; CC(C)(C)c1ccc2c(c1)c1cc(C(C)(C)C)ccc1n2-c1ccc2c3c1N(c1ccccc1)c1ccccc1B3c1cccc3c4cc5oc6ccccc6c5cc4n-2c13 ; Cc1ccc(N2c3ccc(C)cc3B3c4c(ccc(N(c5ccc(C(C)C)cc5)c5ccc(C(C)(C)C)cc5)c42)-n2c4cc5c(cc4c4cccc3c42)oc2ccccc25)cc1 ; c1ccc(N2c3ccccc3B3c4c2cccc4-n2c4cc5c(cc4c4cccc3c42)sc2ccccc25)cc1]

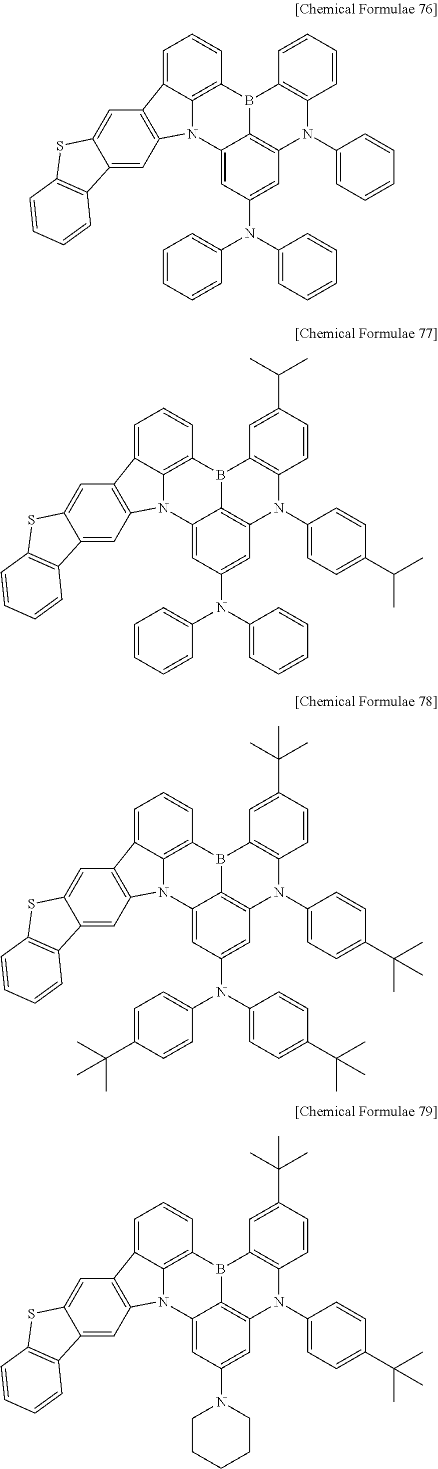 [SMILES: c1ccc(N(c2ccccc2)c2cc3c4c(c2)-n2c5cc6c(cc5c5cccc(c52)B4c2ccccc2N3c2ccccc2)sc2ccccc26)cc1 ; CC(C)c1ccc(N2c3ccc(C(C)C)cc3B3c4c2cc(N(c2ccccc2)c2ccccc2)cc4-n2c4cc5c(cc4c4cccc3c42)sc2ccccc25)cc1 ; CC(C)(C)c1ccc(N(c2ccc(C(C)(C)C)cc2)c2cc3c4c(c2)-n2c5cc6c(cc5c5cccc(c52)B4c2cc(C(C)(C)C)ccc2N3c2ccc(C(C)(C)C)cc2)sc2ccccc26)cc1 ; CC(C)(C)c1ccc(N2c3ccc(C(C)(C)C)cc3B3c4c2cc(N2CCCCC2)cc4-n2c4cc5c(cc4c4cccc3c42)sc2ccccc25)cc1]

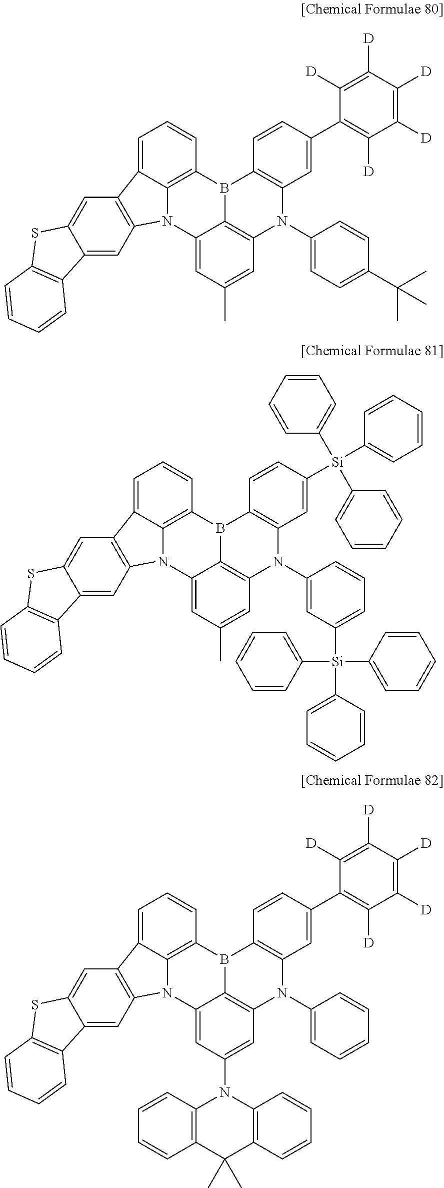 [SMILES: [2H]c1c([2H])c([2H])c(-c2ccc3c(c2)N(c2ccc(C(C)(C)C)cc2)c2cc(C)cc4c2B3c2cccc3c5cc6sc7ccccc7c6cc5n-4c23)c([2H])c1[2H] ; Cc1cc2c3c(c1)-n1c4cc5c(cc4c4cccc(c41)B3c1ccc([Si](c3ccccc3)(c3ccccc3)c3ccccc3)cc1N2c1cccc([Si](c2ccccc2)(c2ccccc2)c2ccccc2)c1)sc1ccccc15 ; [2H]c1c([2H])c([2H])c(-c2ccc3c(c2)N(c2ccccc2)c2cc(N4c5ccccc5C(C)(C)c5ccccc54)cc4c2B3c2cccc3c5cc6sc7ccccc7c6cc5n-4c23)c([2H])c1[2H]]

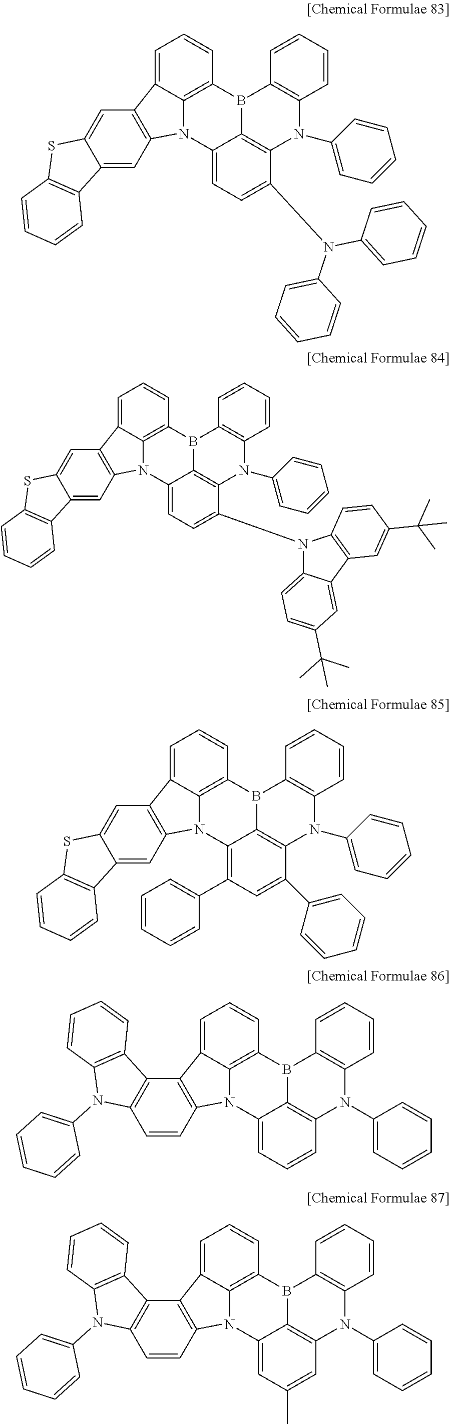

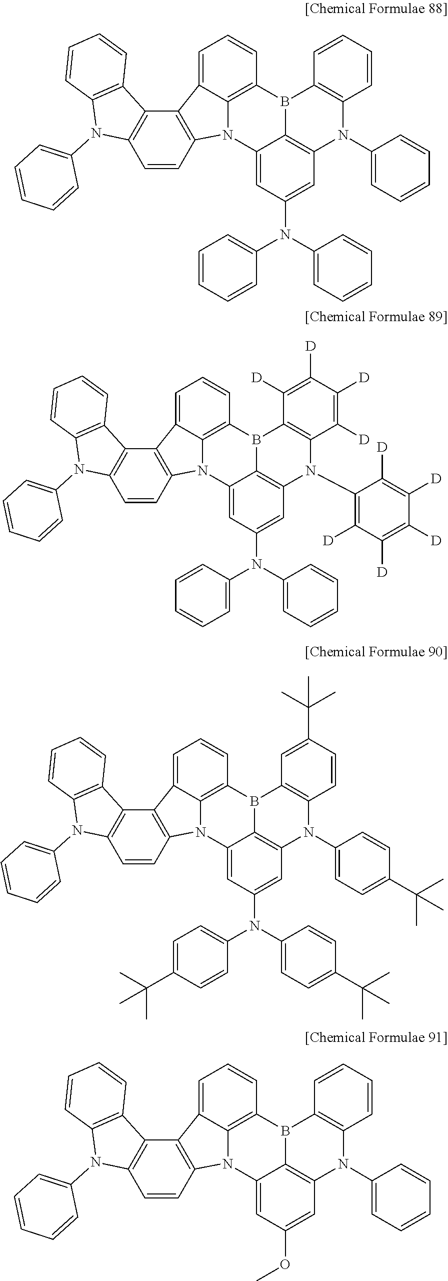 [SMILES: c1ccc(N(c2ccccc2)c2cc3c4c(c2)-n2c5ccc6c(c7ccccc7n6-c6ccccc6)c5c5cccc(c52)B4c2ccccc2N3c2ccccc2)cc1 ; [2H]c1c([2H])c([2H])c(N2c3cc(N(c4ccccc4)c4ccccc4)cc4c3B(c3c([2H])c([2H])c([2H])c([2H])c32)c2cccc3c5c6c7ccccc7n(-c7ccccc7)c6ccc5n-4c23)c([2H])c1[2H] ; CC(C)(C)c1ccc(N(c2ccc(C(C)(C)C)cc2)c2cc3c4c(c2)-n2c5ccc6c(c7ccccc7n6-c6ccccc6)c5c5cccc(c52)B4c2cc(C(C)(C)C)ccc2N3c2ccc(C(C)(C)C)cc2)cc1 ; COc1cc2c3c(c1)-n1c4ccc5c(c6ccccc6n5-c5ccccc5)c4c4cccc(c41)B3c1ccccc1N2c1ccccc1]

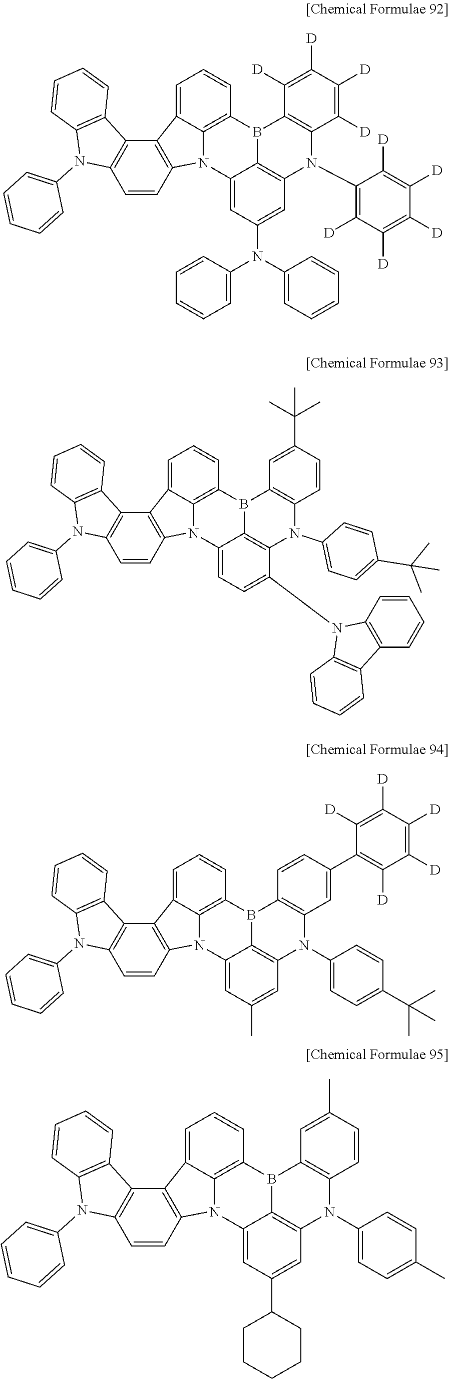 [SMILES: [2H]c1c([2H])c([2H])c(N2c3cc(N(c4ccccc4)c4ccccc4)cc4c3B(c3c([2H])c([2H])c([2H])c([2H])c32)c2cccc3c5c6c7ccccc7n(-c7ccccc7)c6ccc5n-4c23)c([2H])c1[2H] ; CC(C)(C)c1ccc(N2c3ccc(C(C)(C)C)cc3B3c4c(ccc(-n5c6ccccc6c6ccccc65)c42)-n2c4ccc5c(c6ccccc6n5-c5ccccc5)c4c4cccc3c42)cc1 ; [2H]c1c([2H])c([2H])c(-c2ccc3c(c2)N(c2ccc(C(C)(C)C)cc2)c2cc(C)cc4c2B3c2cccc3c5c6c7ccccc7n(-c7ccccc7)c6ccc5n-4c23)c([2H])c1[2H] ; Cc1ccc(N2c3ccc(C)cc3B3c4c2cc(C2CCCCC2)cc4-n2c4ccc5c(c6ccccc6n5-c5ccccc5)c4c4cccc3c42)cc1]

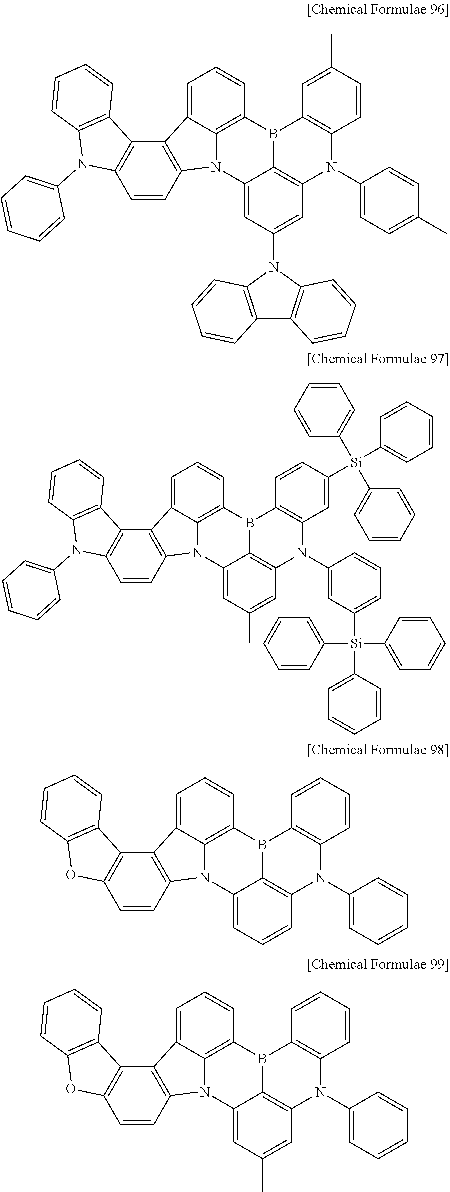

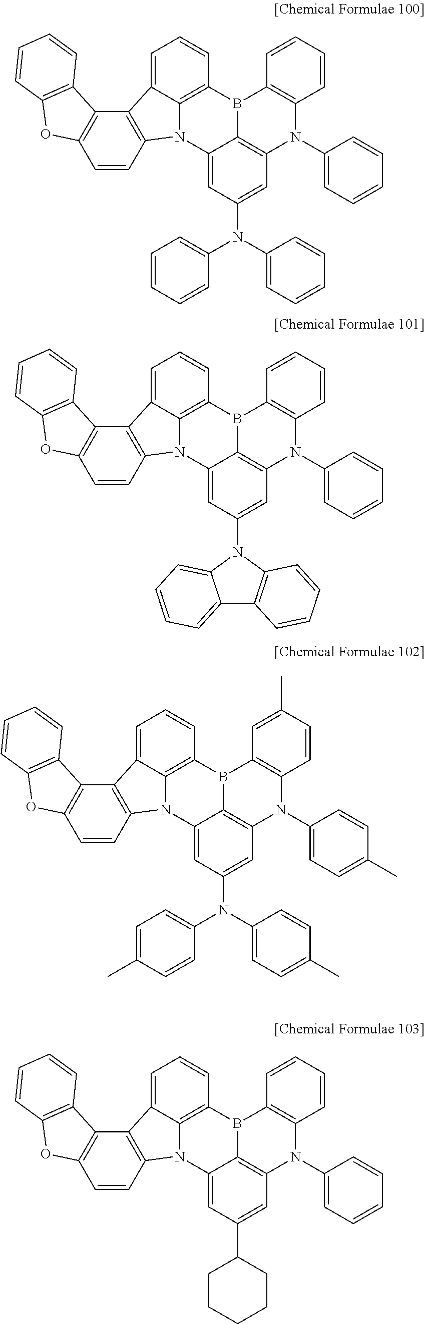 [SMILES: c1ccc(N(c2ccccc2)c2cc3c4c(c2)-n2c5ccc6oc7ccccc7c6c5c5cccc(c52)B4c2ccccc2N3c2ccccc2)cc1 ; c1ccc(N2c3ccccc3B3c4c2cc(-n2c5ccccc5c5ccccc52)cc4-n2c4ccc5oc6ccccc6c5c4c4cccc3c42)cc1 ; Cc1ccc(N(c2ccc(C)cc2)c2cc3c4c(c2)-n2c5ccc6oc7ccccc7c6c5c5cccc(c52)B4c2cc(C)ccc2N3c2ccc(C)cc2)cc1 ; c1ccc(N2c3ccccc3B3c4c2cc(C2CCCCC2)cc4-n2c4ccc5oc6ccccc6c5c4c4cccc3c42)cc1]

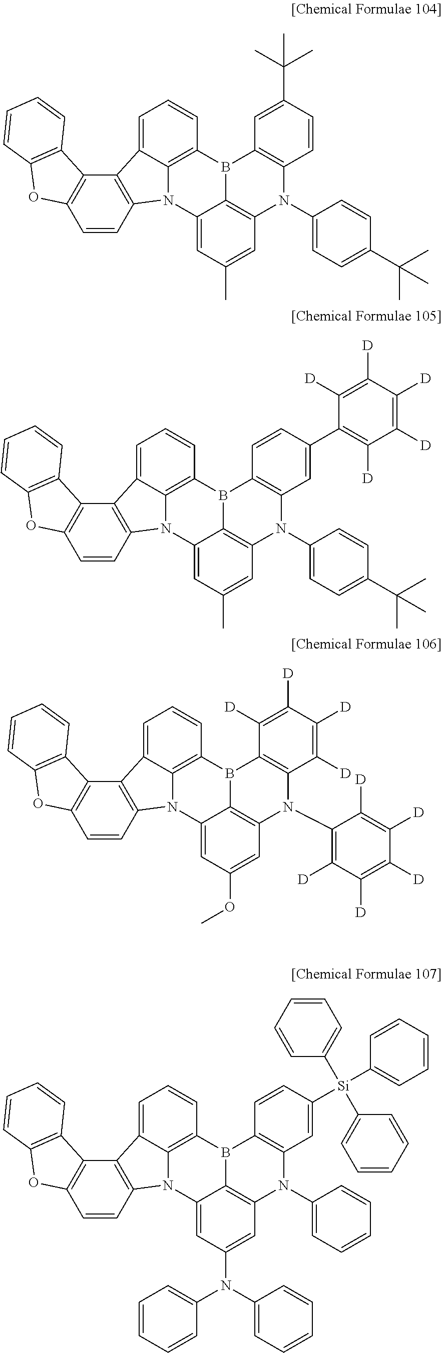 [SMILES: Cc1cc2c3c(c1)-n1c4ccc5oc6ccccc6c5c4c4cccc(c41)B3c1cc(C(C)(C)C)ccc1N2c1ccc(C(C)(C)C)cc1 ; [2H]c1c([2H])c([2H])c(-c2ccc3c(c2)N(c2ccc(C(C)(C)C)cc2)c2cc(C)cc4c2B3c2cccc3c5c6c(ccc5n-4c23)oc2ccccc26)c([2H])c1[2H] ; [2H]c1c([2H])c([2H])c(N2c3cc(OC)cc4c3B(c3c([2H])c([2H])c([2H])c([2H])c32)c2cccc3c5c6c(ccc5n-4c23)oc2ccccc26)c([2H])c1[2H] ; c1ccc(N(c2ccccc2)c2cc3c4c(c2)-n2c5ccc6oc7ccccc7c6c5c5cccc(c52)B4c2ccc([Si](c4ccccc4)(c4ccccc4)c4ccccc4)cc2N3c2ccccc2)cc1]

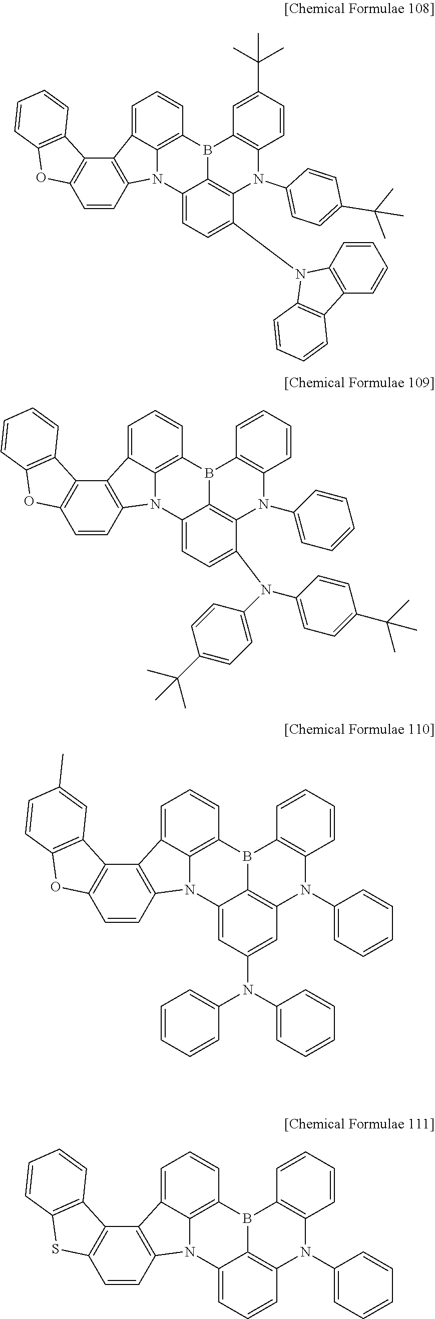 [SMILES: CC(C)(C)c1ccc(N2c3ccc(C(C)(C)C)cc3B3c4c(ccc(-n5c6ccccc6c6ccccc65)c42)-n2c4ccc5oc6ccccc6c5c4c4cccc3c42)cc1 ; CC(C)(C)c1ccc(N(c2ccc(C(C)(C)C)cc2)c2ccc3c4c2N(c2ccccc2)c2ccccc2B4c2cccc4c5c6c(ccc5n-3c24)oc2ccccc26)cc1 ; Cc1ccc2oc3ccc4c(c5cccc6c5n4-c4cc(N(c5ccccc5)c5ccccc5)cc5c4B6c4ccccc4N5c4ccccc4)c3c2c1 ; c1ccc(N2c3ccccc3B3c4c2cccc4-n2c4ccc5sc6ccccc6c5c4c4cccc3c42)cc1]

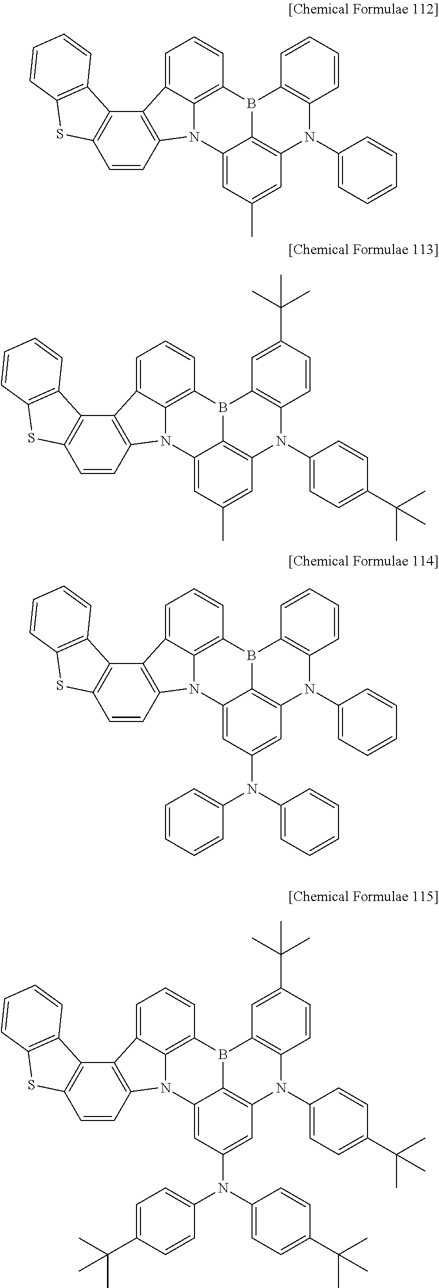 [SMILES: Cc1cc2c3c(c1)-n1c4ccc5sc6ccccc6c5c4c4cccc(c41)B3c1ccccc1N2c1ccccc1 ; Cc1cc2c3c(c1)-n1c4ccc5sc6ccccc6c5c4c4cccc(c41)B3c1cc(C(C)(C)C)ccc1N2c1ccc(C(C)(C)C)cc1 ; c1ccc(N(c2ccccc2)c2cc3c4c(c2)-n2c5ccc6sc7ccccc7c6c5c5cccc(c52)B4c2ccccc2N3c2ccccc2)cc1 ; CC(C)(C)c1ccc(N(c2ccc(C(C)(C)C)cc2)c2cc3c4c(c2)-n2c5ccc6sc7ccccc7c6c5c5cccc(c52)B4c2cc(C(C)(C)C)ccc2N3c2ccc(C(C)(C)C)cc2)cc1]

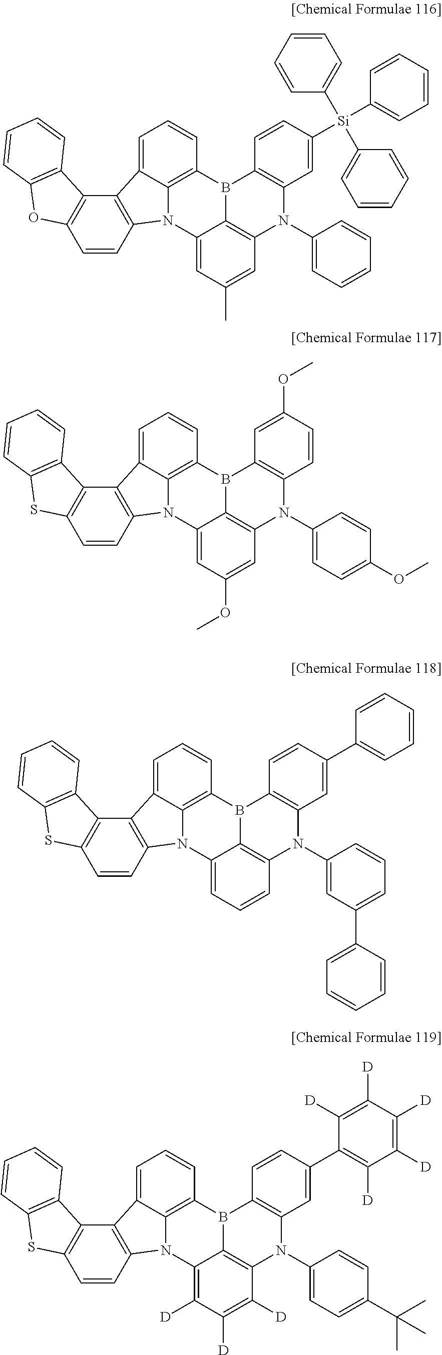 [SMILES: Cc1cc2c3c(c1)-n1c4ccc5oc6ccccc6c5c4c4cccc(c41)B3c1ccc([Si](c3ccccc3)(c3ccccc3)c3ccccc3)cc1N2c1ccccc1 ; COc1ccc(N2c3ccc(OC)cc3B3c4c2cc(OC)cc4-n2c4ccc5sc6ccccc6c5c4c4cccc3c42)cc1 ; c1ccc(-c2cccc(N3c4cc(-c5ccccc5)ccc4B4c5c3cccc5-n3c5ccc6sc7ccccc7c6c5c5cccc4c53)c2)cc1 ; [2H]c1c([2H])c([2H])c(-c2ccc3c(c2)N(c2ccc(C(C)(C)C)cc2)c2c([2H])c([2H])c([2H])c4c2B3c2cccc3c5c6c(ccc5n-4c23)sc2ccccc26)c([2H])c1[2H]]

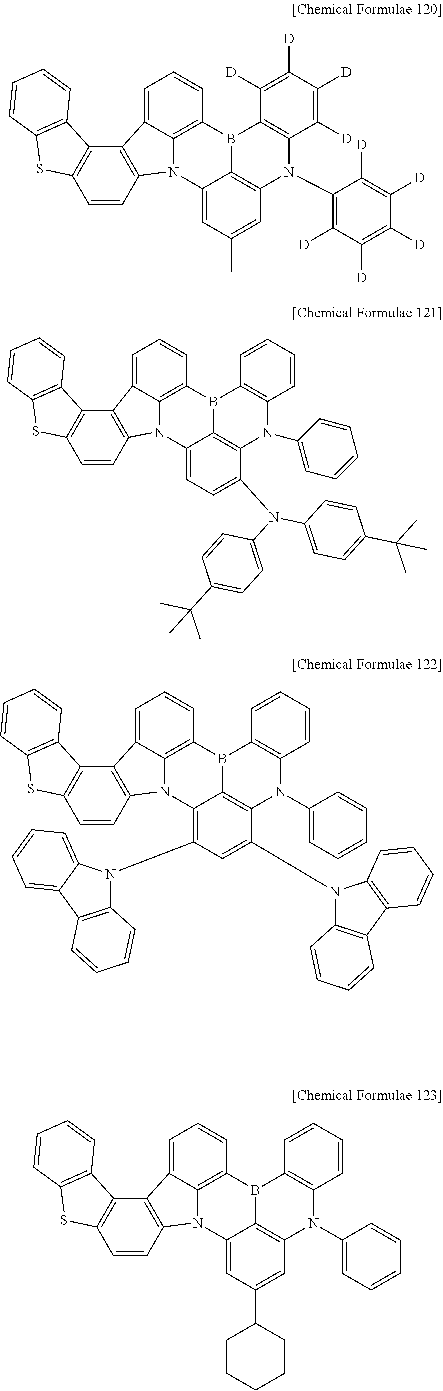 [SMILES: [2H]c1c([2H])c([2H])c(N2c3cc(C)cc4c3B(c3c([2H])c([2H])c([2H])c([2H])c32)c2cccc3c5c6c(ccc5n-4c23)sc2ccccc26)c([2H])c1[2H] ; CC(C)(C)c1ccc(N(c2ccc(C(C)(C)C)cc2)c2ccc3c4c2N(c2ccccc2)c2ccccc2B4c2cccc4c5c6c(ccc5n-3c24)sc2ccccc26)cc1 ; c1ccc(N2c3ccccc3B3c4c2c(-n2c5ccccc5c5ccccc52)cc(-n2c5ccccc5c5ccccc52)c4-n2c4ccc5sc6ccccc6c5c4c4cccc3c42)cc1 ; c1ccc(N2c3ccccc3B3c4c2cc(C2CCCCC2)cc4-n2c4ccc5sc6ccccc6c5c4c4cccc3c42)cc1]

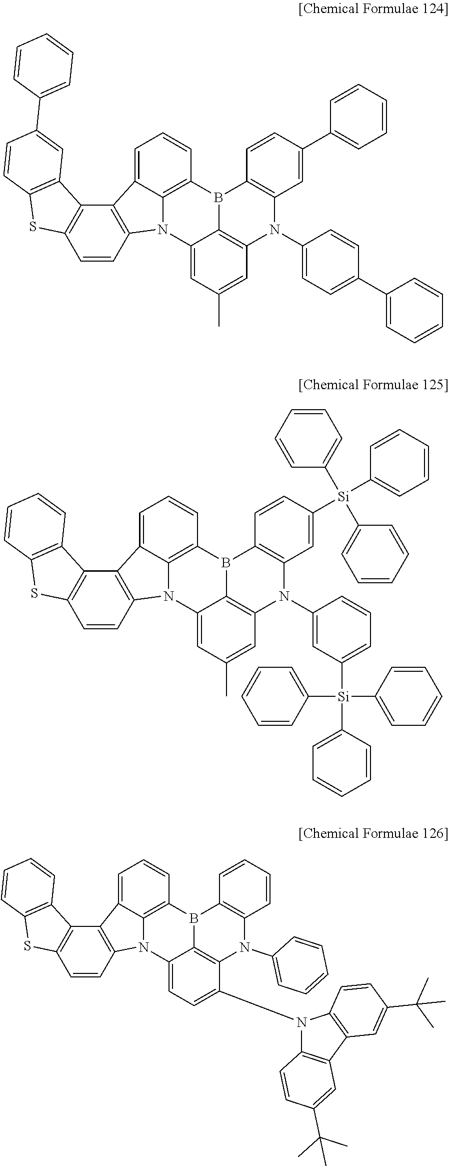 [SMILES: Cc1cc2c3c(c1)-n1c4ccc5sc6ccc(-c7ccccc7)cc6c5c4c4cccc(c41)B3c1ccc(-c3ccccc3)cc1N2c1ccc(-c2ccccc2)cc1 ; Cc1cc2c3c(c1)-n1c4ccc5sc6ccccc6c5c4c4cccc(c41)B3c1ccc([Si](c3ccccc3)(c3ccccc3)c3ccccc3)cc1N2c1cccc([Si](c2ccccc2)(c2ccccc2)c2ccccc2)c1 ; CC(C)(C)c1ccc2c(c1)c1cc(C(C)(C)C)ccc1n2-c1ccc2c3c1N(c1ccccc1)c1ccccc1B3c1cccc3c4c5c(ccc4n-2c13)sc1ccccc15]

An organic light-emitting device according to another aspect of the present invention includes a first electrode, a second electrode provided opposite to the first electrode, and an organic material layer located between the first electrode and the second electrode, wherein the organic material layer includes the boron compound according to the present invention.

The organic material layer may have a single layer structure, but may preferably have a multilayer structure, and specifically, the organic material layer may include an electron injection layer (EIL), an electron transport layer (ETL), a light-emitting layer (EML), a hole transport layer (HTL) and a hole injection layer (HIL), and preferably, the boron compound may be a light emitter of the light-emitting layer (EML) and may specifically be a blue light emitter.

The light-emitting layer may include a host compound and a dopant compound that is a light emitter, and herein, the host compound may include an anthracene derivative represented by the following Chemical Formula 127.

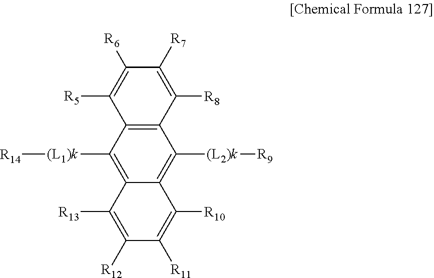

In Chemical Formula 127, R₅ to R₁₄ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group, L₁ and L₂ are each independently a single bond, a substituted or unsubstituted arylene group, or a substituted or unsubstituted heteroarylene group, and ks are each independently an integer of 1 to 3.

The light-emitting layer of the organic material layer includes a host compound, a first dopant compound and a second dopant compound, the second dopant compound is a delayed fluorescent material or a phosphorescent material, and the first dopant compound may be the boron compound according to the present invention. Herein, a half-width of the first dopant compound is preferably narrower than a half-width of the second dopant compound. Color purity increases as a half-width is narrower, and when the half-width of the first dopant compound that is a final light emitter is narrower than the half-width of the second dopant compound, there is an effect of obtaining device characteristics of high color purity compared to existing delayed fluorescent devices.

In the light-emitting layer, the host compound and the second dopant compound each preferably have higher singlet energy and triplet energy than the first dopant compound. The second dopant compound performs a role of receiving energy from the host compound and transferring the energy to the first dopant compound, and a delayed fluorescent material having an electron donating-electron accepting structure or a heavy metal phosphorescent material is preferably used.

The delayed fluorescent material of the second dopant compound is a material having an electron acceptor-electron donor structure, and specific examples thereof may include materials using one or more of a boron compound, a triazine, a cyano group and a sulfone group as the electron acceptor and using one or more of a carbazole derivative and an acridane derivative as the electron donor, and the phosphorescent material of the second dopant compound may be a heavy metal, and specific examples thereof may include one or more types of heavy metals among Ir, Pt and Pd, however, the material is not limited to the above-described examples.

In addition, energy of the second dopant compound is transferred to the first dopant compound by the energy relationship between triplet and singlet of each dopant compound, and as the ratio of the first dopant compound receiving energy is smaller than that of the second dopant compound transferring energy, light emission efficiency of the first dopant compound that is a final light emitter may increase.

As the host compound transferring energy to the second dopant compound, host materials generally used in a light-emitting layer of an organic light-emitting device may be used, and as a specific example, host compounds including a carbazole such as mCP, mCBP, mCBP-CN or 2CzPy having triplet energy of 2.9 eV or greater, compounds including a phosphine oxide such as DBFPO or DPEPO, host materials including a triazine such as DDBFT or pSiTrz, and the like may be used, however, the compound is not limited to the above-described examples.

Herein, as the host compound, using two or more types of different host compounds may contribute to improving device characteristics such as efficiency and lifespan characteristics compared to using only one type of material. For example, when an electron-type host that favorably moves electrons and a host that favorably moves holes are used together, holes and electrons meet in a balanced manner inside the light-emitting layer, and high efficiency and lifespan characteristics may be expected. In addition, when a host that forms an exciplex is used, the driving voltage is lowered due to a small energy difference between the light-emitting layer and adjacent layers, excitons are widely formed inside the light-emitting layer while more energy is generated through a reverse intersystem crossing process between the host materials, which may improve device efficiency and lifespan characteristics.

The organic light-emitting device of the present invention has high color purity and excellent efficiency, and may thereby be used as a light-emitting device in various display apparatuses, and may be used in display apparatuses of, for example, TVs, smart phones, computers, automobiles and the like.

In addition, the organic light-emitting device of the present invention may be used in lighting apparatuses due to high efficiency.

Hereinafter, examples of the present invention will be described in detail so that those skilled in the art may readily implement the present invention. However, the present invention may be implemented in various different forms, and is not limited to preparation examples and examples described herein.

### Preparation Example: Synthesis of Boron Compound

### Example 1: Synthesis of Boron Compound Represented by Chemical Formula 21

2DPA (1 g, 2.2 mmol), NN (0.78 g, 2.34 mmol), Pd₂(dba)₃ (0.023 g, 0.025 mmol), dicyclohexylphosphino 2′,4′,6′-triisopropylbiphenyl (0.024 g, 0.50 mmol) and NaOfBu (0.43 g, 4.5 mmol) were mixed in toluene, and stirred for 15 hours at 120° C. to allow a reaction as in the following Reaction Formula 1-1 to occur. When the reaction was finished, the reaction material was extracted using dichloromethane and water, and an organic layer was obtained. The organic layer was recrystallized using n-hexane to obtain a white solid intermediate 2DPA-NN (1.2 g).

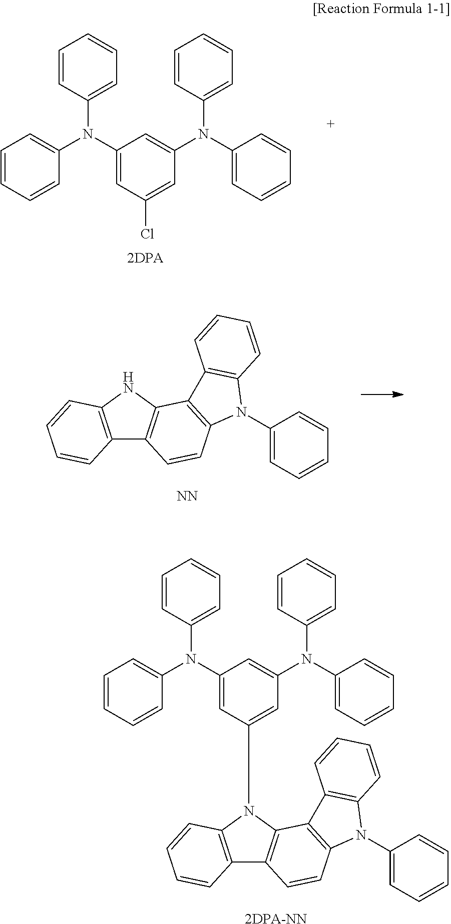

After dissolving the 2DPA-NN (100 mg, 0.13 mmol) in 6 ml of o-dichlorobenzene at room temperature, boron tribromide (0.07 g, 0.27 mmol) was added thereto, and the result was stirred for 6 hours at 180° C. to allow a reaction as in the following Reaction Formula 1-2 to occur. When the reaction was finished, the reaction material was diluted with toluene, and filtered using a silica pad. After reducing the pressure, a white solid compound (Example 1) (52 mg) was obtained using a silica column.

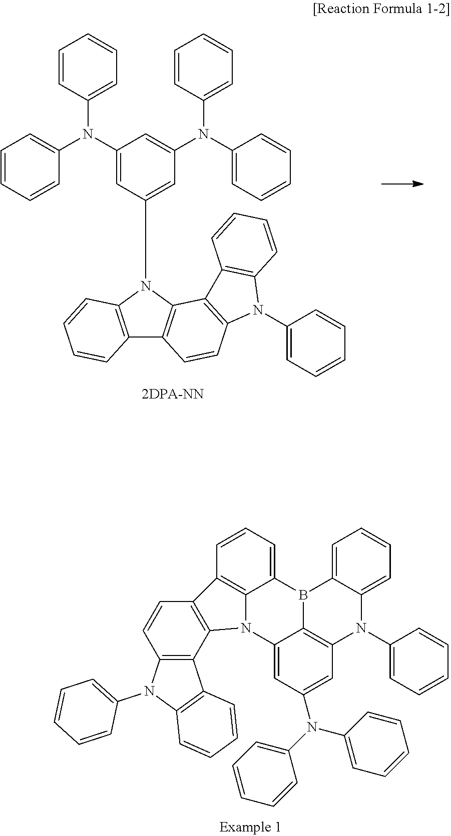 [SMILES: c1ccc(N(c2ccccc2)c2cc(N(c3ccccc3)c3ccccc3)cc(-n3c4ccccc4c4ccc5c(c6ccccc6n5-c5ccccc5)c43)c2)cc1 ; "2DPA-NN" ; c1ccc(N(c2ccccc2)c2cc3c4c(c2)-n2c5c(cccc5c5ccc6c(c7ccccc7n6-c6ccccc6)c52)B4c2ccccc2N3c2ccccc2)cc1]

### Example 2: Synthesis of Boron Compound Represented by Chemical Formula 33

NO compound (1.3 g, 5.05 mmol) and 60% sodium hydride (13.8 mmol) were dissolved in 10 ml of a DMF solvent, and the mixture was slowly added to a DMF (5 ml) solution having 2DPA-F (2 g, 4.6 mmol) dissolved therein. The result was stirred for 15 hours at 150° C. to allow a reaction as in the following Reaction Formula 2-1 to occur. When the reaction was finished, the reaction material was poured into an ice bath and precipitated as a solid. The precipitated solid was extracted several times with water to obtain 2DPA-NO (0.62 g).

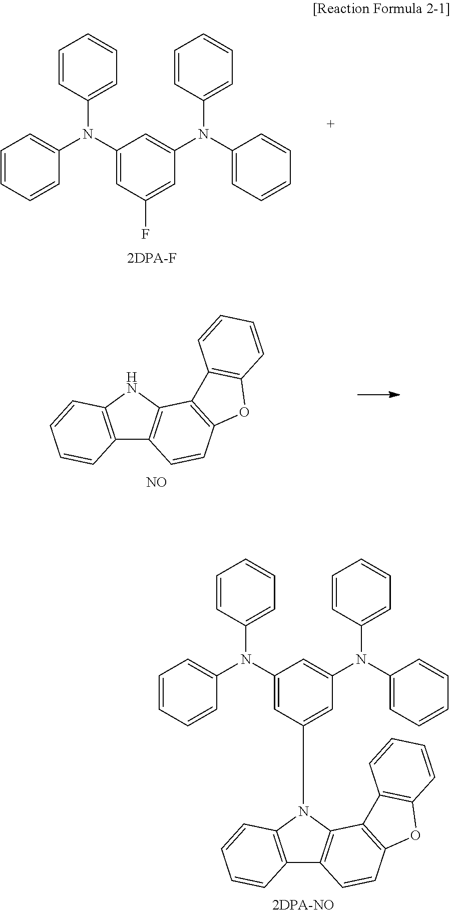

After dissolving the 2DPA-NO (300 mg, 0.44 mmol) in 12 ml of o-dichlorobenzene at room temperature, boron tribromide (0.22 g, 0.90 mmol) was added thereto, and the result was stirred for 12 hours at 180° C. to allow a reaction as in the following Reaction Formula 2-2 to occur. When the reaction was completed, the reaction material was diluted with hot toluene, and filtered using a silica pad. After reducing the pressure, a white solid compound (Example 2) (167 mg) was obtained using a silica column.

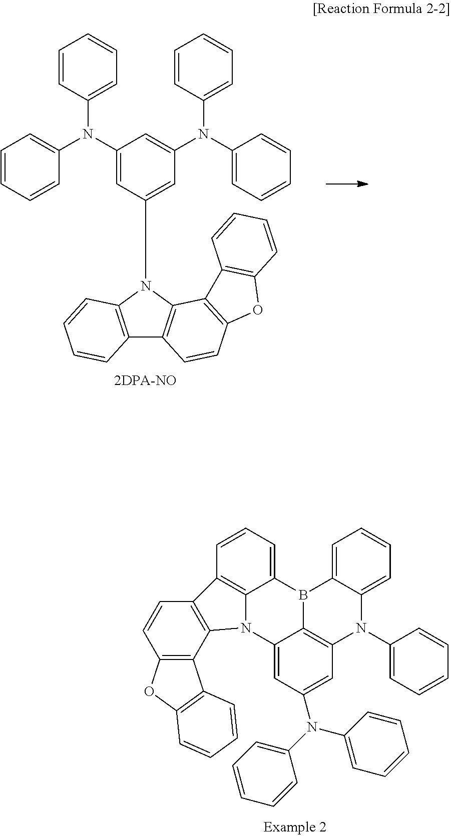

### Example 3: Synthesis of Boron Compound Represented by Chemical Formula 49

2DPA (1 g, 2.2 mmol), NS (0.78 g, 2.27 mmol), Pd₂ (dba)₃ (0.023 g, 0.025 mmol), tri-t-butylphosphonium tetrafluoroborate (0.1 g, 0.34 mmol) and NaOfBu (0.43 g, 4.5 mmol) were dissolved in toluene, and stirred for 15 hours at 120° C. to allow a reaction as in the following Reaction Formula 3-1 to occur. When the reaction was finished, the reaction material was extracted using dichloromethane and water. The result was recrystallized and purified using n-hexane to obtain white solid 2DPA-NS (0.54 g).

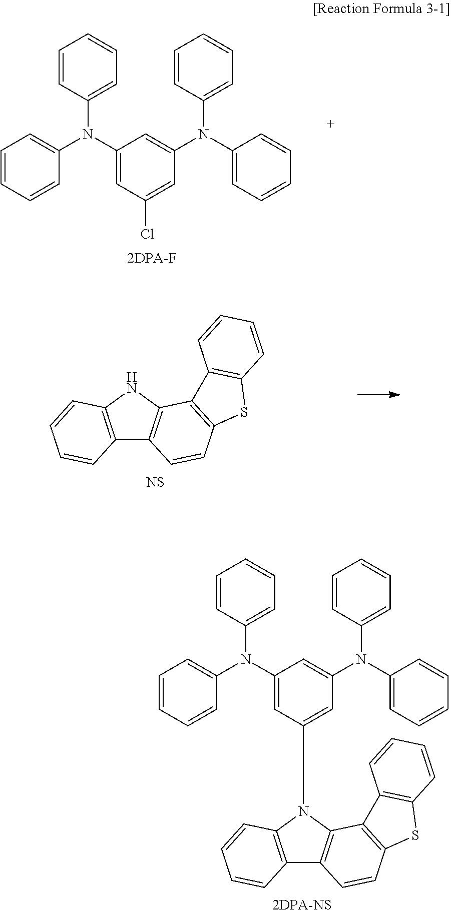

After dissolving the 2DPA-NS (500 mg, 0.73 mmol) in 15 ml of o-dichlorobenzene, boron tribromide (0.36 g, 1.46 mmol) was added thereto, and the mixture was stirred for 10 hours at 180° C. to allow a reaction as in the following Reaction Formula 3-2 to occur. When the reaction was finished, the reaction material was filtered using a silica pad. After reducing the pressure, a white solid compound (Example 3) (186 mg) was obtained using a silica column.

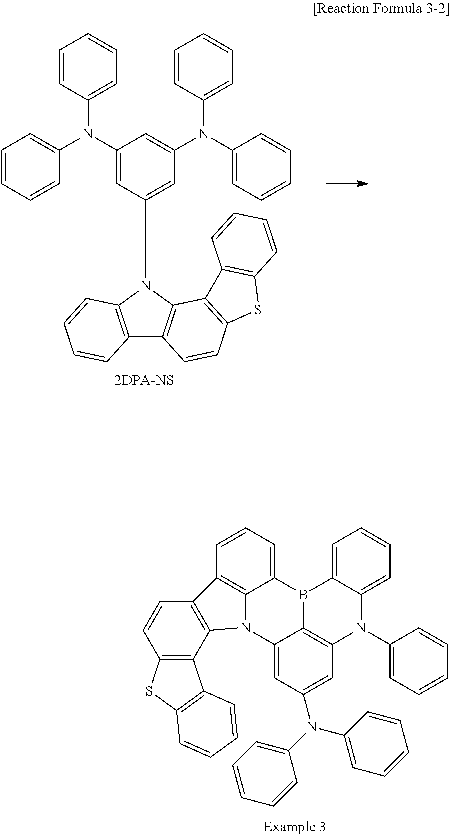

### Example 4: Synthesis of Boron Compound Represented by Chemical Formula 60

2DPA-Cl (2 g, 2.2 mmol), NN (1.56 g, 2.27 mmol), Pd2 (dba) 3 (0.046 g, 0.025 mmol), tri-t-butylphosphonium tetrafluoroborate (0.2 g, 0.34 mmol) and NaOfBu (0.86 g, 4.5 mmol) were dissolved in toluene, and stirred for 10 hours at 90° C. to allow a reaction as in the following Reaction Formula 4-1 to occur. When the reaction was finished, the reaction material was extracted using dichloromethane and water. The result was recrystallized and purified using n-hexane to obtain white solid 2DPA-NN (1.08 g).

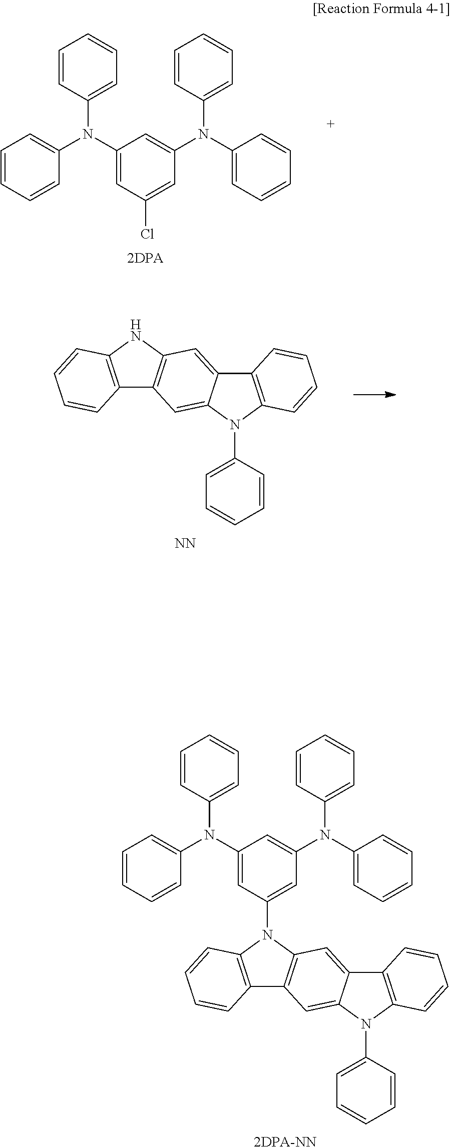 [SMILES: Clc1cc(N(c2ccccc2)c2ccccc2)cc(N(c2ccccc2)c2ccccc2)c1 ; c1ccc(-n2c3ccccc3c3cc4[nH]c5ccccc5c4cc32)cc1 ; "NN" ; c1ccc(N(c2ccccc2)c2cc(N(c3ccccc3)c3ccccc3)cc(-n3c4ccccc4c4cc5c(cc43)c3ccccc3n5-c3ccccc3)c2)cc1 ; "2DPA-NN"]

After dissolving the 2DPA-NN (650 mg, 0.73 mmol) in 15 ml of o-dichlorobenzene, boron tribromide (0.47 g, 1.46 mmol) was added thereto, and the mixture was stirred for 8 hours at 180° C. to allow a reaction as in the following Reaction Formula 4-2 to occur. When the reaction was finished, the reaction material was filtered using a silica pad. After reducing the pressure, a white solid compound (Example 4) (242 mg) was obtained using a silica column.

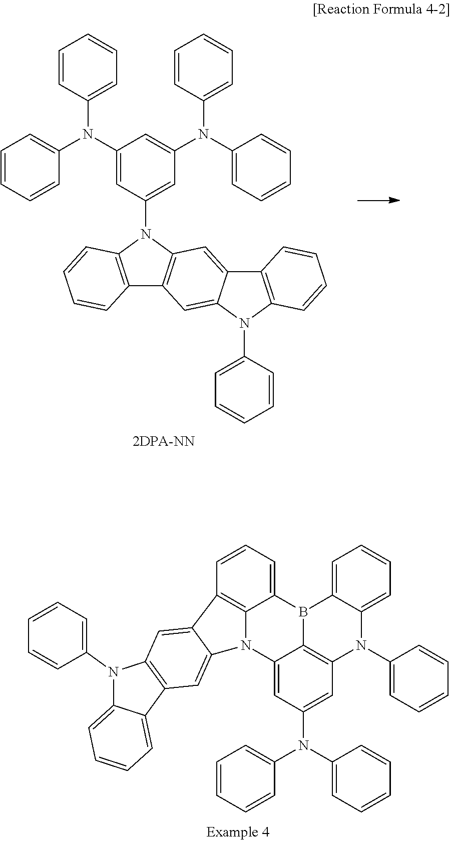 [SMILES: c1ccc(N(c2ccccc2)c2cc(N(c3ccccc3)c3ccccc3)cc(-n3c4ccccc4c4cc5c(cc43)c3ccccc3n5-c3ccccc3)c2)cc1 ; "2DPA-NN" ; c1ccc(N(c2ccccc2)c2cc3c4c(c2)-n2c5cc6c7ccccc7n(-c7ccccc7)c6cc5c5cccc(c52)B4c2ccccc2N3c2ccccc2)cc1]

### Example 5: Synthesis of Boron Compound Represented by Chemical Formula 100

2DPA-Cl (1.18 g, 2.2 mmol), NN (0.92 g, 2.27 mmol), Pd₂(dba)₃ (0.046 g, 0.015 mmol), tri-t-butylphosphonium tetrafluoroborate (0.12 g, 0.34 mmol) and NaOfBu (0.51 g, 4.5 mmol) were dissolved in toluene, and stirred for 10 hours at 90° C. to allow a reaction as in the following Reaction Formula 4-1 to occur. When the reaction was finished, the reaction material was extracted using dichloromethane and water. The result was recrystallized and purified using n-hexane to obtain white solid 2DPA-NO (0.64 g).

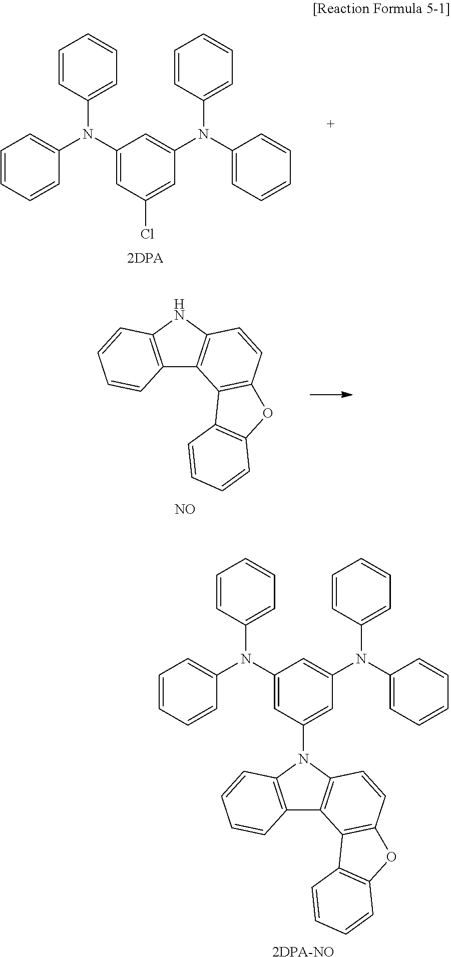

After dissolving the 2DPA-NO (650 mg, 0.73 mmol) in 15 ml of o-dichlorobenzene, boron tribromide (0.47 g, 1.46 mmol) was added thereto, and the mixture was stirred for 8 hours at 180° C. to allow a reaction as in the following Reaction Formula 5-2 to occur. When the reaction was finished, the reaction material was filtered using a silica pad. After reducing the pressure, a white solid compound (Example 5) (242 mg) was obtained using a silica column.

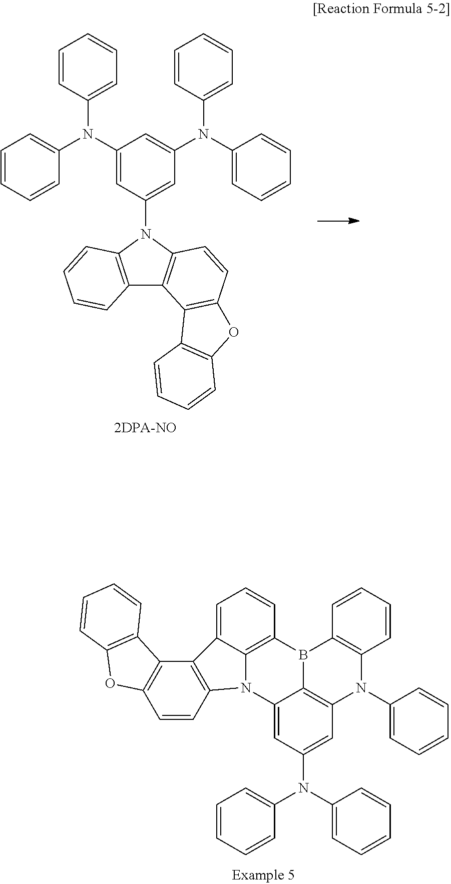 [SMILES: c1ccc(N(c2ccccc2)c2cc(N(c3ccccc3)c3ccccc3)cc(-n3c4ccccc4c4c5c(ccc43)oc3ccccc35)c2)cc1 ; "2DPA-NO" ; c1ccc(N(c2ccccc2)c2cc3c4c(c2)-n2c5ccc6oc7ccccc7c6c5c5cccc(c52)B4c2ccccc2N3c2ccccc2)cc1]

### Experimental Example 1: Evaluation of Boron Compound Properties

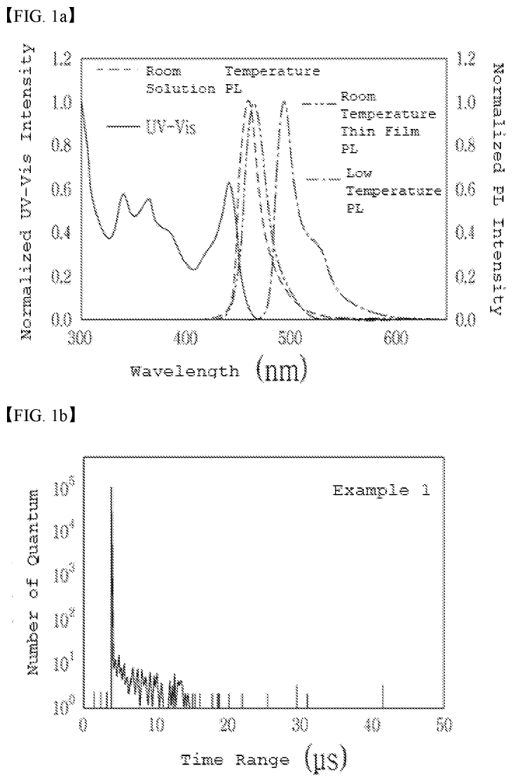

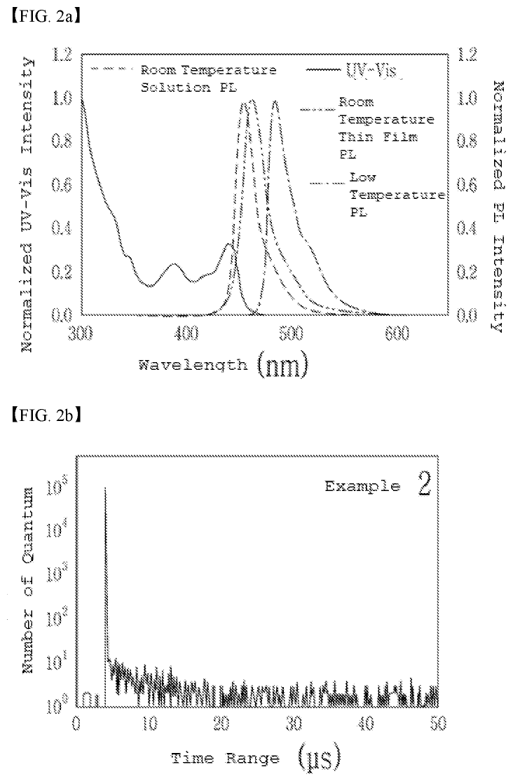

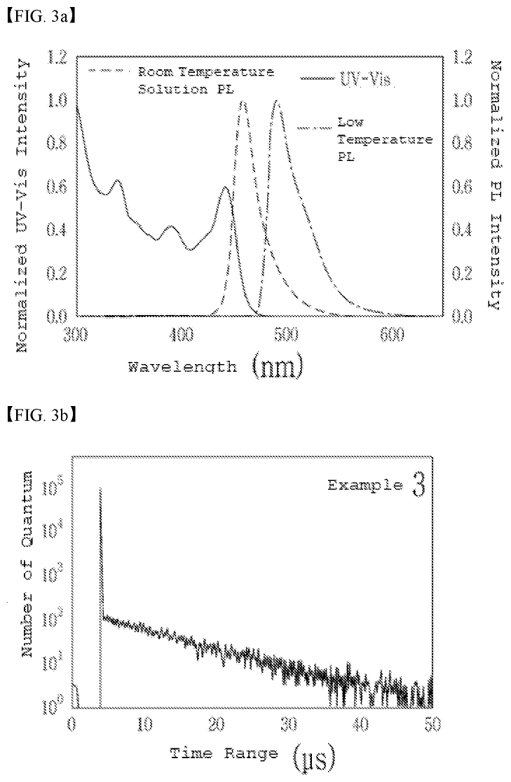

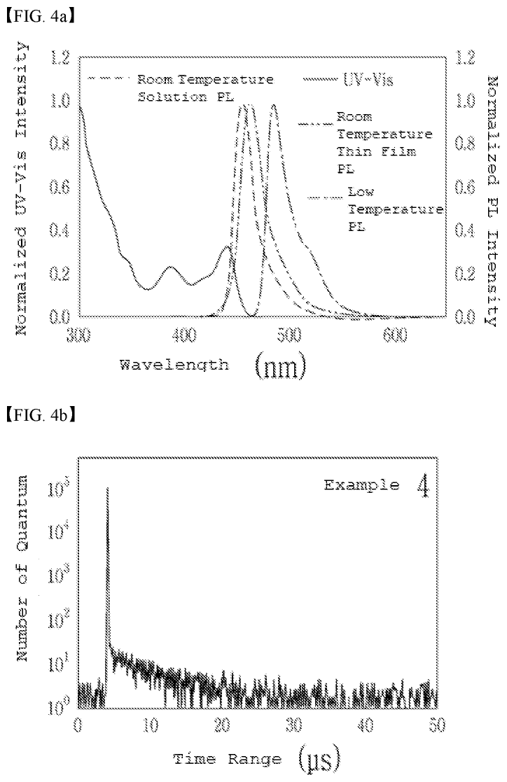

Property evaluations were performed on Examples 1 to 5 prepared according to the above-described preparation examples. The properties were measured by a UV-Vis absorption spectrum and a room temperature photoluminescence spectrum, and the UV-Vis absorption spectrum was measured using JASCO V-750 by diluting the subject to a concentration of 10x⁻⁵ M in a toluene solvent. As for the room temperature photoluminescence spectrum in a solution state, a condition of 10x⁻⁴M concentration in a toluene solvent was used, and as for the room temperature photoluminescence spectrum in a thin film state, an anthracene-based anthracene host was doped with 5% by weight of the compound for the preparation, and JASCO-FP 8500 equipment was used for the measurements. TRPL (Time-Resolved Photoluminescence) was measured using Hamamatsu C11367 equipment by diluting the subject to a concentration of 10x⁻⁴ M in a dichloromethane solvent. Measurement results for each of Examples 1 to 4 are shown in FIG. 1a to FIG. 4b, and properties of DABNA-1 (Comparative Example 1), which is an existing material, and Examples 1 to 5 are compared in the following Table 1.

TABLE 1

| | Comparative | | | | | | | | | | | |
|---|---|---|---|---|---|---|---|---|---|---|---|---|
| Category | Example 1 | | Example 1 | | Example 2 | | Example 3 | | Example 4 | | Example 5 | |
| Compound | DABNA-1 | | Chemical | | Chemical | | Chemical | | Chemical | | Chemical | |
| Structure | | | Formula 21 | | Formula 33 | | Formula 49 | | Formula 60 | | Formula 100 | |
| Maximum | 439 | nm | 443 | nm | 441 | nm | 443 | nm | 442 | nm | 445 | nm |
| Absorption | | | | | | | | | | | | |
| Spectrum | | | | | | | | | | | | |
| Stokes' Shift | 11 | nm | 18 | nm | 15 | nm | 17 | nm | 16 | nm | 16 | nm |
| Maximum | 450 | nm | 461 | nm | 456 | nm | 460 | nm | 458 | nm | 461 | nm |
| Luminescence | | | | | | | | | | | | |
| Spectrum | | | | | | | | | | | | |
| (Solution) | | | | | | | | | | | | |
| Half-Width | 21 | nm | 21 | nm | 22 | nm | 26 | nm | 22 | nm | 21 | nm |
| (Solution) | | | | | | | | | | | | |
| Maximum | 460 | nm | 466 | nm | 461 | nm | 465 | nm | 463 | nm | 466 | nm |
| Luminescence | | | | | | | | | | | | |
| Spectrum | | | | | | | | | | | | |
| (Thin Film) | | | | | | | | | | | | |
| Half-Width | 28 | nm | 25 | nm | 26 | nm | 31 | nm | 27 | nm | 26 | nm |
| (Thin Film) | | | | | | | | | | | | |
| Singlet- | 0.20 | eV | 0.20 | eV | 0.20 | eV | 0.20 | eV | 0.24 | eV | 0.20 | eV |
| Triplet | | | | | | | | | | | | |
| Energy | | | | | | | | | | | | |
| Triplet | 93.7 | μs | 4.45 | μs | 7.04 | μs | 9.76 | μs | 5.17 | μs | 6.15 | μs |
| Exciton | | | | | | | | | | | | |
| Lifespan | | | | | | | | | | | | |

As a result of the luminescence spectrum measurements, DABNA-1 that is Comparative Example 1 had the maximum luminescence peak increasing by 10 nm and the half-width by 7 nm in the thin film state compared to in the solution state, which worsened color characteristics, however, in Examples 1 to 5, the range of increase was only within 5 nm each.

### Experimental Example 2: Evaluation on Delayed Fluorescent Device Including Boron Compound

An ITO glass substrate was cut to a size of 50 mm×50 mm×0.7 mm, washed using acetone, isopropyl alcohol and distilled water for 10 minutes each, and then irradiated with ultraviolet rays for 10 minutes and exposed to ozone for cleaning. Then, the ITO glass substrate was installed on a vacuum deposition apparatus. On the ITO glass substrate, HATCN (7 nm)/TAPC (50 nm)/DCDPA (10 nm)/DBFPO host: 5% by weight of the boron compound (Example or Comparative Example) (25 nm)/DBFPO (5 nm)/TPBi (20 nm)/LiF (1.5 nm)/Al (100 nm) were laminated in this order to manufacture an organic light-emitting device. Device specific results are shown in the following Table 2.

TABLE 2

| | Comparative | | | | | | | | | | | |
|---|---|---|---|---|---|---|---|---|---|---|---|---|
| Category | Example 1 | | Example 1 | | Example 2 | | Example 3 | | Example 4 | | Example 5 | |
| Compound | DABNA-1 | | Chemical | | Chemical | | Chemical | | Chemical | | Chemical | |
| Structure | | | Formula 21 | | Formula 33 | | Formula 49 | | Formula 60 | | Formula 100 | |
| Maximum | 13.5% | | 19.3% | | 14.3% | | 16.7% | | 21.3% | | 15.1% | |
| EQE (%) | | | | | | | | | | | | |
| Half-Width | 28 | nm | 21 | nm | 22 | nm | 26 | nm | 22 | nm | 21 | nm |
| (nm) | | | | | | | | | | | | |
| Maximum | 460 | nm | 466 | nm | 461 | nm | 465 | nm | 463 | nm | 464 | nm |
| Electro- | | | | | | | | | | | | |
| lumines- | | | | | | | | | | | | |
| cence | | | | | | | | | | | | |
| Wavelength | | | | | | | | | | | | |
| (nm) | | | | | | | | | | | | |
| Device | 2 | Hours | 3 | Hours | 3 | Hours | 5 | Hours | 6 | Hours | 4 | Hours |
| Lifespan | | | | | | | | | | | | |
| LT90 | | | | | | | | | | | | |
| @ 1,000 | | | | | | | | | | | | |
| cd/m² | | | | | | | | | | | | |
| (Hour) | | | | | | | | | | | | |

Hereinbefore, examples of the present invention have been described in detail, however, the scope of a right of the present invention is not limited thereto, and it will be apparent to those skilled in the art that various modifications and variations may be made without departing technical ideas of the present invention described in the claims.

1. A boron compound represented by the following Chemical Formula 1: 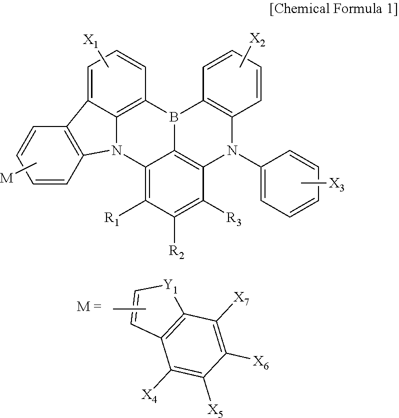
wherein, in Chemical Formula 1,
X₁ to X₇ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group;
Y₁ is N—R₄, oxygen or sulfur;
R₁ to R₃ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group; and
R₄ is hydrogen, deuterium, a substituted or unsubstituted C₁˜C₆₀ alkyl group, a substituted or unsubstituted C₃˜C₁₀ cycloalkyl group, a substituted or unsubstituted C₆˜C₆₀ aryl group, or a substituted or unsubstituted C₆˜C₆₀ heteroaryl group.

2. The boron compound of claim 1, which is represented by one of the following Chemical Formulae 2 to 126:

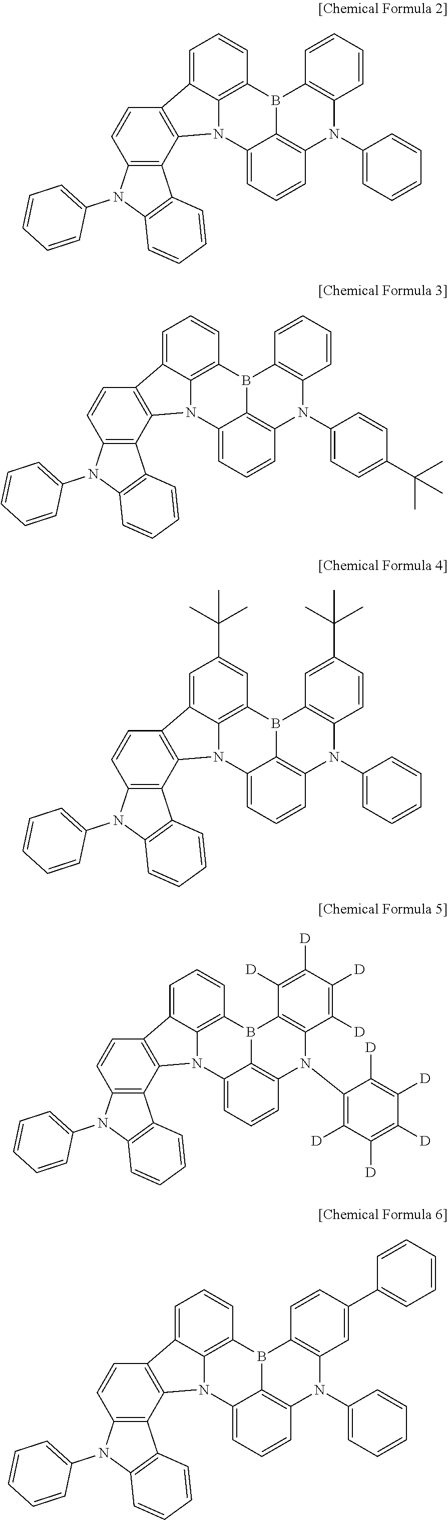 [SMILES: c1ccc(N2c3ccccc3B3c4c2cccc4-n2c4c3cccc4c3ccc4c(c5ccccc5n4-c4ccccc4)c32)cc1 ; CC(C)(C)c1ccc(N2c3ccccc3B3c4c2cccc4-n2c4c3cccc4c3ccc4c(c5ccccc5n4-c4ccccc4)c32)cc1 ; CC(C)(C)c1ccc2c(c1)B1c3c(cccc3-n3c4c1cc(C(C)(C)C)cc4c1ccc4c(c5ccccc5n4-c4ccccc4)c13)N2c1ccccc1 ; [2H]c1c([2H])c([2H])c(N2c3cccc4c3B(c3c([2H])c([2H])c([2H])c([2H])c32)c2cccc3c5ccc6c(c7ccccc7n6-c6ccccc6)c5n-4c23)c([2H])c1[2H] ; c1ccc(-c2ccc3c(c2)N(c2ccccc2)c2cccc4c2B3c2cccc3c5ccc6c(c7ccccc7n6-c6ccccc6)c5n-4c23)cc1]

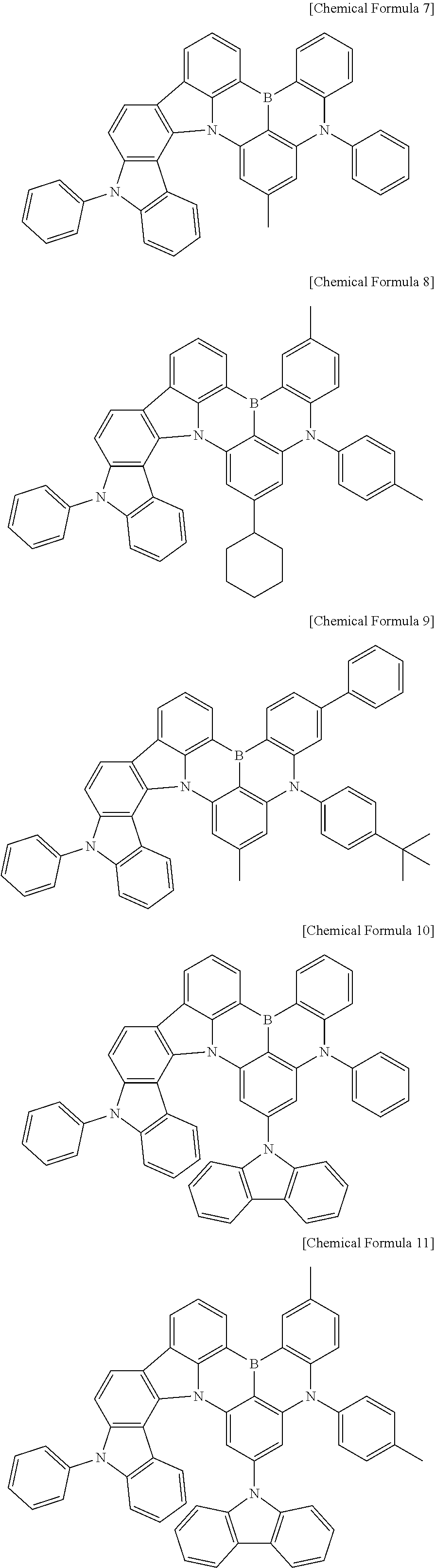

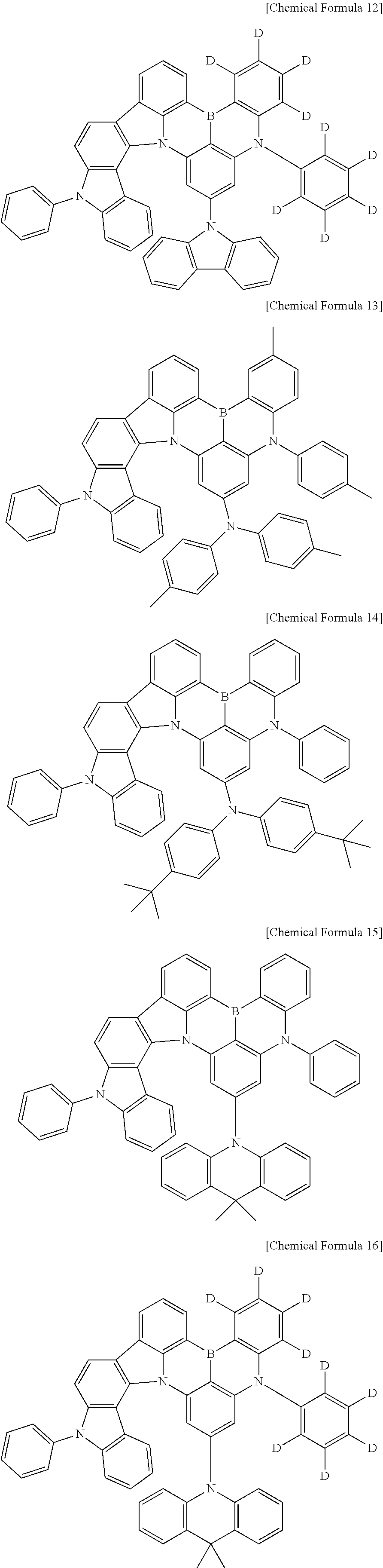

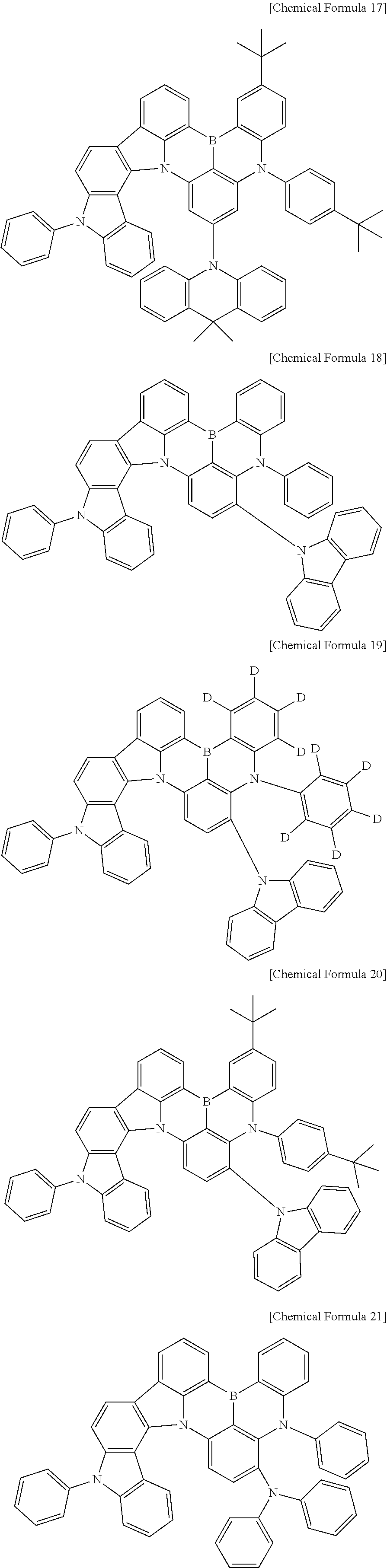

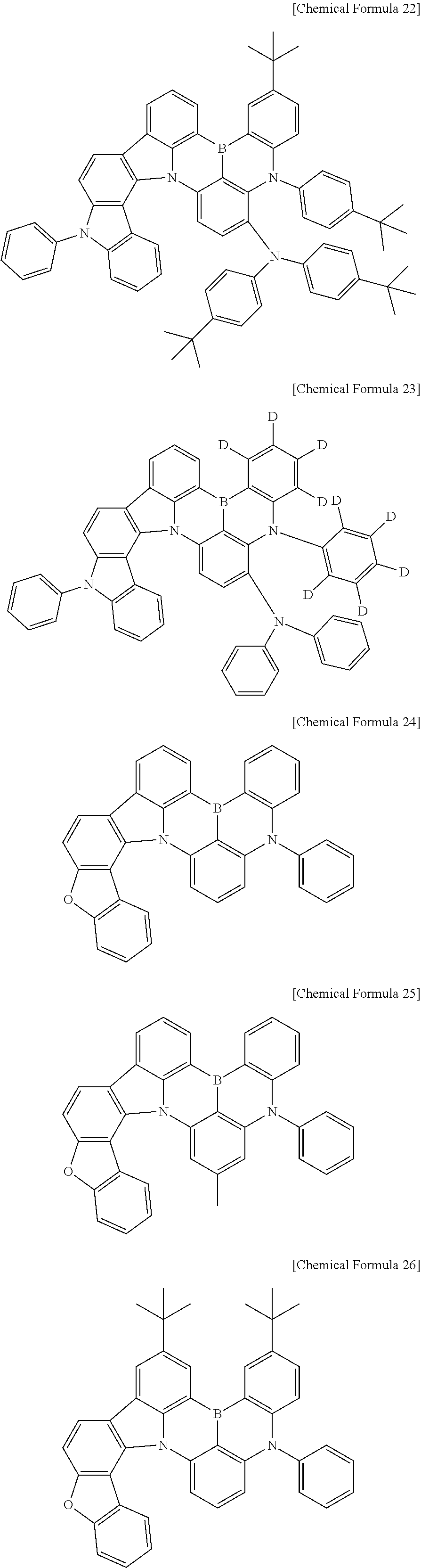

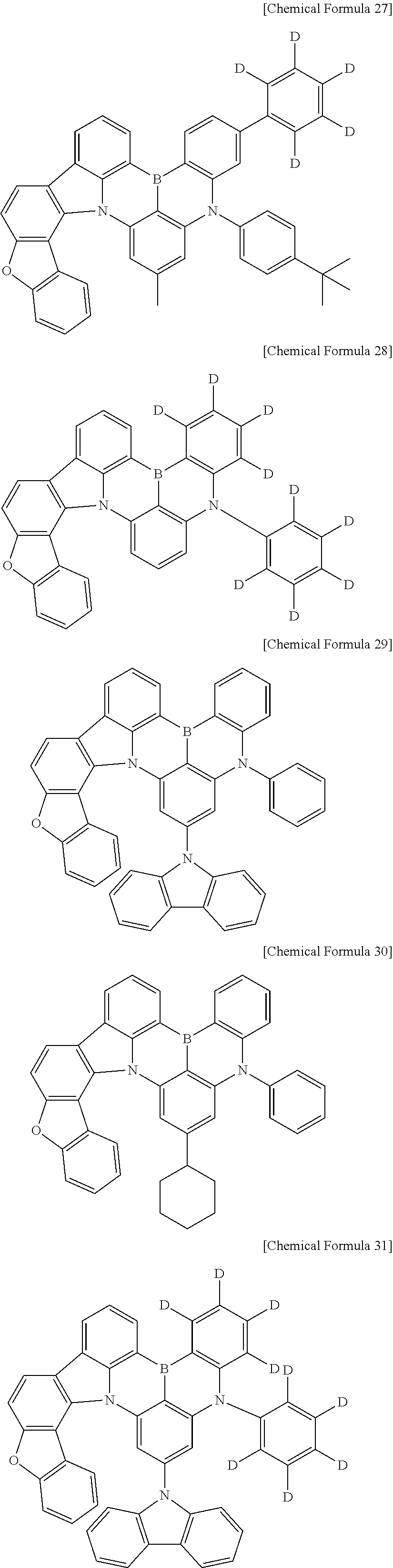

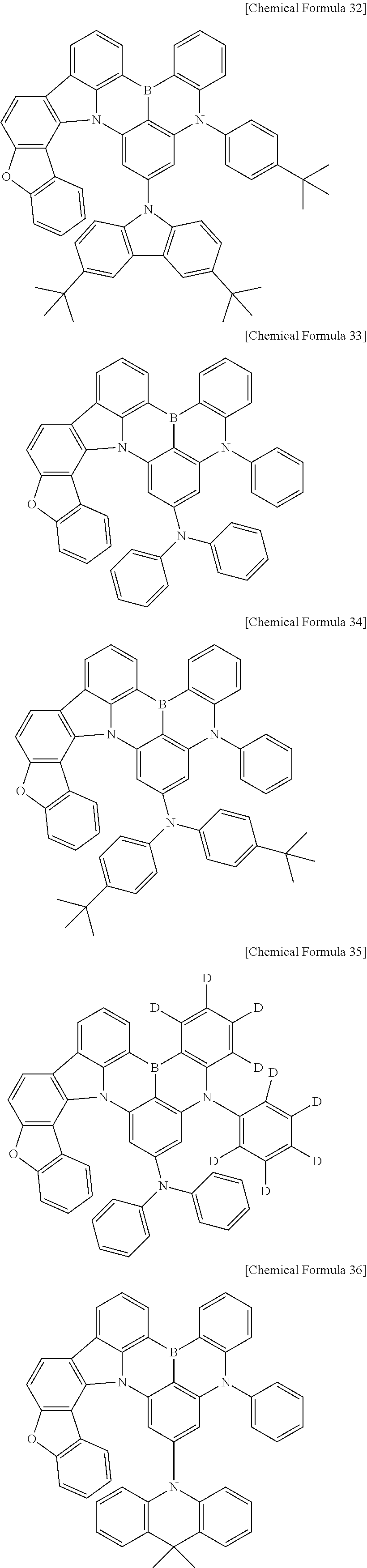

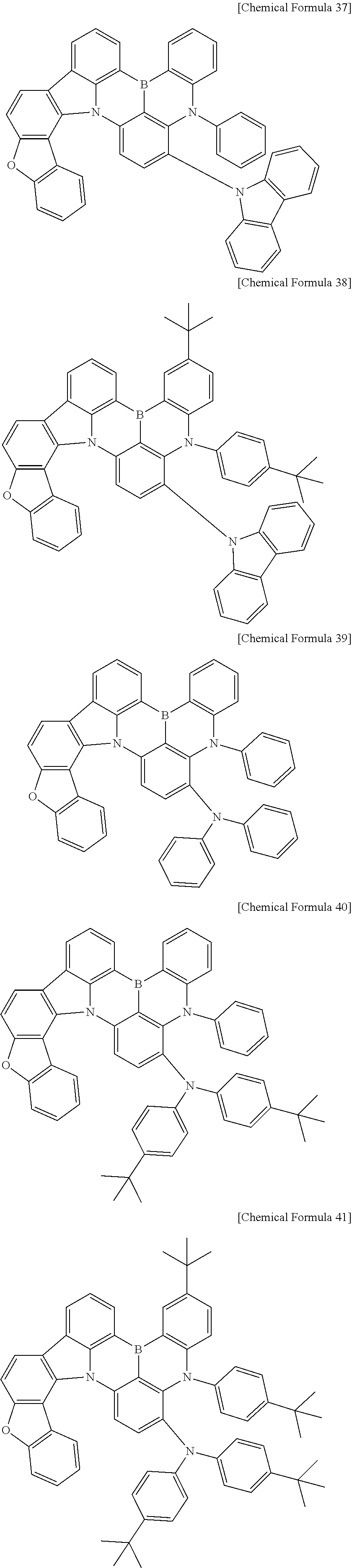

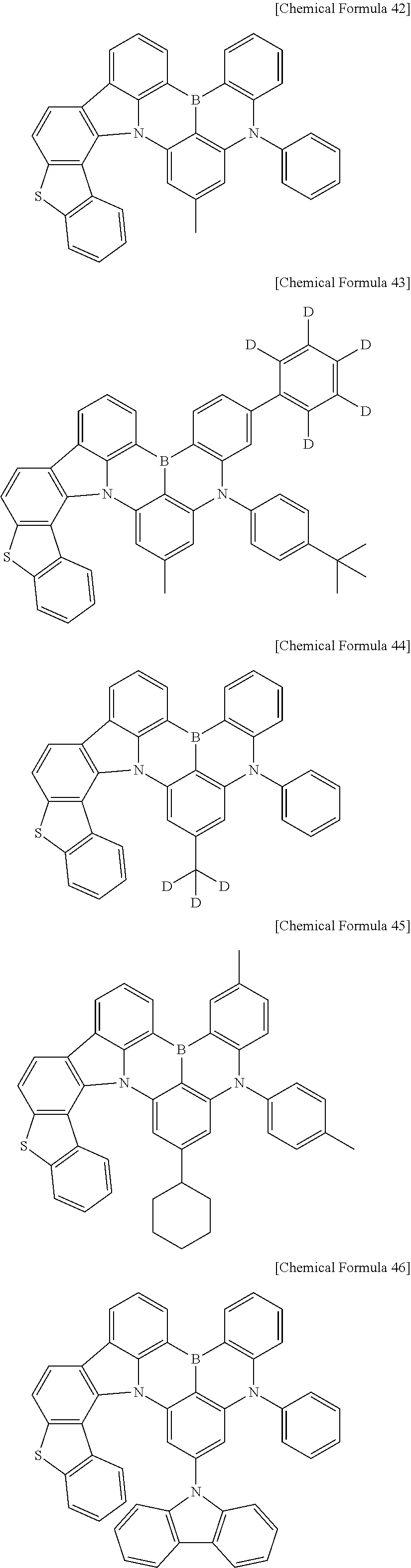 [SMILES: Cc1cc2c3c(c1)-n1c4c(cccc4c4ccc5sc6ccccc6c5c41)B3c1ccccc1N2c1ccccc1 ; [2H]c1c([2H])c([2H])c(-c2ccc3c(c2)N(c2ccc(C(C)(C)C)cc2)c2cc(C)cc4c2B3c2cccc3c5ccc6sc7ccccc7c6c5n-4c23)c([2H])c1[2H] ; [2H]C([2H])([2H])c1cc2c3c(c1)-n1c4c(cccc4c4ccc5sc6ccccc6c5c41)B3c1ccccc1N2c1ccccc1 ; Cc1ccc(N2c3ccc(C)cc3B3c4c2cc(C2CCCCC2)cc4-n2c4c3cccc4c3ccc4sc5ccccc5c4c32)cc1 ; c1ccc(N2c3ccccc3B3c4c2cc(-n2c5ccccc5c5ccccc52)cc4-n2c4c3cccc4c3ccc4sc5ccccc5c4c32)cc1]

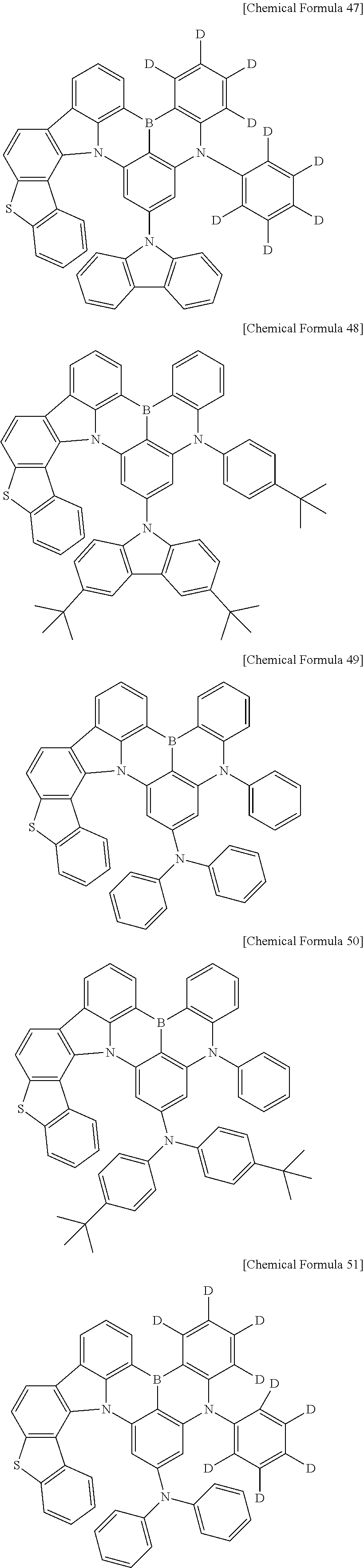

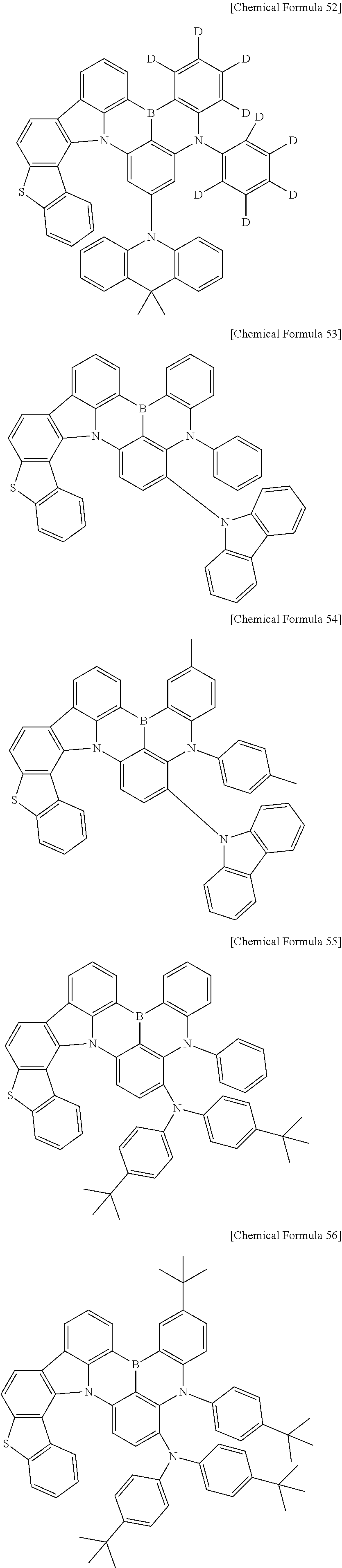

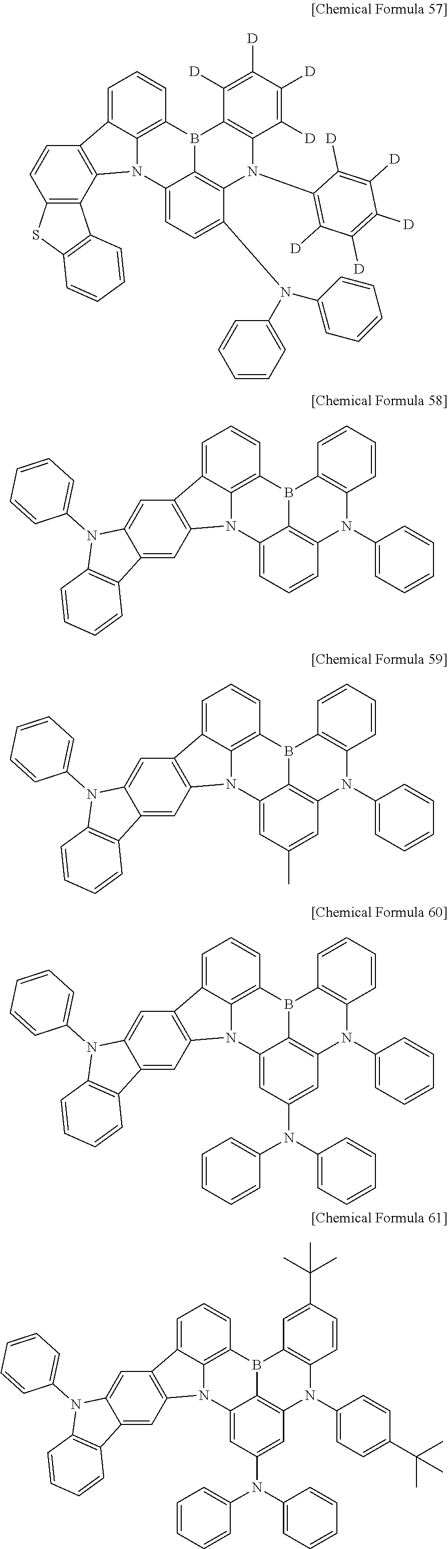

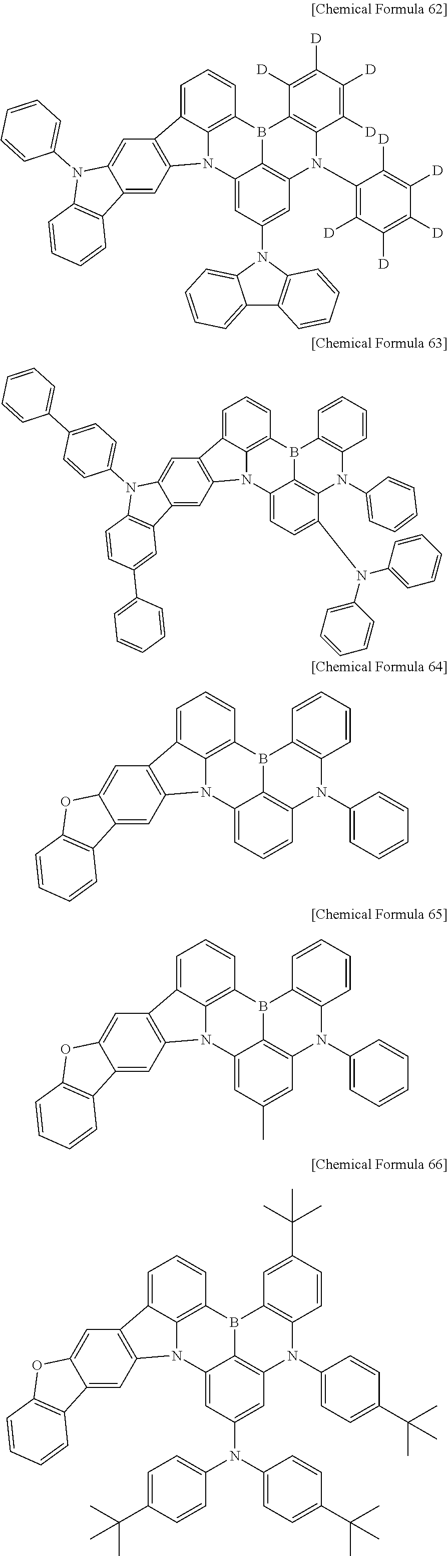

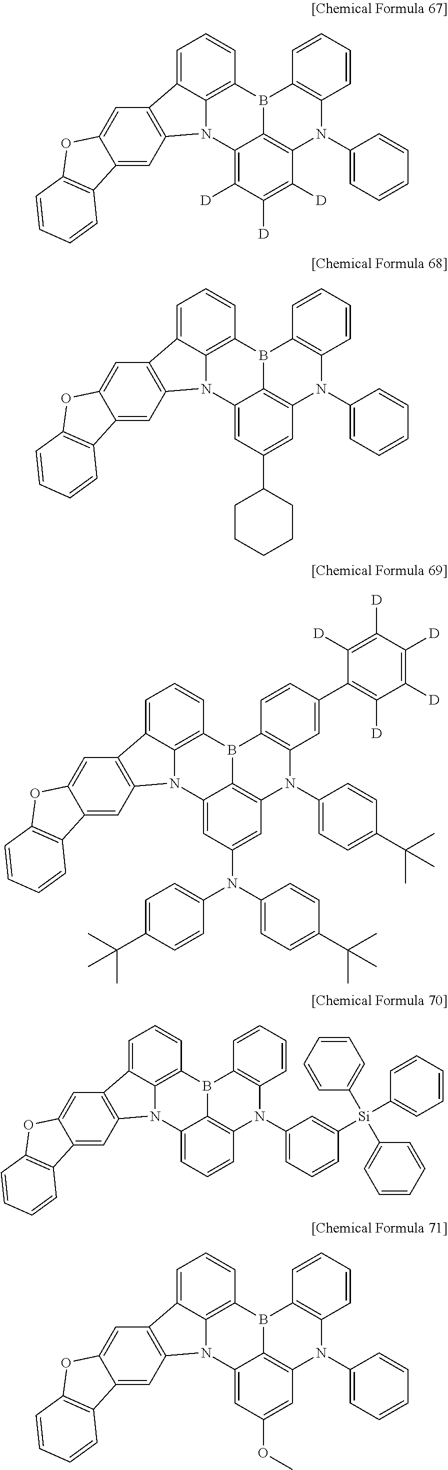 [SMILES: [2H]c1c([2H])c2c3c(c1[2H])-n1c4cc5c(cc4c4cccc(c41)B3c1ccccc1N2c1ccccc1)oc1ccccc15 ; c1ccc(N2c3ccccc3B3c4c2cc(C2CCCCC2)cc4-n2c4cc5c(cc4c4cccc3c42)oc2ccccc25)cc1 ; [2H]c1c([2H])c([2H])c(-c2ccc3c(c2)N(c2ccc(C(C)(C)C)cc2)c2cc(N(c4ccc(C(C)(C)C)cc4)c4ccc(C(C)(C)C)cc4)cc4c2B3c2cccc3c5cc6oc7ccccc7c6cc5n-4c23)c([2H])c1[2H] ; c1ccc([Si](c2ccccc2)(c2ccccc2)c2cccc(N3c4ccccc4B4c5c3cccc5-n3c5cc6c(cc5c5cccc4c53)oc3ccccc36)c2)cc1 ; COc1cc2c3c(c1)-n1c4cc5c(cc4c4cccc(c41)B3c1ccccc1N2c1ccccc1)oc1ccccc15]

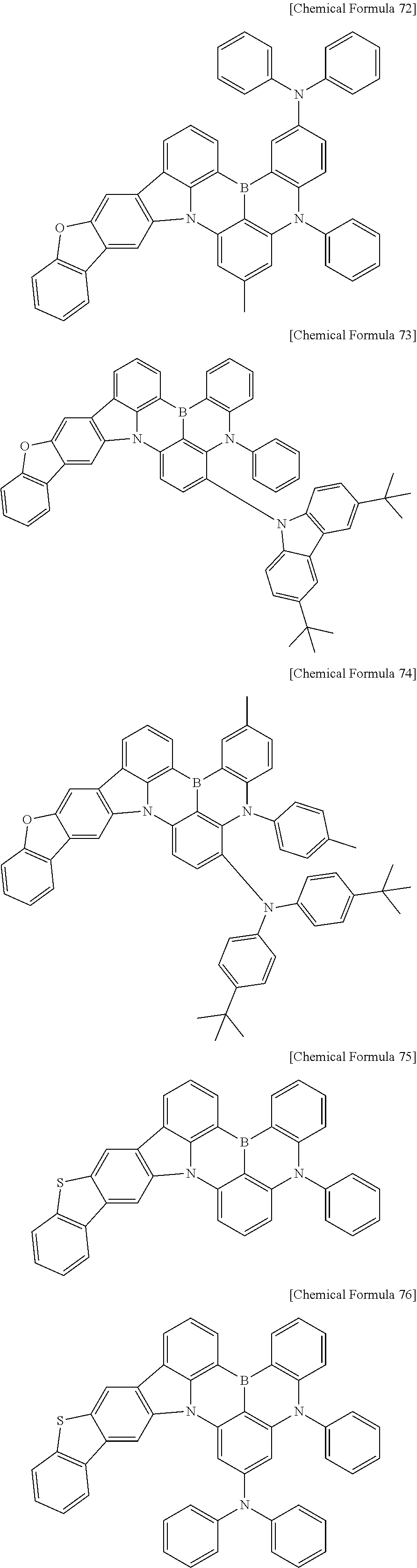 [SMILES: Cc1cc2c3c(c1)-n1c4cc5c(cc4c4cccc(c41)B3c1cc(N(c3ccccc3)c3ccccc3)ccc1N2c1ccccc1)oc1ccccc15 ; CC(C)(C)c1ccc2c(c1)c1cc(C(C)(C)C)ccc1n2-c1ccc2c3c1N(c1ccccc1)c1ccccc1B3c1cccc3c4cc5oc6ccccc6c5cc4n-2c13 ; Cc1ccc(N2c3ccc(C)cc3B3c4c(ccc(N(c5ccc(C(C)(C)C)cc5)c5ccc(C(C)(C)C)cc5)c42)-n2c4cc5c(cc4c4cccc3c42)oc2ccccc25)cc1 ; c1ccc(N2c3ccccc3B3c4c2cccc4-n2c4cc5c(cc4c4cccc3c42)sc2ccccc25)cc1 ; c1ccc(N(c2ccccc2)c2cc3c4c(c2)-n2c5cc6c(cc5c5cccc(c52)B4c2ccccc2N3c2ccccc2)sc2ccccc26)cc1]

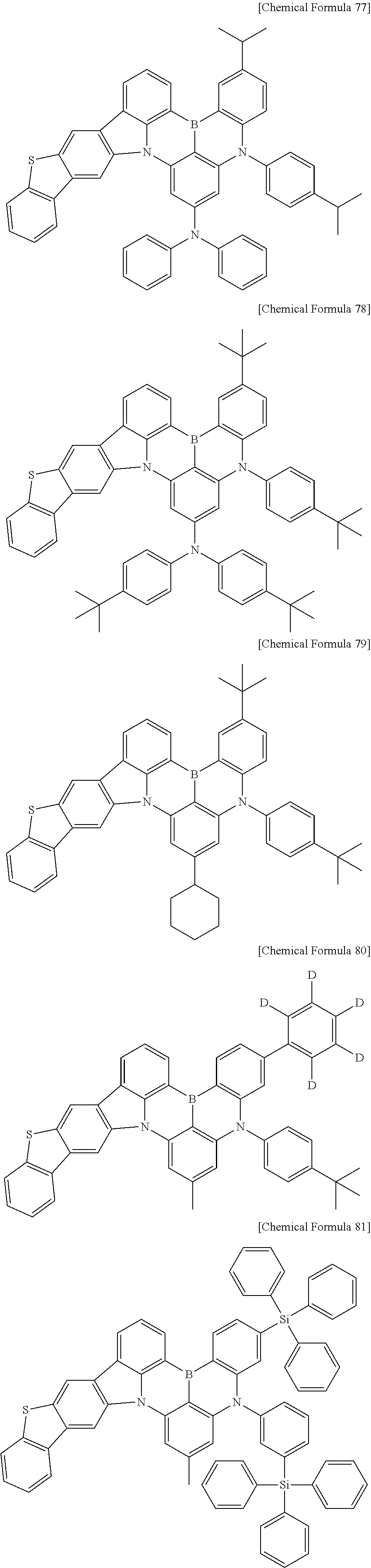

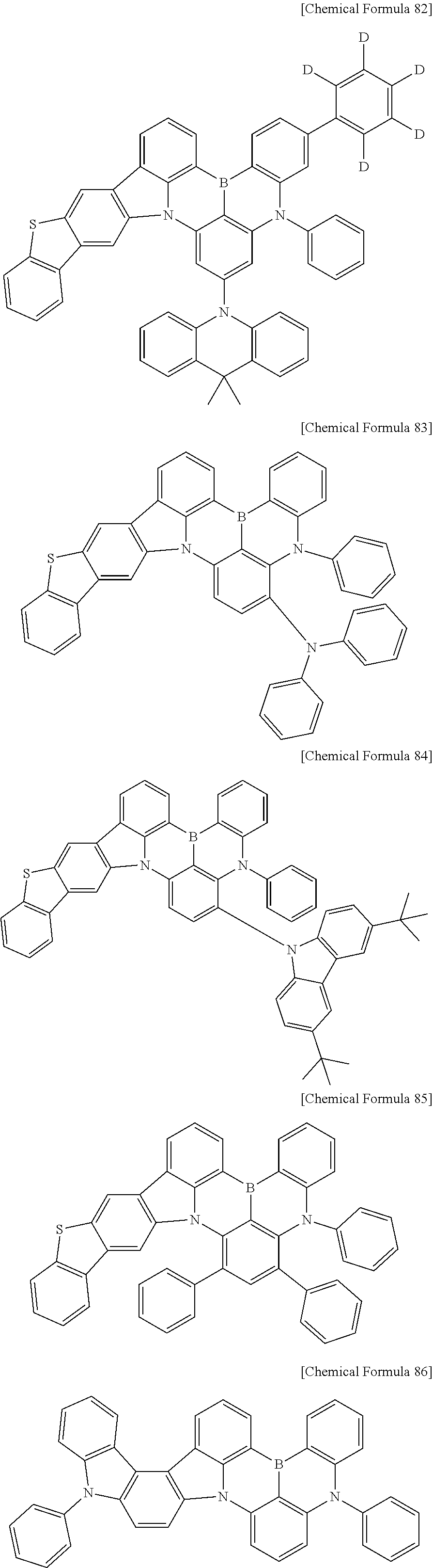

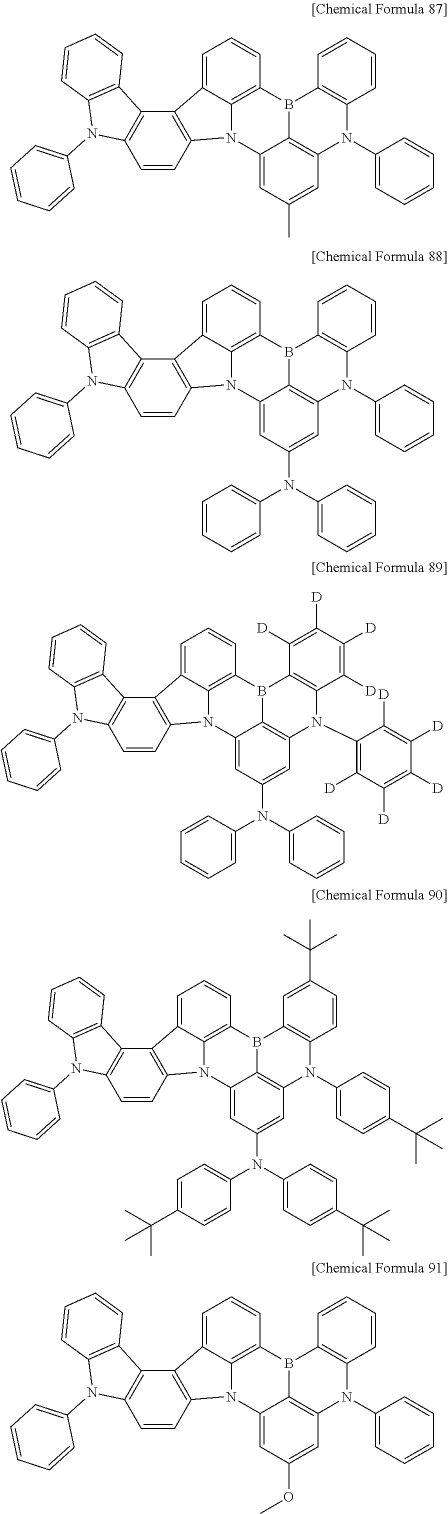

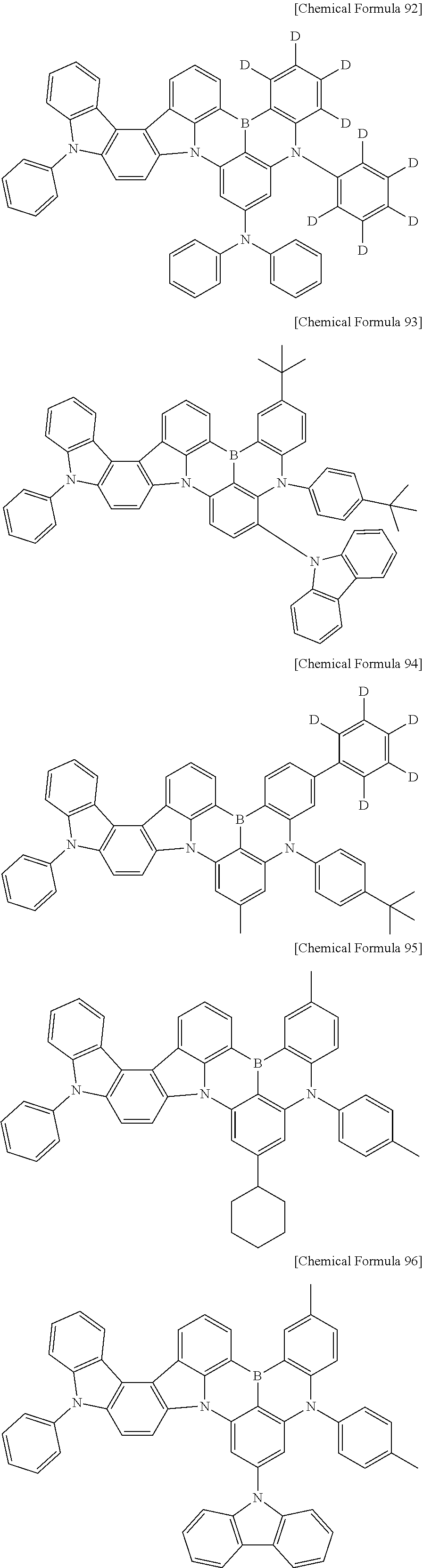

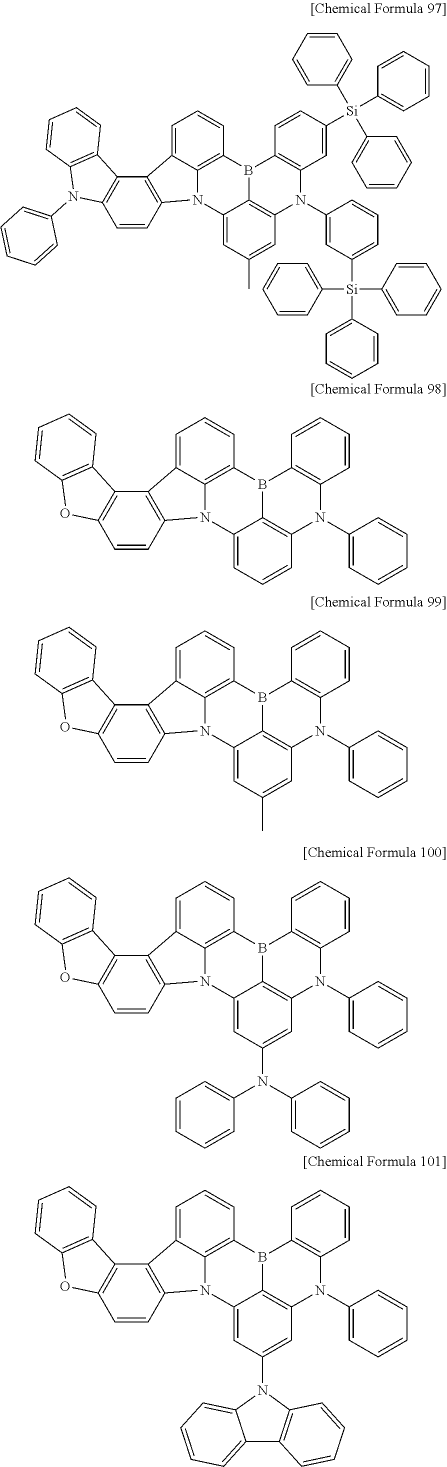

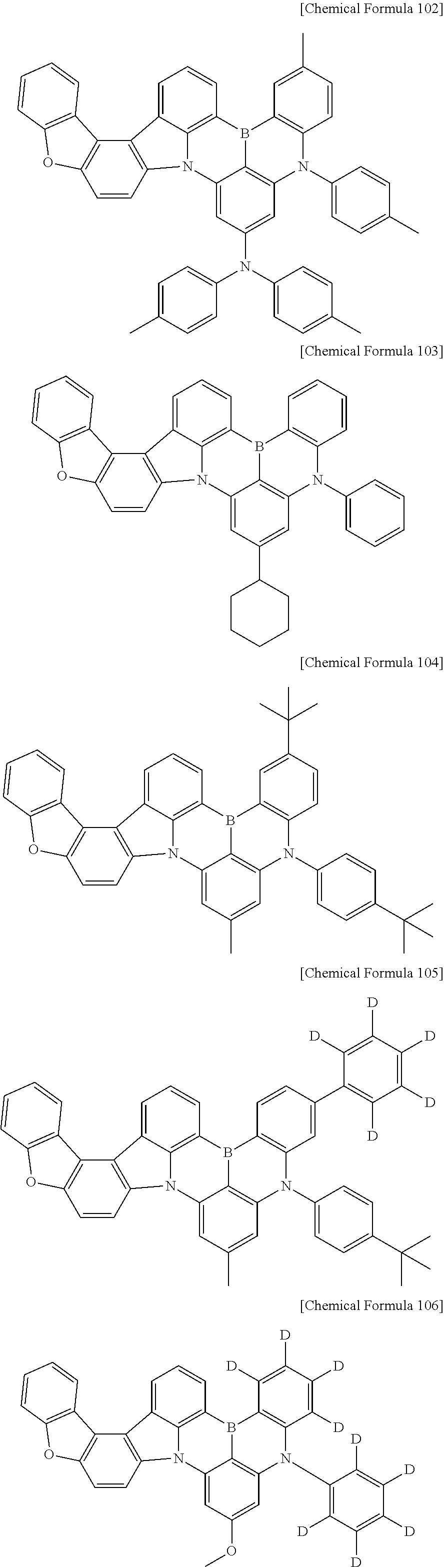

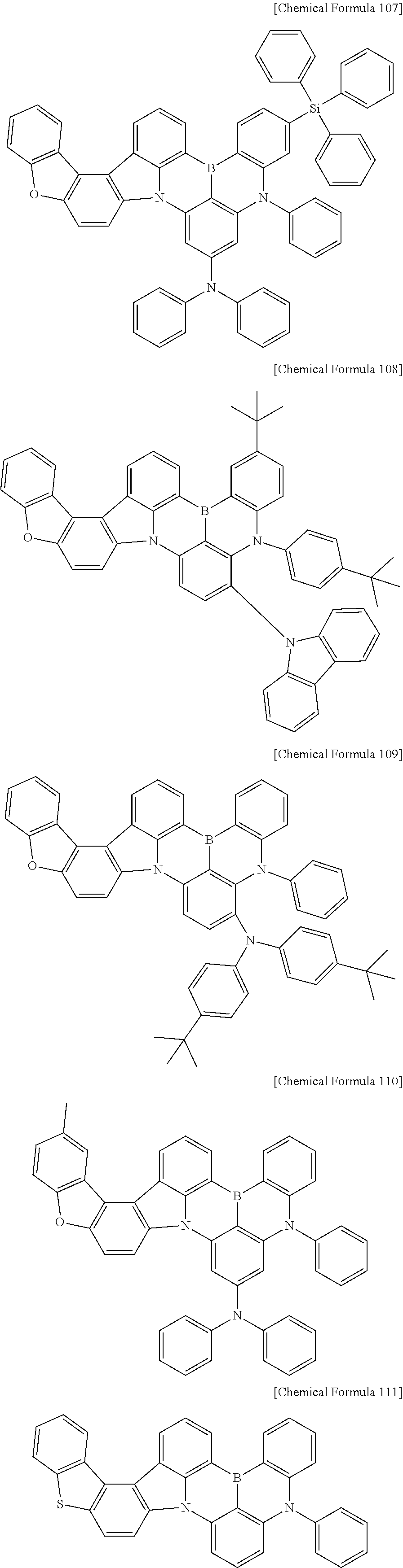 [SMILES: c1ccc(N(c2ccccc2)c2cc3c4c(c2)-n2c5ccc6oc7ccccc7c6c5c5cccc(c52)B4c2ccc([Si](c4ccccc4)(c4ccccc4)c4ccccc4)cc2N3c2ccccc2)cc1 ; CC(C)(C)c1ccc(N2c3ccc(C(C)(C)C)cc3B3c4c(ccc(-n5c6ccccc6c6ccccc65)c42)-n2c4ccc5oc6ccccc6c5c4c4cccc3c42)cc1 ; CC(C)(C)c1ccc(N(c2ccc(C(C)(C)C)cc2)c2ccc3c4c2N(c2ccccc2)c2ccccc2B4c2cccc4c5c6c(ccc5n-3c24)oc2ccccc26)cc1 ; Cc1ccc2oc3ccc4c(c5cccc6c5n4-c4cc(N(c5ccccc5)c5ccccc5)cc5c4B6c4ccccc4N5c4ccccc4)c3c2c1 ; c1ccc(N2c3ccccc3B3c4c2cccc4-n2c4ccc5sc6ccccc6c5c4c4cccc3c42)cc1]

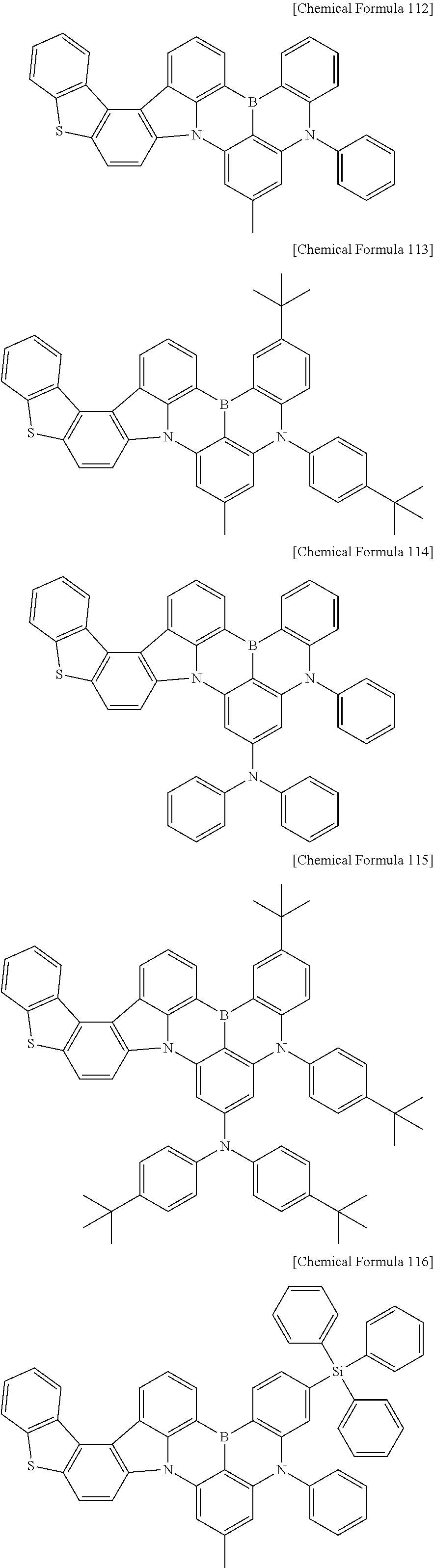

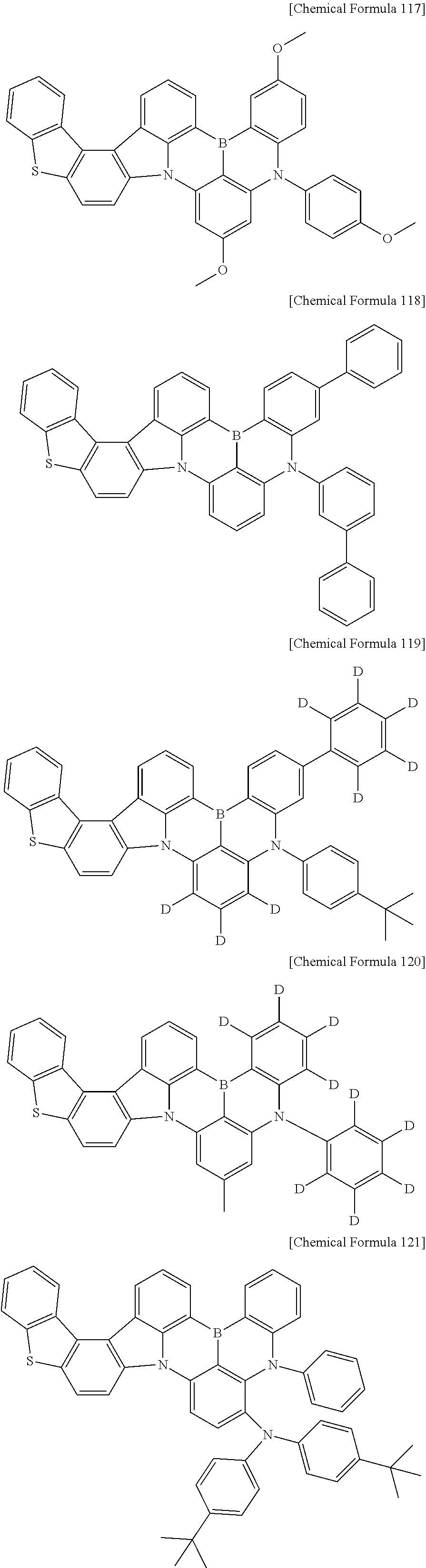

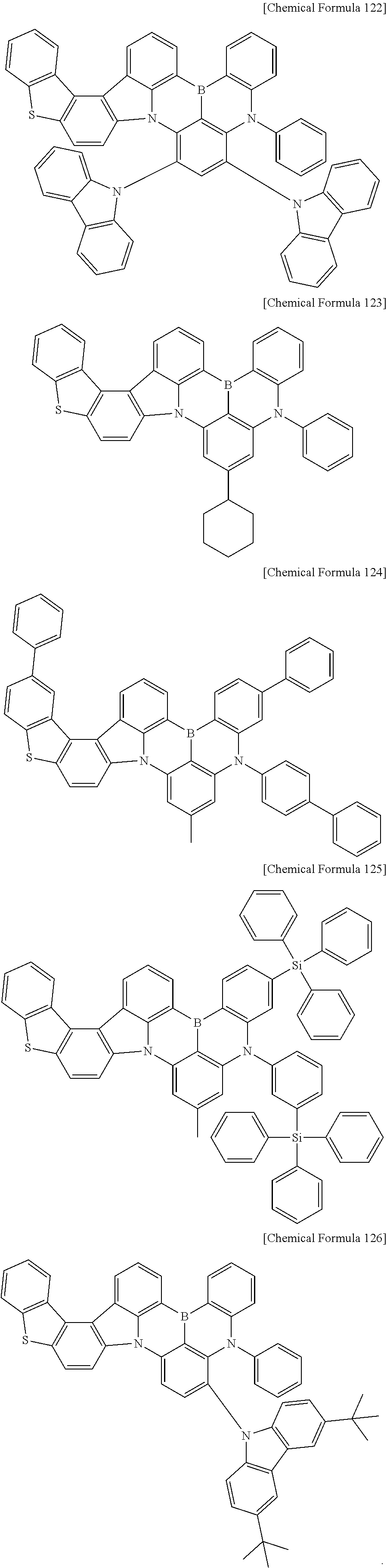

3. An organic light-emitting device comprising:
a first electrode;
a second electrode provided opposite to the first electrode; and
an organic material layer located between the first electrode and the second electrode,
wherein the organic material layer includes the boron compound of claim 1.

4. The organic light-emitting device of claim 3, wherein the organic material layer includes an electron injection layer (EIL), an electron transport layer (ETL), a light-emitting layer (EML), a hole transport layer (HTL) and a hole injection layer (HIL).

5. The organic light-emitting device of claim 4, wherein the light-emitting layer includes an anthracene derivative represented by the following Chemical Formula 127 as a host compound: 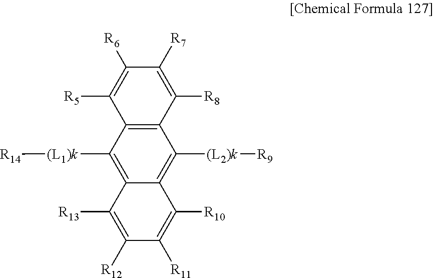
in Chemical Formula 127,
R₅ to R₁₄ are each independently hydrogen, deuterium, a nitrile group, a halogen group, a substituted or unsubstituted C₁˜C₁₀ alkyl group, a substituted or unsubstituted C₃˜C₁₀ cycloalkyl group, a substituted or unsubstituted C₁˜C₁₀ alkoxy group, a substituted or unsubstituted C₁˜C₁₀ silyl group, a substituted or unsubstituted amine group, a substituted or unsubstituted C₆˜C₂₀ aryl group, a substituted or unsubstituted C₂˜C₂₀ heteroaryl group, a substituted or unsubstituted C₁₂˜C₂₀ diarylamino group, a substituted or unsubstituted C₄˜C₂₀ diheteroarylamino group, or a substituted or unsubstituted C₂˜C₂₀ arylheteroarylamino group;
L₁ and L₂ are each independently a single bond, a substituted or unsubstituted arylene group, or a substituted or unsubstituted heteroarylene group; and
ks are each independently an integer of 1 to 3.

6. The organic light-emitting device of claim 4, wherein the light-emitting layer includes a host compound, a first dopant compound and a second dopant compound;
the second dopant compound is a delayed fluorescent material or a phosphorescent material; and
the first dopant compound includes the boron compound of claim 1.

7. The organic light-emitting device of claim 6, wherein a half-width of the first dopant compound is narrower than a half-width of the second dopant compound.

8. The organic light-emitting device of claim 6, wherein the host compound and the second dopant compound each have higher singlet energy and triplet energy than the first dopant compound.

9. The organic light-emitting device of claim 6, wherein the delayed fluorescent material of the second dopant compound is a material having an electron donating-electron accepting structure;
the material having an electron donating-electron accepting structure uses one or more of a boron compound, a triazine, a cyano group and a sulfone group as an electron acceptor, and one or more of a carbazole derivative and an acridane derivative as an electron donor; and
the phosphorescent material of the second dopant compound includes one or more types of heavy metals among Ir, Pt and Pd.

10. The organic light-emitting device of claim 6, wherein the host compound includes one or more of mCP, mCBP, mCBP-CN, 2CzPy, DBFPO, DPEPO, DDBFT and pSiTrz.

11. The organic light-emitting device of claim 10, wherein the host compound includes two or more types of different host compounds.

12. A display apparatus comprising the organic light-emitting device of claim 3.

13. A lighting apparatus comprising the organic light-emitting device of claim 3.

14. An organic light-emitting device comprising:
a first electrode;
a second electrode provided opposite to the first electrode; and
an organic material layer located between the first electrode and the second electrode,
wherein the organic material layer includes the boron compound according to claim 2.

15. The organic light-emitting device of claim 14, wherein the organic material layer includes an electron injection layer (EIL), an electron transport layer (ETL), a light-emitting layer (EML), a hole transport layer (HTL) and a hole injection layer (HIL).

16. The organic light-emitting device of claim 15, wherein the light-emitting layer includes a host compound, a first dopant compound and a second dopant compound;
the second dopant compound is a delayed fluorescent material or a phosphorescent material;
and
the first dopant compound includes the boron compound according to claim 2.
